(19) United States
(12) Patent Application Publication
(10) Pub. No.: US 2008/0241762 A1
(43) Pub. Date: Oct. 2, 2008

(54) Photothermographic material and image forming method

(75) Inventor: Kouta Fukui, Kanagawa (JP)

Correspondence Address: TAIYO CORPORATION, 401 HOLLAND LANE, #407, ALEXANDRIA, VA, 22314, US

(73) Assignee: FUJIFILM CORPORATION, Minato-ku (JP)

(21) Appl. No.: 12/068,990

(22) Filed: Feb. 14, 2008

(30) Foreign Application Priority Data
Mar. 26, 2007 (JP) 2007-080114

(51) Int. Cl. G03F 7/00

(52) U.S. Cl. 430/322; 430/564

(57) ABSTRACT

A photothermographic material including at least a photosensitive silver halide, a non-photosensitive organic silver salt, and a reducing agent for thermal development, and further including at least two dyes having maximum absorption wavelengths different from each other, wherein the difference between the maximum absorption wavelengths is from 10 nm to 50 nm, a maximum absorption wavelength of a first dye corresponds to a wavelength of a first laser for imagewise exposure, and a maximum absorption wavelength of a second dye corresponds to a wavelength of a second laser for imagewise exposure. Moreover, an image forming method using a sheet of the photothermographic material, wherein a part of the sheet is imagewise exposed using a laser while another part of the sheet that has already been imagewise exposed is thermally developed, and a distance between the exposure portion and thermal developing portion is 50 cm or less, is provided.

### CROSS-REFERENCE TO RELATED APPLICATION

This application claims priority under 35 USC 119 from Japanese Patent Application No. 2007-080114, the disclosure of which is incorporated by reference herein.

### BACKGROUND OF THE INVENTION

1. Field of the Invention

The present invention relates to a photothermographic material and an image forming method using the same.

2. Description of the Related Art

In recent years, in the field of films for medical imaging, there has been strong demand for decreasing the amount of processing liquid waste in order to protect the environment and economize space. Technology is therefore required for light-sensitive photothermographic materials which can be exposed effectively by laser image setters or laser imagers to obtain clear black-toned images of high resolution and sharpness, for use in medical diagnostic applications and for use in photographic technical applications. Light-sensitive photothermographic materials do not require liquid processing chemicals and can therefore be supplied to customers as a simpler and more environmentally friendly thermal developing processing system.

While similar requirements also exist in the field of general image forming materials, images for medical imaging in particular require high image quality excellent in sharpness and granularity because fine depiction is required, and further require a blue-black image tone for easy diagnosis. Various kinds of hard copy systems utilizing dyes or pigments, such as ink jet printers and electrophotographic systems, have been marketed as general image forming systems, but these are not satisfactory as output systems for medical images.

Thermal image forming systems utilizing organic silver salts are described in many documents. In particular, photothermographic materials generally have an image forming layer in which a catalytically active amount of a photocatalyst (for example, silver halide), a reducing agent, a reducible silver salt (for example, an organic silver salt), and if necessary, a toner for controlling the color tone of developed silver images, are dispersed in a binder. Photothermographic materials form black silver images by being heated to a high temperature (for example, 80° C. or higher) after imagewise exposure to cause an oxidation-reduction reaction between a silver halide or a reducible silver salt (functioning as an oxidizing agent) and a reducing agent. The oxidation-reduction reaction is accelerated by the catalytic action of a latent image on the silver halide generated by imagewise exposure. As a result, a black silver image is formed in the exposed region. Further, the Fuji Medical Dry Imager FM-DPL is an example of a medical image forming system using photothermographic materials that has been made commercially available.

As a method of manufacturing a photothermographic material utilizing an organic silver salt, a method of manufacture by coating using an organic solvent such as methyl ethyl ketone as a solvent followed by drying is known. As a binder for an image forming layer, poly(vinyl acetals) such as poly(vinyl butyral) and the like have been generally used (see, for example, “Thermally Processed Silver Systems” by D. H. Klosterboer, appearing in “Imaging Processes and Materials”, Neblette, 8th edition, edited by J. Sturge, V. Walworth, and A. Shepp, Chapter 9, pages 279 to 291, 1989). All patents, patent publications, and non-patent literature cited in this specification are hereby expressly incorporated by reference herein.

An image forming layer of a photothermographic material has a photosensitive silver halide, a reducing agent, and a non-photosensitive organic silver salt necessary for image formation, and if necessary, a toner for controlling the color tone of developed silver images, all of which are dispersed in a binder in advance. Therefore, the ratio of the total solid content of these components relative to the binder is high, the viscosity of the coating solution is increased, and fluidity of the coating solution is decreased, resulting in a problem whereby productivity in the coating step deteriorates. According to Japanese Patent Application Laid-Open (JP-A) No. 2006-17877, the viscosity can be lowered by increasing the amount of coating solvent and decreasing the solid content, but this is not preferable because the amount of solvent increases and the effort involved in coating, drying, and recovery of the used solvent increases.

As a laser for imagewise exposure which is used in laser image setters or laser imagers, various lasers are used, and laser light sources have also been improved such that, for example, new lasers have been further developed and the like. Depending on the laser used, there are cases where the oscillation wavelength changes together with a rise in the environmental temperature of the laser oscillator in conjunction with continuous driving. Because the sensitivity of a photothermographic material varies when the oscillation wavelength changes, this is problematic in that stable performance cannot be obtained.

In general, photothermographic materials are designed to exhibit the highest sensitivity at the wavelength of a laser used for imagewise exposure. Therefore, when the laser is changed and, accordingly, the emission wavelength is changed, a photothermographic material which has the highest sensitivity at that particular wavelength is always required.

However, difficulties in handling systems have become problematic because the photothermographic materials corresponding to each laser have increased in variety and storage control thereof has become complicated. Moreover, because photothermographic materials include all the components necessary for image formation in the film in advance, there are concerns that the performance changes when the time period of storage between production and use for image formation is long. When the variety of photothermographic materials increases, the time period for storage becomes longer, so that the problem concerning storage stability has become more significant.

Thus, a photothermographic material which has versatility of use and can be used in common in different types of thermal developing apparatuses is desired.

### SUMMARY OF THE INVENTION

The present invention has been made in view of the above circumstances and provides a photothermographic material and an image forming method with the following aspects.

A first aspect of the invention provides a photothermographic material comprising, on at least one side of a support, at least a photosensitive silver halide, a non-photosensitive organic silver salt, and a reducing agent for thermal development, and further comprising at least two dyes having maximum absorption wavelengths that are different from each other, wherein the difference between the maximum absorption wavelengths is from 10 nm to 50 nm, a maximum absorption wavelength of a first dye corresponds to a wavelength of a first laser for imagewise exposure, and a maximum absorption wavelength of a second dye corresponds to a wavelength of a second laser for imagewise exposure.

A second aspect of the invention provides an image forming method for forming an image during conveyance of a sheet of a photothermographic material by using an image forming apparatus comprising an imagewise exposure portion and a thermal developing portion, wherein the photothermographic material is the photothermographic material according to the first aspect, a part of the sheet is subjected to imagewise exposure using a laser while another part of the sheet that has already been imagewise exposed is subjected to thermal development, and a distance between the imagewise exposure portion and the thermal developing portion is 50 cm or less.

### BRIEF DESCRIPTION OF THE DRAWINGS

FIG. 1 is a lateral view schematically illustrating the configuration of the main components of a thermal developing apparatus according to the present invention.

FIG. 2 is a lateral view schematically illustrating the configuration of the main components of another thermal developing apparatus according to the present invention.

### DETAILED DESCRIPTION OF THE INVENTION

An object of the present invention is to provide a photothermographic material which has versatility of use and can be used in common in different types of thermal developing apparatuses, and an image forming method using the same.

The present invention is explained below in detail.

The photothermographic material of the present invention is characterized in that it includes, on at least one side of a support, at least a photosensitive silver halide, a non-photosensitive organic silver salt, and a reducing agent for thermal development, and further includes at least two dyes having maximum absorption wavelengths that are different from each other, wherein the difference between the maximum absorption wavelengths is from 10 nm to 50 nm, a maximum absorption wavelength of a first dye corresponds to a wavelength of a first laser for imagewise exposure, and a maximum absorption wavelength of a second dye corresponds to a wavelength of a second laser for imagewise exposure.

When the difference between the maximum absorption wavelengths of the two dyes is less than 10 nm, it is difficult to attain sufficient versatility of use with respect to various thermal developing apparatuses and stability with respect to continuous driving of a laser oscillator. Further, it is not preferable for the difference between the maximum absorption wavelengths of the two dyes to exceed 50 nm because image tone deteriorates and coloring in a non-image portion, called residual color, is evident.

Preferably, the maximum absorption wavelength of the first dye is from 750 nm to 800 nm, and the difference between the maximum absorption wavelength of the second dye and the maximum absorption wavelength of the first dye is from 10 nm to 50 nm. More preferably, the maximum absorption wavelength of the second dye is 10 nm to 50 nm longer than the maximum absorption wavelength of the first dye.

A preferable category of lasers for the imagewise exposure used in the present invention consists of semiconductor lasers which have an oscillation wavelength in the red to infrared region; however, these use different oscillation wavelengths of, for example, 765 nm, 785 nm, 810 nm, or the like depending on the semiconductor device. Further, the wavelength varies due to continuous driving of the laser oscillator, and there are cases where the wavelength varies by about 10 nm, depending on the conditions. By setting the maximum absorption wavelengths of the two dyes according to the present invention to the wavelengths described above, a photothermographic material with excellent versatility of use with respect to semiconductor lasers in the red to infrared region can be provided.

The image forming method of the present invention is characterized in that it is an image forming method for forming an image during conveyance of a sheet of a photothermographic material by using an image forming apparatus having an imagewise exposure portion and a thermal developing portion, wherein the photothermographic material described above is used, a part of the sheet is subjected to imagewise exposure using a laser while another part of the sheet that has already been imagewise exposed is subjected to thermal development, and a distance between the imagewise exposure portion and the thermal developing portion is 50 cm or less. Preferably, the thermal developing portion has a temperature raising portion and a temperature keeping portion, in which a distance between the imagewise exposure portion and the temperature raising portion is 50 cm or less, and the temperature raising portion and the temperature keeping portion have heating means that are different from each other. More preferably, a total time required for the photothermographic material to pass through the temperature raising portion and the temperature keeping portion is from 2 sec to 11 sec.

The image forming apparatus used for the image forming method of the present invention has an imagewise exposure portion and a thermal developing portion, and forms an image during conveyance of a sheet of a photothermographic material, wherein a part of the sheet is subjected to imagewise exposure using a laser while another part of the sheet that has already been imagewise exposed is subjected to thermal development, and a distance between the imagewise exposure portion and the thermal developing portion is 50 cm or less. The image forming apparatus used for the image forming method of the present invention has an advantage in that continuous imagewise exposure and thermal development are possible, and at the same time design of a compact desktop apparatus is possible. In such a compact design, it is important to retain and insulate the heat of the thermal developing portion. However, when the distance between the imagewise exposure portion and the thermal developing portion is small, the apparatus is excessively large in order to insulate the heat sufficiently, resulting in the loss of the feature of compact size. By using the photothermographic material of the present invention, stable performance can be always obtained, even if the heat of the thermal developing portion influences the imagewise exposure portion to raise the temperature of the imagewise exposure portion during continuous drive.

According to the present invention, a photothermographic material, which has versatility of use and can be used in common in various thermal developing apparatuses, and an image forming method using the same, are provided. Further, according to the present invention, a photothermographic material which can provide stable performance even during continuous driving of a laser oscillator, and an image forming method using the same, are provided.

(Explanation of Dye)

The photothermographic material of the present invention contains at least two dyes having maximum absorption wavelengths that are different from each other, wherein the difference between the maximum absorption wavelengths is from 10 nm to 50 nm, a maximum absorption wavelength of a first dye corresponds to a wavelength of a first laser for imagewise exposure, and a maximum absorption wavelength of a second dye corresponds to a wavelength of a second laser for imagewise exposure.

Preferably, the maximum absorption wavelength of the first dye is from 750 nm to 800 nm, the difference between the maximum absorption wavelength of the second dye and the maximum absorption wavelength of the first dye is from 10 nm to 50 nm, and the maximum absorption wavelength of the second dye is 10 nm to 50 nm longer than the maximum absorption wavelength of the first dye.

More preferably, the maximum absorption wavelength of the first dye is from 760 nm to 795 nm, and the difference between the maximum absorption wavelength of the second dye and the maximum absorption wavelength of the first dye is from 15 nm to 45 nm. Even more preferably, the maximum absorption wavelength of the second dye is 20 nm to 30 nm longer than the maximum absorption wavelength of the first dye.

Density of the first dye at the maximum absorption wavelength thereof is preferably from 0.2 to 1.2.

Density of the second dye at the maximum absorption wavelength thereof is preferably from 0.2 to 1.2.

A density ratio of the first dye to the second dye is preferably from 30/70 to 70/30.

The dyes which can be used in the present invention can be added into the coating solution in the form of a solution using water or an organic solvent, or in the form of a dispersion such as an emulsified dispersion or solid dispersion.

The dyes which can be used in the present invention are preferably soluble to water or organic solvent, and are preferably added in the form of a solution.

The dyes which can be used in the present invention have no particular restriction on the dye structure, as long as the dyes have the absorption properties described above. The dyes having the above-described properties can be selected from various dyes conventionally known in the technical field and used. Particularly preferable dyes among these are explained below.

1) First Dye

The first dye according to the present invention is preferably a squarylium dye explained below. The dye represented by the following formula (1) is preferable.

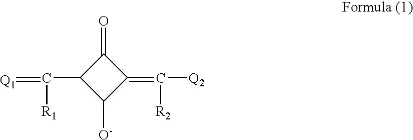

In formula (1), R₁ and R₂ each independently represent a hydrogen atom or a substituent; R₁ and R₂ are not simultaneously a hydrogen atom; when both of R₁ and R₂ are a substituent, R₁ and R₂ represent different substituents; and Q₁ and Q₂ each independently represent a 6-membered heterocycle.

More preferably, the dye represented by formula (1) is a dye represented by the following formula (2).

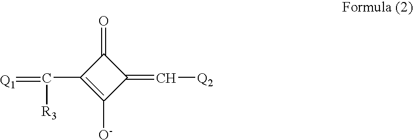

In formula (2), R₃ represents a substituent. Q₁ and Q₂ each have the same meaning as in formula (1) described above.

Even more preferably, the dye represented by formula (2) is a dye represented by the following formula (3).

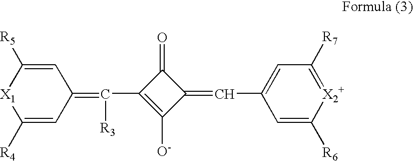

In formula (3), R₃ has the same meaning as in formula (2) described above. X₁ and X₂ each independently represent O, S. Se, Te, or N—R. R represents an alkyl group or an aryl group. R₄ to R₇ each independently represent a hydrogen atom or a substituent.

Preferably, in formula (3) described above, X₁ and X₂ are different from each other.

Further preferably, the dye represented by formula (3) described above is a dye represented by the following formula (4).

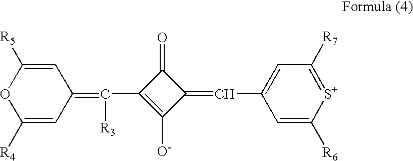

In formula (4), R₃ has the same meaning as in formula (2) described above. R₄ to R₇ each have the same meaning as in formula (3) described above.

In formula (1) described above, R₁ and R₂ each independently represent a hydrogen atom or a substituent. However, R₁ and R₂ are not simultaneously a hydrogen atom, and when both of R₁ and R₂ are a substituent, R₁ and R₂ represent different substituents. Examples of the substituent represented by R₁ or R₂ include an alkyl group, a cycloalkyl group, an alkenyl group, an alkynyl group, an aryl group, a heterocyclic group, a halogen atom, a cyano group, and the like. Preferable is the case where R₁ is a hydrogen atom and R₂ is an alkyl group or an aryl group. More preferable is the case where R₁ is a hydrogen atom and R₂ is an alkyl group.

Q₁ and Q₂ each independently represent a 6-membered heterocycle. Examples of the heterocycle include pyrylium, thiopyrylium, selenopyrylium, telluropyrylium, pyridinium, benzpyrylium, benzthiopyrylium, benzselenopyrylium, and the like. Preferable is pyrylium, thiopyrylium, or selenopyrylium, and more preferable is pyrylium or thiopyrylium.

These heterocycles may have a substituent, and examples of the substituent include an alkyl group, a cycloalkyl group, an alkyl halide group, an alkenyl group, an alkynyl group, an aryl group, a heterocyclic group, a halogen atom, a cyano group, a hydroxy group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group, an anilino group, an acylamino group, an aminocarbonylamino group, alkoxycarbonylamino group, an aryloxycarbonylamino group, sulfamoylamino group, an alkylsulfonylamino group, an arylsulfonylamino group, a mercapto group, an alkylthio group, an arylthio group, a heterocyclic thio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, an imido group, a silyl group, a hydrazino group, a ureido group, a boron acid group, a phosphato group, a sulfato group, and the like.

In formula (2) described above, R₃ represents a substituent, and examples of the substituent include an alkyl group, a cycloalkyl group, an alkenyl group, an alkynyl group, an aryl group, a heterocyclic group, a halogen atom, a cyano group, and the like. Preferable is an alkyl group or an aryl group, and more preferable is an alkyl group.

Q₁ and Q₂ each have the same meaning as in formula (1) described above.

In formula (3) described above, R₃ has the same meaning as in formula (2) described above.

X₁ and X₂ each independently represent O, S, Se, Te, or N—R, and R represents an alkyl group or an aryl group. X₁ and X₂ are each preferably O or S.

R₄ to R₇ each independently represent a hydrogen atom or a substituent. Examples of the substituent include an alkyl group, a cycloalkyl group, an alkyl halide group, an alkenyl group, an alkynyl group, an aryl group, a heterocyclic group, a halogen atom, a cyano group, a hydroxy group, a carboxy group, an alkoxy group, an aryloxy group, a silyloxy group, a heterocyclic oxy group, an amino group, an anilino group, an acylamino group, a mercapto group, an alkylthio group, an arylthio group, a heterocyclic thio group, a sulfamoyl group, a sulfo group, an acyl group, a hydrazino group, a ureido group, and the like.

In formula (4) described above, R₃ has the same meaning as in formula (2) described above.

R₄ to R₇ each have the same meaning as in formula (3) described above.

Specific examples of the compound represented by formula (1) to (4) are shown below, but the first dye according to the invention is not limited to these examples.

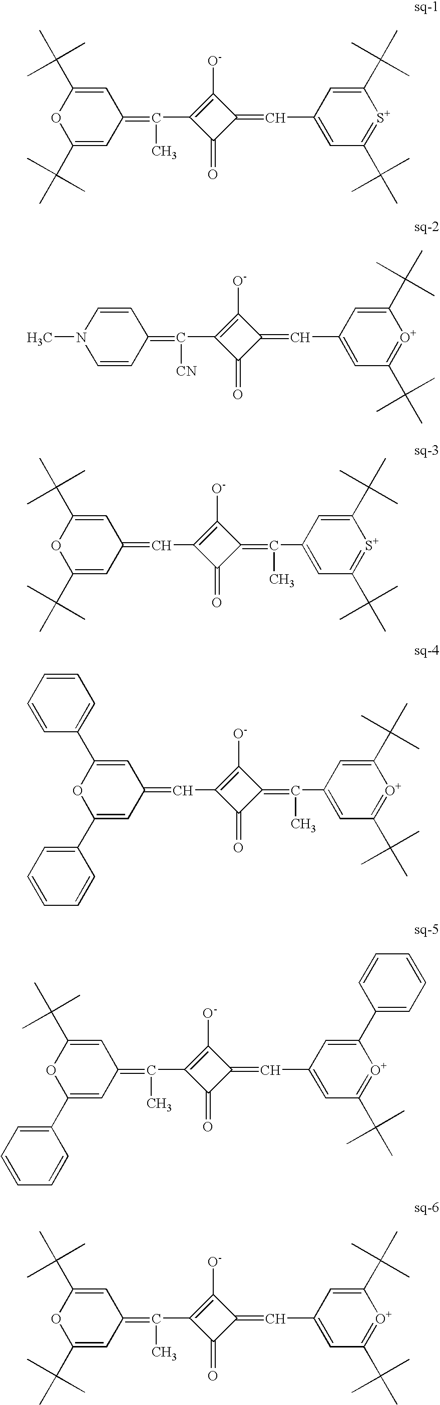

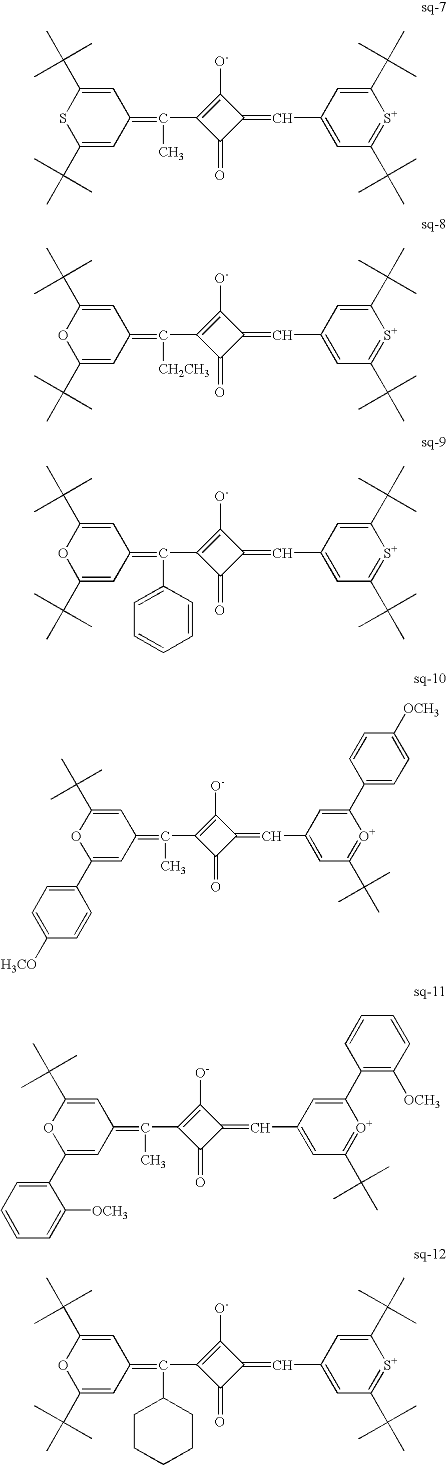

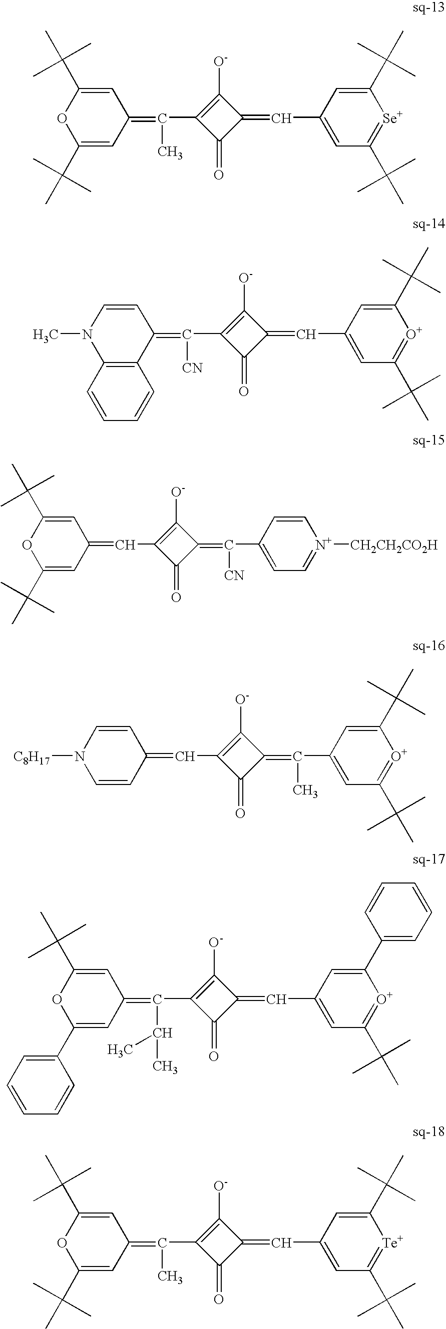

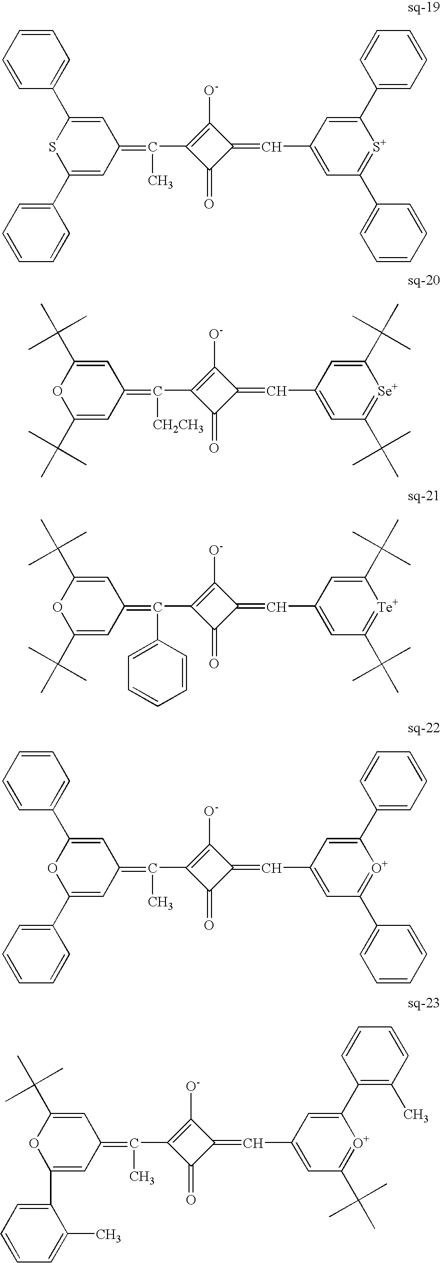

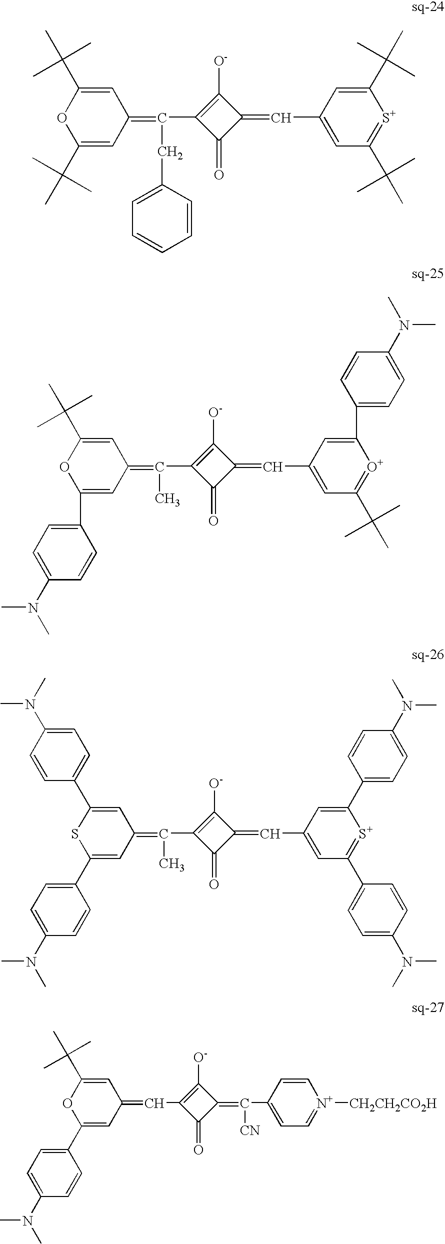

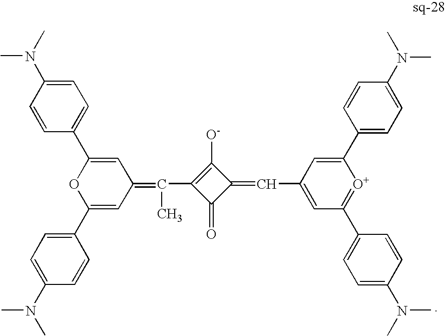

The compound represented by formula (1) to (4) may be added to any layer of the photothermographic material, but it is preferably added to the image forming layer, a non-photosensitive layer on the side of the support having the image forming layer, or a filter layer which is formed on the opposite side of the support from the image forming layer, and it is more preferably added to a non-photosensitive layer on the side of the support having the image forming layer or a filter layer which is formed on the opposite side of the support from the image forming layer. The addition amount of the compound represented by formula (1) to (4) is preferably from 1×10⁻⁵ mmol to 10 mmol, more preferably from 1×10⁻⁴ mmol to 1 mmol, and most preferably from 1×10⁻³ mmol to 1×10⁻¹ mmol, per 1 m².

The compound represented by formula (1) to (4) can be added according to known methods.

That is, the compound can be added to the coating solution by being dissolved in alcohols such as methanol, ethanol, or the like; ketones such as methyl ethyl ketone, acetone, or the like; polar solvent such as dimethyl sulfoxide, dimethylformamide, or the like; or the like. The compound can be added in the form of fine particles having a size of 1 μm or less being dispersed in water or an organic solvent. Concerning the technique for fine particle dispersion, a lot of techniques are disclosed, and the compound can be dispersed according to these techniques.

As the first dye according to the present invention other than those above, dyes represented by formula (1) to (9) described in JP-A No. 2006-251755 can be preferably used.

2) Second Dye

The dye represented by formula (B) which is used for the second dye according to the present invention will be explained.

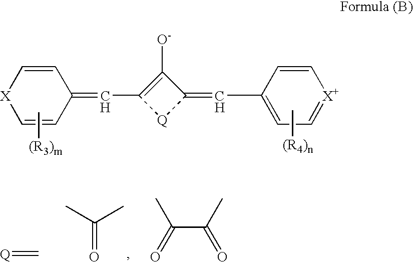

In formula (B), X represents a sulfur atom or an oxygen atom; and R₃ and R₄ each represent a monovalent substituent. The monovalent substituent has no particular restriction and include, preferably, an alkyl group (for example, a methyl group, an ethyl group, an isopropyl group, a tert-butyl group, a methoxyethyl group, a methoxyethoxyethyl group, a 2-ethylhexyl group, a 2-hexyldecyl group, a benzyl group, or the like) and an aryl group (for example, a phenyl group, a 4-chlorophenyl group, a 2,6-dimethylphenyl group, or the like). An alkyl group is more preferred, and a tert-butyl group is most preferred. R₃ and R₄ may join together to form a ring. m and n each represent an integer of from 0 to 4, and are each preferably 2 or less.

Examples of the dye used in the present invention are shown below. However the invention is not limited to these dyes.

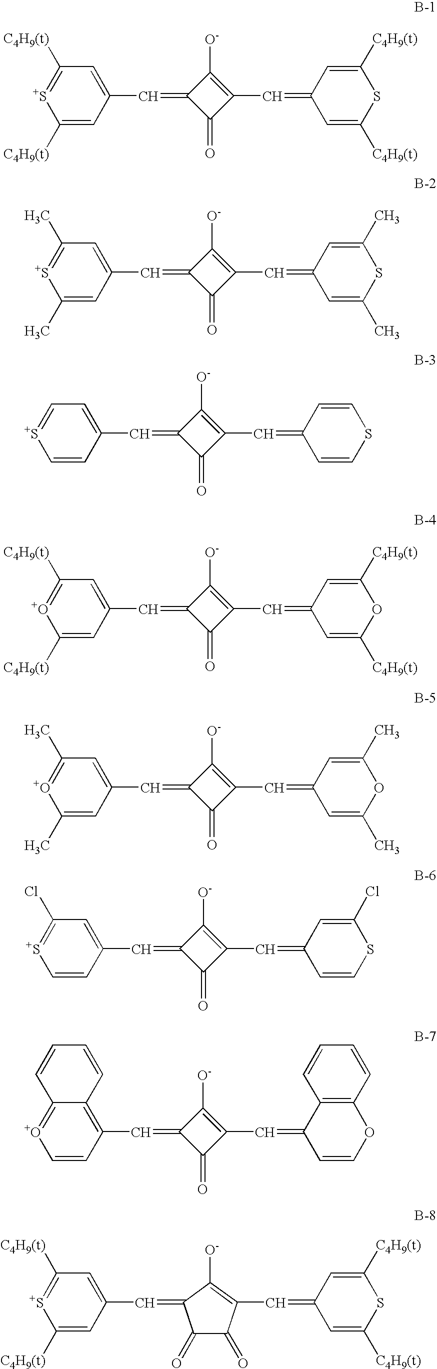

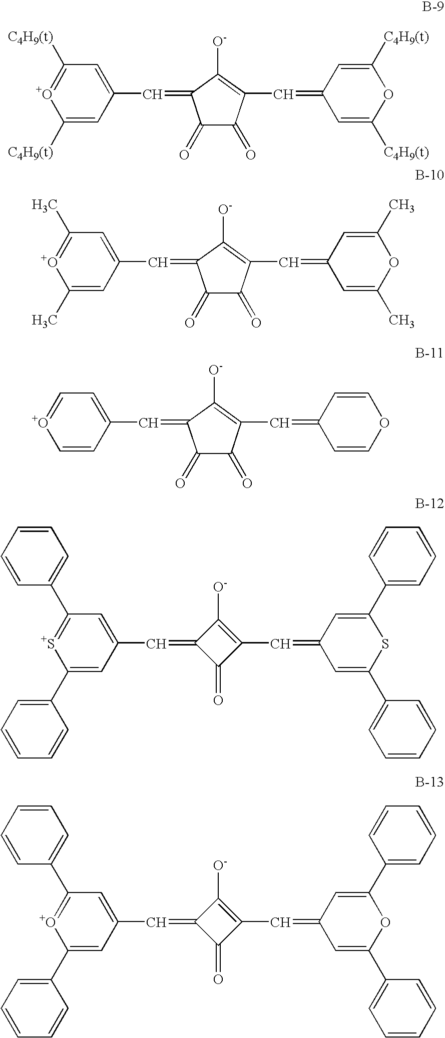

These squarylium dyes can be synthesized according to the methods described in JP-A Nos. 2006-106469 and 2006-251755.

In the case where the dye represented by formula (B) is added to the thermal developing photosensitive layer (image forming layer), it is generally added in the form of a solution by dissolving the dye in a solvent, but the dye can be added by being dispersed to be in the form of fine particles by a method which is called solid dispersion. When the dye is added to the thermal developing photosensitive layer (image forming layer), the effect to suppress most effectively the light scattering is great; and when the dye is added to a thermal developing photosensitive layer (image forming layer) which is spectrally sensitized so that the spectral sensitization maximum wavelength is in the infrared region of from 800 nm to 830 nm, a great improvement in sharpness can be attained. Further in the present invention, by adding these dyes, variation in performance such as sensitivity, color tone, or the like of the photothermographic material due to lack of movement of coating solution can be greatly improved, which is the subject of the present invention.

(Reducing Agent)

The photothermographic material of the present invention preferably contains a reducing agent for silver ions as a thermal developing agent. The reducing agent may be any substance (preferably, organic substance) which reduces silver ions into metallic silver. Examples of the reducing agent are described in JP-A No. 11-65021 (paragraph Nos. 0043 to 0045) and European Patent (EP) No. 0803764A1 (p. 7, line 34 to p. 18, line 12).

In the present invention, the reducing agent is preferably a so-called hindered phenol reducing agent or a bisphenol reducing agent having a substituent at the ortho-position with respect to the phenolic hydroxy group. It is more preferably a compound represented by the following formula (R).

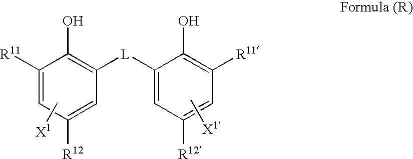

In formula (R), R¹¹ and R^{11′} each independently represent an alkyl group having 1 to 20 carbon atoms. R¹² and R^{12′} each independently represent a hydrogen atom or a substituent which substitutes for a hydrogen atom on a benzene ring. L represents an —S— group or a —CHR¹³— group. R¹³ represents a hydrogen atom or an alkyl group having 1 to 20 carbon atoms. X¹ and X^{1′} each independently represent a hydrogen atom or a group substituting for a hydrogen atom on a benzene ring.

Formula (R) is to be described in detail.

1) R¹¹ and R^{11′}

R¹¹ and R^{11′} each independently represent a substituted or unsubstituted alkyl group having 1 to 20 carbon atoms. The substituent of the alkyl group has no particular restriction and include, preferably, an aryl group, a hydroxy group, an alkoxy group, an aryloxy group, an alkylthio group, an arylthio group, an acylamino group, a sulfonamido group, a sulfonyl group, a phosphoryl group, an acyl group, a carbamoyl group, an ester group, a ureido group, a urethane group, a halogen atom, and the like.

2) R¹² and R^{12′}, X¹ and X^{1′}

R¹² and R^{12′} each independently represent a hydrogen atom or a substituent which substitutes for a hydrogen atom on a benzene ring. X¹ and X^{1′} each independently represent a hydrogen atom or a group substituting for a hydrogen atom on a benzene ring. As each of the groups substituting for a hydrogen atom on the benzene ring, an alkyl group, an aryl group, a halogen atom, an alkoxy group, and an acylamino group are described preferably.

3) L

L represents an —S— group or a —CHR¹³— group. R¹³ represents a hydrogen atom or an alkyl group having 1 to 20 carbon atoms in which the alkyl group may have a substituent. Specific examples of the unsubstituted alkyl group for R¹³ include a methyl group, an ethyl group, a propyl group, a butyl group, a heptyl group, an undecyl group, an isopropyl group, a 1-ethylpentyl group, a 2,4,4-trimethylpentyl group, a cyclohexyl group, a 2,4-dimethyl-3-cyclohexenyl group, a 3,5-dimethyl-3-cyclohexenyl group, and the like. In particular, the alkyl group for R¹³ is preferably an alicyclic alkyl group, and particularly preferably a cyclohexyl group, a 2,4-dimethyl-3-cyclohexenyl group, or a 3,5-dimethyl-3-cyclohexenyl group. Examples of the substituent of the alkyl group include, similar to the substituent of R¹¹, a halogen atom, an alkoxy group, an alkylthio group, an aryloxy group, an arylthio group, an acylamino group, a sulfonamido group, a sulfonyl group, a phosphoryl group, an oxycarbonyl group, a carbamoyl group, a sulfamoyl group, and the like.

4) Preferred Substituents

R¹¹ and R^{11′} are preferably a primary, secondary, or tertiary alkyl group having 1 to 15 carbon atoms; and examples thereof include, specifically, a methyl group, an isopropyl group, a t-butyl group, a t-amyl group, a t-octyl group, a cyclohexyl group, a cyclopentyl group, a 1-methylcyclohexyl group, a 1-methylcyclopropyl group, and the like. R¹¹ and R^{11′} each represent, more preferably, an alkyl group having 1 to 8 carbon atoms, and among them, a methyl group, a t-butyl group, a t-amyl group, and a 1-methylcyclohexyl group are even more preferred, a methyl group and a t-butyl group being most preferred.

R¹² and R^{12′} are preferably an alkyl group having 1 to 20 carbon atoms; and examples thereof include, specifically, a methyl group, an ethyl group, a propyl group, a butyl group, an isopropyl group, a t-butyl group, a t-amyl group, a cyclohexyl group, a 1-methylcyclohexyl group, a benzyl group, a methoxymethyl group, a methoxyethyl group, and the like. More preferred are a methyl group, an ethyl group, a propyl group, an isopropyl group, and a t-butyl group, and particularly preferred are a methyl group and an ethyl group.

X¹ and X^{1′} are preferably a hydrogen atom, a halogen atom, or an alkyl group, and more preferably a hydrogen atom.

L is preferably a —CHR¹³— group.

R¹³ is preferably a hydrogen atom or an alkyl group having 1 to 15 carbon atoms. The alkyl group is preferably a chain or cyclic alkyl group. And, groups which have a C═C bond in these alkyl groups are also preferably used. Preferable examples of the alkyl group include a methyl group, an ethyl group, a propyl group, an isopropyl group, a 2,4,4-trimethylpentyl group, a cyclohexyl group, a 2,4-dimethyl-3-cyclohexenyl group, a 3,5-dimethyl-3-cyclohexenyl group, and the like. Particularly preferable R¹³ is a hydrogen atom, a methyl group, an ethyl group, a propyl group, an isopropyl group, or a 2,4-dimethyl-3-cyclohexenyl group.

In the case where R¹¹ and R^{11′} are a tertiary alkyl group and R¹² and R^{12′} are a methyl group, R¹³ is preferably a primary or secondary alkyl group having 1 to 8 carbon atoms (a methyl group, an ethyl group, a propyl group, an isopropyl group, a 2,4-dimethyl-3-cyclohexenyl group, or the like).

In the case where R¹¹ and R^{11′} are a tertiary alkyl group and R¹² and R^{12′} are an alkyl group other than a methyl group, R¹³ is preferably a hydrogen atom.

In the case where R¹¹ and R^{11′} are not a tertiary alkyl group, R¹³ is preferably a hydrogen atom or a secondary alkyl group, and particularly preferably a secondary alkyl group. As the secondary alkyl group for R¹³, an isopropyl group and a 2,4-dimethyl-3-cyclohexenyl group are preferred.

The reducing agent described above shows different thermal development performance, color tone of developed silver images, or the like depending on the combination of R¹¹, R^{11′}, R¹², R^{12′}, and R¹³. Since the performance can be controlled by using two or more reducing agents in combination, it is preferred to use two or more reducing agents in combination depending on the purpose.

Specific examples of the reducing agent according to the invention including the compounds represented by formula (R) are shown below, but the invention is not restricted to these examples.

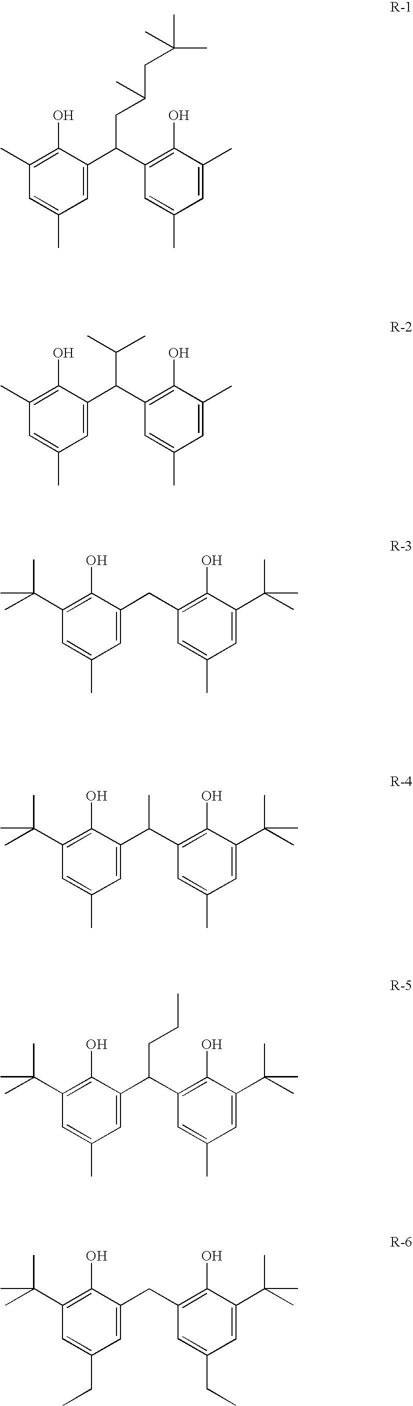

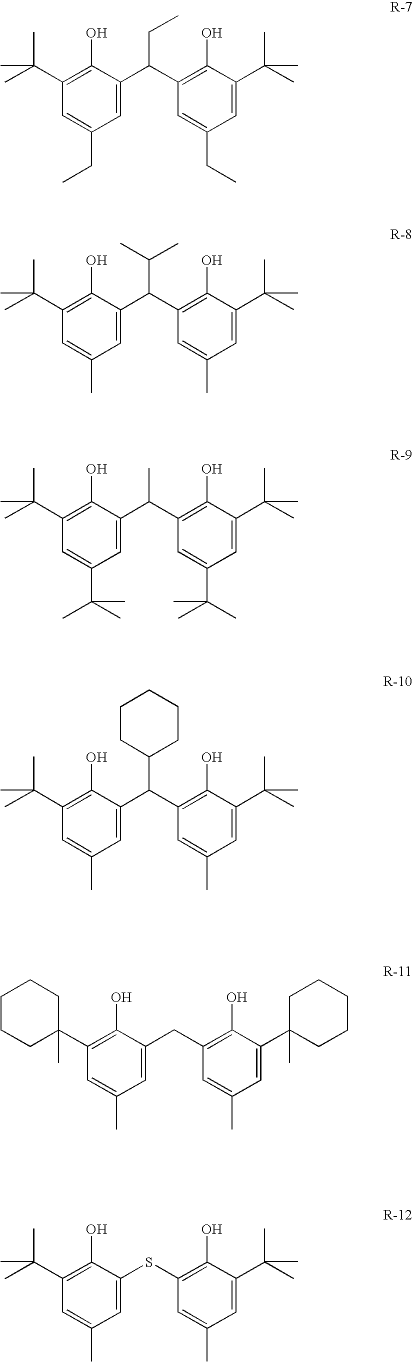

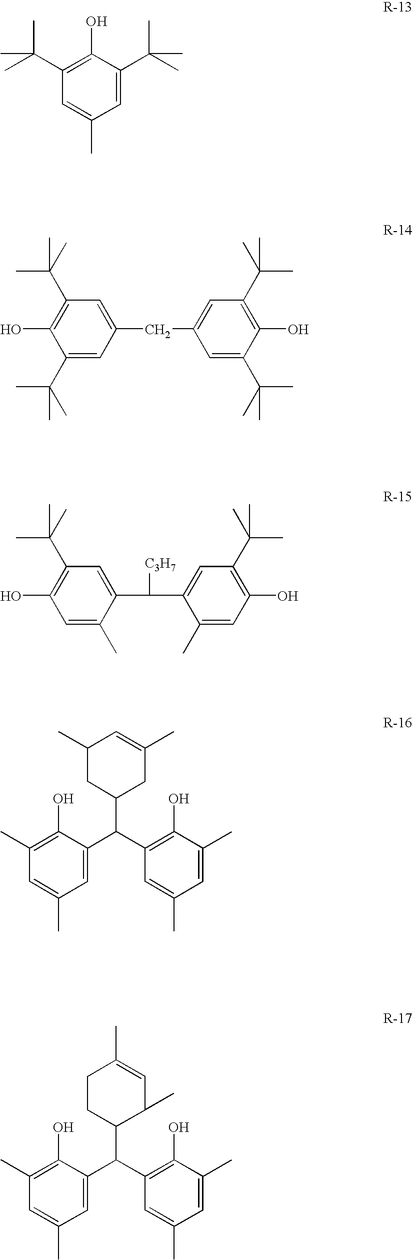

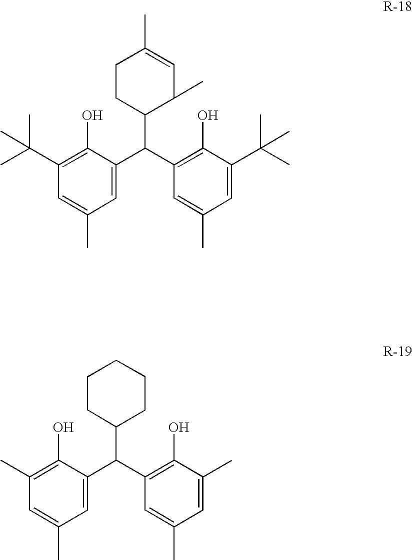

As preferred examples of the reducing agent according to the invention other than those above, there are mentioned compounds described in JP-A Nos. 2001-188314, 2001-209145, 2001-350235, and 2002-156727, and EP No. 1278101A2.

In the present invention, the addition amount of the reducing agent is preferably from 0.1 g/m² to 3.0 g/m², more preferably from 0.2 g/m² to 1.5 g/m² and even more preferably from 0.3 g/m² to 1.0 g/m². It is preferably contained in a range of from 5 mol % to 50 mol %, more preferably from 8 mol % to 30 mol %, and even more preferably from 10 mol % to 20 mol %, with respect to 1 mol of silver on the side having the image forming layer. The reducing agent is preferably contained in the image forming layer.

The reducing agent may be incorporated into the photothermographic material by being contained into the coating solution by any method, such as in the form of a solution, an emulsified dispersion, a solid fine particle dispersion, or the like.

As an emulsified dispersion method that is well known in the technical field, there is mentioned a method comprising dissolving the reducing agent in an oil such as dibutyl phthalate, tricresyl phosphate, glyceryl triacetate, diethyl phthalate, or the like, and an auxiliary solvent such as ethyl acetate, cyclohexanone, or the like, followed by mechanically preparing an emulsified dispersion.

As a solid fine particle dispersion method, there is mentioned a method comprising dispersing the powder of the reducing agent in a proper solvent such as water or the like, by means of ball mill, colloid mill, vibrating ball mill, sand mill, jet mill, roller mill, or ultrasonics, thereby obtaining a solid dispersion. In this process, there may be used a protective colloid (such as poly(vinyl alcohol)), or a surfactant (for instance, an anionic surfactant such as sodium triisopropylnaphthalenesulfonate (a mixture of compounds having the three isopropyl groups in different substitution sites)). In the mills enumerated above, generally used as the dispersion media are beads made of zirconia or the like, and Zr or the like eluting from the beads may be incorporated in the dispersion. Although depending on the dispersing conditions, the amount of Zr or the like incorporated in the dispersion is generally in a range of from 1 ppm to 1000 ppm. It is practically acceptable so long as Zr is incorporated in the photothermographic material in an amount of 0.5 mg or less per 1 g of silver.

Preferably, an antiseptic (for instance, benzisothiazolinone sodium salt) is added in an aqueous dispersion.

The reducing agent is particularly preferably used as a solid particle dispersion, and is added in the form of fine particles having a mean particle size of from 0.01 μm to 10 μm, preferably from 0.05 μm to 5 μm, and more preferably from 0.1 μm to 2 μm. In the application, other solid dispersions are preferably used to be dispersed with this particle size range.

(Photosensitive Silver Halide)

1) Halogen Composition

For the photosensitive silver halide used in the invention, there is no particular restriction on the halogen composition, and silver chloride, silver bromochloride, silver bromide, silver iodobromide, silver iodochlorobromide, or silver iodide can be used. Among these, silver bromide, silver iodobromide, and silver iodide are preferred. The distribution of the halogen composition in a grain may be uniform, the halogen composition may be changed stepwise, or it may be changed continuously. Further, a silver halide grain having a core/shell structure can be used preferably. Preferred structure is a twofold to fivefold structure, and more preferably, a core/shell grain having a twofold to fourfold structure can be used. Further, a technique of localizing silver chloride, silver bromochloride, silver bromide, silver iodobromide, silver iodochlorobromide, or silver iodide at the surface of a silver chloride, silver bromochloride, silver bromide, silver iodobromide, silver iodochlorobromide, or silver iodide grain can also be used preferably.

2) Grain Size

Concerning the grain size of the silver halide used for the invention, when the grain size of the silver halide is large, it is not preferred because transparency of the film after image formation decreases. The grain size of the silver halide is preferably 0.20 μm or less, more preferably in a range of from 0.01 μm to 0.15 μm, and even more preferably from 0.02 μm to 0.12 μm. The grain size as used herein means a diameter of a circle converted such that it has the same area as a projected area of the silver halide grain (projected area of a major plane in the case of a tabular grain).

3) Coating Amount

The coating amount of the silver halide, when expressed by the silver amount, is from 0.03 g/m² to 0.6 g/m², preferably from 0.05 g/m² to 0.4 g/m², and more preferably from 0.07 g/m² to 0.3 g/m². The silver halide is used in an amount of from 0.01 mol to 0.5 mol, preferably from 0.02 mol to 0.3 mol, and more preferably from 0.03 mol to 0.2 mol, with respect to 1 mol of the non-photosensitive organic silver salt described below.

4) Method of Grain Formation

The method of forming photosensitive silver halide is well known in the relevant art and, for example, methods described in Research Disclosure No. 17029, June 1978 and U.S. Pat. No. 3,700,458 can be used. Specifically, a method of preparing a photosensitive silver halide by adding a silver-supplying compound and a halogen-supplying compound in a gelatin or other polymer solution, and then mixing them with an organic silver salt is used. Further, a method described in JP-A No. 11-119374 (paragraph Nos. 0217 to 0224) and methods described in JP-A Nos. 11-352627 and 2000-347335 are also preferred.

For example, a method of halogenating a part of silver of an organic silver salt by an organic halide or inorganic halide, which is called a halidation method, is also preferably used. The organic halide used herein may be any compound as long as it reacts with an organic silver salt to form silver halide, and examples thereof include N-halogenoimide (N-bromosuccinimide or the like), a quaternary nitrogen halogenide compound (tetrabutylammonium bromide or the like), an aggregate of a quaternary nitrogen halogenide salt and a halogen molecule (pyridinium bromide perbromide or the like), and the like. The inorganic halide may be any compound as long as it reacts with an organic silver salt to form silver halide, and examples thereof include an alkaline metal halide or ammonium halide (sodium chloride, lithium bromide, potassium iodide, ammonium bromide, or the like), an alkaline earth metal halide (calcium bromide, magnesium chloride, or the like), a transition metal halide (iron(III) chloride, copper(II) bromide, or the like), a metal complex having halogen ligand (bromoiridium acid sodium salt, chlororhodium acid ammonium salt, or the like), a halogen molecule (bromine, chlorine, or iodine), and the like. Further, a desired organic halide and inorganic halide may be used in combination. The addition amount of the halide upon halidation is preferably from 1 mmol to 500 mmol on the basis of halogen atom per 1 mol of the organic silver salt, and more preferably from 10 mmol to 250 mmol.

The photosensitive silver halide grains can be subjected to desalting by a water-washing method well known in the art such as noodle method, flocculation method, or the like, but in the present invention, the silver halide grains may be or be not subjected to desalting.

5) Grain Shape

The shape of the silver halide grain includes, for example, cubic, octahedral, dodecahedral, tetradecahedral, tabular, spherical, rod-like, and potato-like shape.

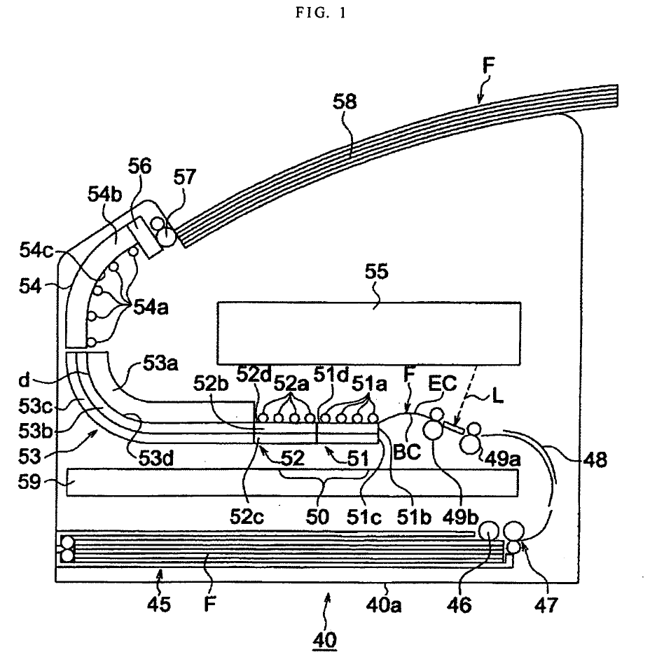

Particularly, a dodecahedral, tetradecahedral, or cubic grain is preferred. The silver halide having high silver iodide content according to the invention can take a complicated form, and as a preferable form, there are listed, for example, a conjugation grain as shown in R. L. JENKINS et al., J. of Phot. Sci., vol. 28, page 164, FIG. 1 (1980). Tabular grains as shown in FIG. 1 of the same literature can also be preferably used. A silver halide grain rounded at corners can also be used preferably. The surface indices (Miller indices) of the outer surface of a photosensitive silver halide grain are not particularly restricted, and it is preferable that the ratio occupied by the {100} face is large, because of showing high spectral sensitization efficiency when a spectral sensitizing dye is adsorbed. The ratio is preferably 50% or higher, more preferably 65% or higher, and even more preferably 80% or higher. The ratio of the {100} face, Miller indices, can be determined by a method utilizing adsorption dependency of the {111} face and {100} face upon adsorption of a sensitizing dye, which is described in T. Tani; J. Imaging Sci., vol. 29, page 165, (1985).

6) Heavy Metal

The photosensitive silver halide grain according to the invention can contain metals or complexes of metals belonging to groups 6 to 13 of the periodic table (showing groups 1 to 18). Preferably, the photosensitive silver halide grain can contain metals or complexes of metals belonging to groups 6 to 10. Preferable specific examples of the metal or the center metal of the metal complex from groups 6 to 10 of the periodic table include rhodium, ruthenium, iridium, and iron. The metal complex may be used alone, or two or more complexes comprising identical or different species of metals may be used in combination. A preferred content is in a range of from 1×10⁻⁹ mol to 1×10⁻³ mol with respect to 1 mol of silver. The heavy metals, metal complexes, and the addition method thereof are described in JP-A No. 7-225449, in paragraph Nos. 0018 to 0024 of JP-A No. 11-65021, and in paragraph Nos. 0227 to 0240 of JP-A No. 11-119374.

In the present invention, a silver halide grain having a hexacyano metal complex present on the outermost surface of the grain is preferred. The hexacyano metal complex includes, for example, [Fe(CN)₆]⁴⁻, [Fe(CN)₆]³⁻, [Ru(CN)₆]⁴⁻, [Os(CN)₆]⁴⁻, [Co(CN)₆]³⁻, [Rh(CN)₆]³⁻, [Ir(CN)₆]³⁻, [Cr(CN)₆]³⁻, and [Re(CN)₆]³⁻. In the invention, hexacyano Fe complex is preferred.

Since the hexacyano metal complex exists in an ionic form in an aqueous solution, counter cation is not important, but an alkaline metal ion such as sodium ion, potassium ion, rubidium ion, cesium ion, or lithium ion, ammonium ion, or an alkyl ammonium ion (for example, tetramethyl ammonium ion, tetraethyl ammonium ion, tetrapropyl ammonium ion, or tetra(n-butyl) ammonium ion), which is easily miscible with water and suitable to precipitation operation of silver halide emulsion, is preferably used.

The hexacyano metal complex can be added while being mixed with water, as well as a mixed solvent of water and an appropriate organic solvent miscible with water (for example, alcohols, ethers, glycols, ketones, esters, amides, or the like) or gelatin.

The addition amount of the hexacyano metal complex is preferably from 1×10⁻⁵ mol to 1×10⁻² mol, and more preferably from 1×10⁻⁴ mol to 1×10⁻³ mol, per 1 mol of silver.

In order to allow the hexacyano metal complex to be present on the outermost surface of a silver halide grain, the hexacyano metal complex is directly added in any stage of: after completion of addition of an aqueous solution of silver nitrate used for grain formation; before completion of an emulsion formation step prior to a chemical sensitization step of conducting chalcogen sensitization such as sulfur sensitization, selenium sensitization, or tellurium sensitization, or noble metal sensitization such as gold sensitization; during a washing step; during a dispersion step; and before a chemical sensitization step. In order not to grow fine silver halide grains, the hexacyano metal complex is preferably added rapidly after the grain is formed, and it is preferably added before completion of the emulsion formation step.

Addition of the hexacyano metal complex may be started after addition of 96% by weight of an entire amount of silver nitrate to be added for grain formation, more preferably started after addition of 98% by weight, and particularly preferably, started after addition of 99% by weight.

When any of the hexacyano metal complexes is added after addition of an aqueous solution of silver nitrate just prior to completion of grain formation, it can be adsorbed to the outermost surface of the silver halide grain, and most of the complex forms an insoluble salt with silver ions on the surface of the grain. Since silver hexacyanoferrate (II) is a salt less soluble than silver iodide, re-dissolution with fine grains can be prevented, and it becomes possible to prepare fine silver halide grains with smaller grain size.

Metal atoms that can be contained in the silver halide grain used in the invention (for example, [Fe(CN)₆]⁴⁻), and the desalting method and chemical sensitizing method of silver halide emulsion are described in paragraph Nos. 0046 to 0050 of JP-A No. 11-84574, in paragraph Nos. 0025 to 0031 of JP-A No. 11-65021, and in paragraph Nos. 0242 to 0250 of JP-A No. 11-119374.

7) Gelatin

As the gelatin which is contained in the photosensitive silver halide emulsion used in the invention, various types of gelatin can be used. It is necessary to maintain an excellent dispersion state of a photosensitive silver halide emulsion in the coating solution containing an organic silver salt, and gelatin having a molecular weight of 10,000 to 1,000,000 is preferably used. Phthalated gelatin is also preferably used. The gelatin may be used at the time of grain formation or at the time of dispersion after desalting treatment, and it is preferably used at the time of grain formation.

8) Chemical Sensitization

The photosensitive silver halide grain according to the invention is preferably chemically sensitized by sulfur sensitizing method, selenium sensitizing method, or tellurium sensitizing method. As the compounds used preferably for sulfur sensitizing method, selenium sensitizing method, and tellurium sensitizing method, known compounds, for example, compounds described in JP-A No. 7-128768 and the like can be used. Particularly, tellurium sensitization is preferred in the invention, and compounds described in the literature cited in paragraph No. 0030 in JP-A No. 11-65021 and compounds represented by formula (II), (III), or (IV) in JP-A No. 5-313284 are more preferred.

The amount of sulfur, selenium, or tellurium sensitizer used in the invention may vary depending on the silver halide grain used, the chemical ripening condition, and the like, and it is used in an amount of from 10⁻⁸ mol to 10⁻² mol, and preferably from 10⁻⁷ mol to 10⁻³ mol, per 1 mol of silver halide.

The photosensitive silver halide grain according to the invention may be chemically sensitized by gold sensitizing method in combination with the chalcogen sensitization described above. As the gold sensitizer, those having an oxidation number of gold of either +1 or +3 are preferred.

As representative examples, chloroauric acid, bromoauric acid, potassium chloroaurate, potassium bromoaurate, auric trichloride, potassium auric thiocyanate, potassium iodoaurate, tetracyanoauric acid, ammonium aurothiocyanate, pyridyl trichloro gold, and the like are preferred. Further, gold sensitizers described in U.S. Pat. No. 5,858,637 and JP-A No. 2002-278016 are also used preferably.

The addition amount of the gold sensitizer to be used in combination may vary depending on various conditions, but it is generally from 10⁻⁷ mol to 10⁻³ mol, and preferably from 10⁻⁶ mol to 5×10⁻⁴ mol, per 1 mol of silver halide.

In the invention, chemical sensitization can be applied at any time so long as it is after grain formation and before coating, and it can be applied, after desalting, (1) before spectral sensitization, (2) simultaneously with spectral sensitization, (3) after spectral sensitization, (4) just prior to coating, or the like.

There is no particular restriction on the conditions for the chemical sensitization in the invention, and appropriately, the pH is from 5 to 8, the pAg is from 6 to 11, and the temperature is from 40° C. to 95° C.

In the silver halide emulsion used in the invention, a thiosulfonic acid compound may be added by the method shown in EP-A No. 293,917.

The photosensitive silver halide grain according to the invention may also be subjected to reduction sensitization. As the reduction sensitizer, ascorbic acid or thiourea dioxide is preferred, as well as use of stannous chloride, aminoimino methane sulfonic acid, a hydrazine derivative, a borane compound, a silane compound, a polyamine compound, or the like is preferred. The reduction sensitizer may be added at any stage in the photosensitive emulsion production process from crystal growth to the preparation step just prior to coating. Further, it is preferred to apply reduction sensitization by ripening while keeping the pH to 7 or higher or the pAg to 8.3 or lower for the emulsion, and it is also preferred to apply reduction sensitization by introducing a single addition portion of silver ions during grain formation.

9) Compound that is One-Electron-Oxidized to Provide a One-Electron Oxidation Product which Releases One or More Electrons

The photothermographic material of the present invention preferably contains a compound that is one-electron-oxidized to provide a one-electron oxidation product which releases one or more electrons. The said compound can be used alone or in combination with various chemical sensitizers described above to increase the sensitivity of silver halide.

The compound that is one-electron-oxidized to provide a one-electron oxidation product which releases one or more electrons, which is contained in the photothermographic material of the invention, is a compound selected from the following Groups 1 or 2.

(Group 1) a compound that is one-electron-oxidized to provide a one-electron oxidation product which further releases one or more electrons due to being subjected to a subsequent bond cleavage reaction;

(Group 2) a compound that is one-electron-oxidized to provide a one-electron oxidation product which further releases one or more electrons after being subjected to a subsequent bond formation reaction.

The compound of Group 1 will be explained below.

In the compound of Group 1, as a compound that is one-electron-oxidized to provide a one-electron oxidation product which further releases one electron due to being subjected to a subsequent bond cleavage reaction, specific examples include examples of compound referred to as “one photon two electrons sensitizer” or “deprotonating electron-donating sensitizer” described in JP-A No. 9-211769 (specific examples: Compound PMT-1 to S-37 in Tables E and F, pages 28 to 32); JP-A No. 9-211774; JP-A No. 11-95355 (specific examples: Compound INV 1 to 36); JP-W No. 2001-500996 (specific examples: Compound 1 to 74, 80 to 87, and 92 to 122); U.S. Pat. Nos. 5,747,235 and 5,747,236; EP No. 786692A1 (specific examples: Compound INV 1 to 35); EP No. 893732A1; U.S. Pat. Nos. 6,054,260 and 5,994,051; etc. Preferred ranges of these compounds are the same as the preferred ranges described in the quoted specifications.

In the compound of Group 1, as a compound that is one-electron-oxidized to provide a one-electron oxidation product which further releases one or more electrons due to being subjected to a subsequent bond cleavage reaction, specific examples include the compounds represented by formula (1) (same as formula (1) described in JP-A No. 2003-114487), formula (2) (same as formula (2) described in JP-A No. 2003-114487), formula (3) (same as formula (1) described in JP-A No. 2003-114488), formula (4) (same as formula (2) described in JP-A No. 2003-114488), formula (5) (same as formula (3) described in JP-A No. 2003-114488), formula (6) (same as formula (1) described in JP-A No. 2003-75950), formula (7) (same as formula (2) described in JP-A No. 2003-75950), and formula (8) (same as formula (1) described in JP-A No. 2004-239943), and the compound represented by formula (9) (same as formula (3) described in JP-A No. 2004-245929) among the compounds which can undergo the reaction represented by chemical reaction formula (1) (same as chemical reaction formula (1) described in JP-A No. 2004-245929). Preferable ranges of these compounds are the same as the preferable ranges described in the quoted specifications.

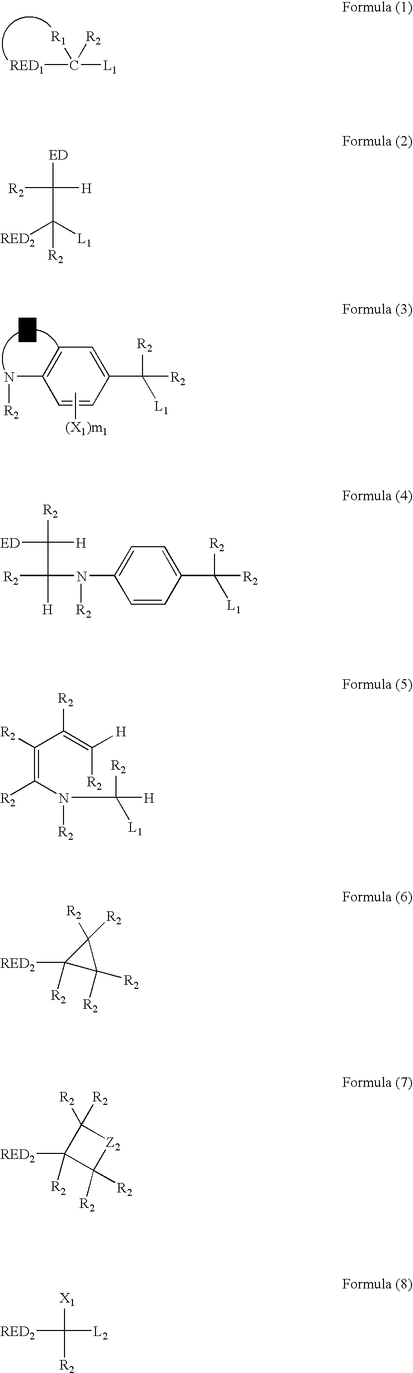

### Chemical Reaction Formula (1)

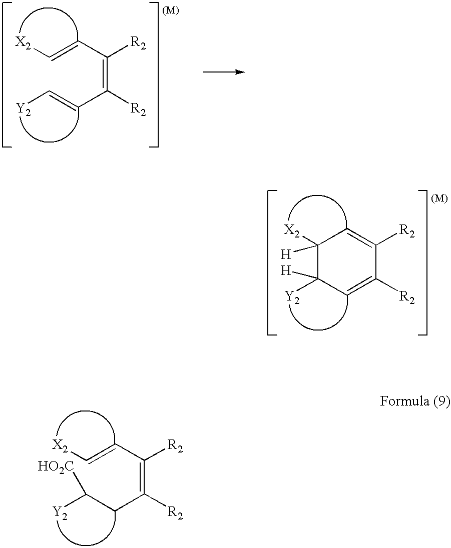

In the formulae, RED₁ and RED₂ represent a reducing group. R₁ represents a nonmetallic atomic group which forms a cyclic structure equivalent to a tetrahydro derivative or octahydro derivative of a 5- or 6-membered aromatic ring (including an aromatic heterocycle) with the carbon atom (C) and RED₁. R₂ represents a hydrogen atom or a substituent. In the case where plural R₂s exist in the same molecule, these may be identical or different from each other. L₁ represents a leaving group. ED represents an electron-donating group. Z₁ represents an atomic group which forms a 6-membered ring with a nitrogen atom and two carbon atoms of the benzene ring. X₁ represents a substituent, and m₁ represents an integer of from 0 to 3. Z₂ represents —CR₁₁R₁₂—, —NR₁₃—, or —O—.

R₁₁ and R₁₂ each independently represent a hydrogen atom or a substituent. R₁₃ represents a hydrogen atom, an alkyl group, an aryl group, or a heterocyclic group. X₁ represents one selected from an alkoxy group, an aryloxy group, a heterocyclic oxy group, an alkylthio group, an arylthio group, a heterocyclic thio group, an alkylamino group, an arylamino group, or a heterocyclic amino group. L₂ represents a carboxy group or a salt thereof, or a hydrogen atom. X₂ represents a group which forms a 5-membered heterocycle with C═C. Y₂ represents a group which forms a 5- or 6-membered aryl group or heterocyclic group with C═C. M represents a radical, a radical cation, or a cation.

Next, the compound of Group 2 is explained.

In the compound of Group 2, as a compound that is one-electron-oxidized to provide a one-electron oxidation product which further releases one or more electrons after being subjected to a subsequent bond formation reaction, specific examples include the compound represented by formula (10) (same as formula (1) described in JP-A No. 2003-140287), and the compound represented by formula (11) (same as formula (2) described in JP-A No. 2004-245929) which can undergo the chemical reaction represented by chemical reaction formula (1) (same as chemical reaction formula (1) described in JP-A No. 2004-245929). Preferable ranges of these compounds are the same as the preferable ranges described in the quoted specifications.

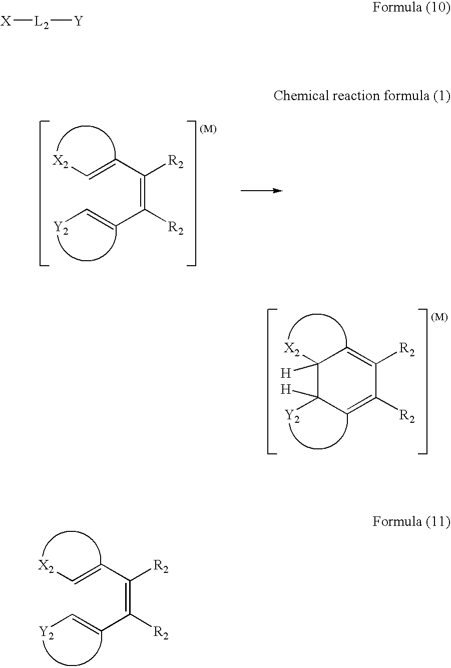

In the formulae, X represents a reducing group which is to be one-electron-oxidized. Y represents a reactive group containing a carbon-carbon double bond part, a carbon-carbon triple bond part, an aromatic group part, or a benzo-condensed non-aromatic heterocycle part, which reacts with one-electron-oxidized product formed by one-electron-oxidation of X to form a new bond. L₂ represents a linking group to link X and Y. R₂ represents a hydrogen atom or a substituent. In the case where plural R₂s exist in a same molecule, these may be identical or different from one another. X₂ represents a group which forms a 5-membered heterocycle with C═C. Y₂ represents a group which forms a 5- or 6-membered aryl group or heterocyclic group with C═C. M represents a radical, a radical cation, or a cation.

The compounds of Groups 1 or 2 are preferably “the compound having an adsorptive group to silver halide in the molecule” or “the compound having a partial structure of a spectral sensitizing dye in the molecule”. The representative adsorptive group to silver halide is the group described in JP-A No. 2003-156823, page 16 right, line 1 to page 17 right, line 12. The partial structure of a spectral sensitizing dye is the structure described in the same specification, page 17 right, line 34 to page 18 left, line 6.

As the compound of Groups 1 or 2, “the compound having at least one adsorptive group to silver halide in the molecule” is more preferred, and “the compound having two or more adsorptive groups to silver halide in the same molecule” is even more preferred. In the case where two or more adsorptive groups exist in a single molecule, those adsorptive groups may be identical or different from one another.

As preferable adsorptive group, a mercapto-substituted nitrogen-containing heterocyclic group (e.g., a 2-mercaptothiadiazole group, a 3-mercapto-1,2,4-triazole group, a 5-mercaptotetrazole group, a 2-mercapto-1,3,4-oxadiazole group, a 2-mercaptobenzoxazole group, a 2-mercaptobenzothiazole group, a 1,5-dimethyl-1,2,4-triazolium-3-thiolate group, or the like) or a nitrogen-containing heterocyclic group having an —NH— group, which forms silver iminate (—N(Ag)—), as a partial structure of the heterocycle (e.g., a benzotriazole group, a benzimidazole group, an indazole group, or the like) are described. A 5-mercaptotetrazole group, a 3-mercapto-1,2,4-triazole group, and a benzotriazole group are particularly preferable, and a 3-mercapto-1,2,4-triazole group and a 5-mercaptotetrazole group are most preferable.

The case where the adsorptive group has two or more mercapto groups as a partial structure in the molecule is also particularly preferable. Herein, the mercapto group (—SH) may become a thione group in the case where it can tautomerize. Preferred examples of the adsorptive group having two or more mercapto groups as a partial structure (dimercapto-substituted nitrogen-containing heterocyclic group and the like) include a 2,4-dimercaptopyrimidine group, a 2,4-dimercaptotriazine group, and a 3,5-dimercapto-1,2,4-triazole group.

Further, a quaternary salt structure of nitrogen or phosphorus is also preferably used as the adsorptive group. Specific examples of the quaternary salt structure of nitrogen include an ammonio group (a trialkylammonio group, a dialkylarylammonio group, a dialkylheteroarylammonio group, an alkyldiarylammonio group, an alkyldiheteroarylammonio group, or the like) and a nitrogen-containing heterocyclic group containing a quaternary nitrogen atom. Examples of the quaternary salt structure of phosphorus include a phosphonio group (a trialkylphosphonio group, a dialkylarylphosphonio group, a dialkylheteroarylphosphonio group, an alkyldiarylphosphonio group, an alkyldiheteroarylphosphonio group, a triarylphosphonio group, a triheteroarylphosphonio group, or the like). A quaternary salt structure of nitrogen is more preferably used, and a 5- or 6-membered nitrogen-containing aromatic heterocyclic group containing a quaternary nitrogen atom is even more preferably used. Particularly preferably, a pyridinio group, a quinolinio group, or an isoquinolinio group is used. These nitrogen-containing heterocyclic groups containing a quaternary nitrogen atom may have any substituent.

Examples of a counter anion of the quaternary salt include a halogen ion, carboxylate ion, sulfonate ion, sulfate ion, perchlorate ion, carbonate ion, nitrate ion, BF₄⁻, PF₆⁻, Ph₄B⁻, and the like. In the case where the group having negative charge at carboxylate group or the like exists in the molecule, an inner salt may be formed with it. As a counter anion outside of the molecule, chloro ion, bromo ion, or methanesulfonate ion is particularly preferable.

Preferable structure of the compound represented by Groups 1 or 2 having a quaternary salt structure of nitrogen or phosphorus as the adsorptive group is represented by formula (X).

(P-Q₁-)ᵢ-R(-Q₂-S)ⱼ Formula (X)

In formula (X), P and R each independently represent a quaternary salt structure of nitrogen or phosphorus, which is not a partial structure of a spectral sensitizing dye. Q₁ and Q₂ each independently represent a linking group and typically represent a single bond, an alkylene group, an arylene group, a heterocyclic group, —O—, —S—, —NRN, —C(═O)—, —SO₂—, —SO—, —P(═O)— or combinations of these groups. Herein, R_{N} represents a hydrogen atom, an alkyl group, an aryl group, or a heterocyclic group. S represents a residue which is obtained by removing one atom from the compound represented by Group 1 or 2. i and j are an integer of one or more and are selected from within a range satisfying i+j=2 to 6. The case where i is 1 to 3 and j is 1 or 2 is preferable, the case where i is 1 or 2 and j is 1 is more preferable, and the case where i is 1 and j is 1 is particularly preferable. The compound represented by formula (X) preferably has 10 to 100 carbon atoms in total, more preferably 10 to 70 carbon atoms, even more preferably 11 to 60 carbon atoms, and particularly preferably 12 to 50 carbon atoms in total.

The compounds of Groups 1 or 2 may be used at any time during preparation of the photosensitive silver halide emulsion and production of the photothermographic material. For example, the compound may be used in a photosensitive silver halide grain formation step, in a desalting step, in a chemical sensitization step, before coating, or the like. The compound may be added several times during these steps. The compound is preferably added after completion of the photosensitive silver halide grain formation step and before the desalting step; in the chemical sensitization step (just before initiation of the chemical sensitization to immediately after completion of the chemical sensitization); or before coating. The compound is more preferably added within a period from the chemical sensitization to before being mixed with the non-photosensitive organic silver salt.

It is preferred that the compound of Groups 1 or 2 according to the invention is added by being dissolved in water, a water-soluble solvent such as methanol or ethanol, or a mixed solvent thereof. In the case where the compound is dissolved in water and solubility of the compound is increased by increasing or decreasing a pH value of the solvent, the pH value may be increased or decreased to dissolve and add the compound.

The compound of Groups 1 or 2 according to the invention is preferably used in the image forming layer which contains the photosensitive silver halide and the non-photosensitive organic silver salt. The compound may be added to a protective layer or intermediate layer, as well as the image forming layer containing the photosensitive silver halide and the non-photosensitive organic silver salt, to be diffused in the coating step. The compound may be added before or after addition of a sensitizing dye. The compound is contained in the silver halide emulsion layer (image forming layer) preferably in an amount of from 1×10⁻⁹ mol to 5×10⁻¹ mol, and more preferably from 1×10⁻⁸ mol to 5×10⁻² mol, per 1 mol of silver halide.

10) Compound Having Adsorptive Group and Reducing Group

The photothermographic material of the present invention preferably contains a compound having an adsorptive group to silver halide and a reducing group in the molecule. It is preferred that the compound is represented by the following formula (I).

A-(W)n-B Formula (I)

In formula (I), A represents a group which adsorbs to a silver halide (hereafter, it is called an adsorptive group); W represents a divalent linking group; n represents 0 or 1; and B represents a reducing group.

In formula (I), the adsorptive group represented by A is a group to adsorb directly to a silver halide or a group to promote adsorption to a silver halide. As typical examples, a mercapto group (or a salt thereof); a thione group (—C(═S)—); a heterocyclic group comprising at least one atom selected from among nitrogen, sulfur, selenium, and tellurium; a sulfide group; a disulfide group; a cationic group; an ethynyl group, and the like are described.

The mercapto group (or the salt thereof) as the adsorptive group means a mercapto group (or a salt thereof) itself and simultaneously more preferably represents a heterocyclic group, aryl group, or alkyl group substituted by at least one mercapto group (or a salt thereof). Herein, the heterocyclic group is at least a 5- to 7-membered, monocyclic or condensed, aromatic or non-aromatic heterocyclic group; and examples thereof include an imidazole ring group, a thiazole ring group, an oxazole ring group, a benzimidazole ring group, a benzothiazole ring group, a benzoxazole ring group, a triazole ring group, a thiadiazole ring group, an oxadiazole ring group, a tetrazole ring group, a purine ring group, a pyridine ring group, a quinoline ring group, an isoquinoline ring group, a pyrimidine ring group, a triazine ring group, and the like. Further, a heterocyclic group having a quaternary nitrogen atom may also be adopted, wherein the mercapto group as a substituent may dissociate to form a mesoion. When the mercapto group forms a salt, a counter ion of the salt may be a cation of an alkaline metal, alkaline earth metal, heavy metal, or the like, such as Li⁺, Na⁺, K⁺, Mg²⁺, Ag⁺, or Zn²⁺; an ammonium ion; a heterocyclic group containing a quaternary nitrogen atom; a phosphonium ion, or the like.

Furthermore, the mercapto group as the adsorptive group may become a thione group by tautomerization.

The thione group used as the adsorptive group also includes a chain or cyclic thioamido group, thioureido group, thiourethane group, and dithiocarbamic acid ester group.

The heterocyclic group, as the adsorptive group, which comprises at least one atom selected from among nitrogen, sulfur, selenium, and tellurium, represents a nitrogen-containing heterocyclic group having an —NH— group, which forms silver iminate (—N(Ag)—), as a partial structure of the heterocycle, or a heterocyclic group having an —S— group, —Se— group, —Te— group, or ═N— group, which coordinates to a silver ion by a coordination bond, as a partial structure of the heterocycle. As the former examples, a benzotriazole group, a triazole group, an indazole group, a pyrazole group, a tetrazole group, a benzimidazole group, an imidazole group, a purine group, and the like are described. As the latter examples, a thiophene group, a thiazole group, an oxazole group, a benzothiophene group, a benzothiazole group, a benzoxazole group, a thiadiazole group, an oxadiazole group, a triazine group, a selenoazole group, a benzoselenoazole group, a tellurazole group, a benzotellurazole group, and the like are described.

The sulfide group or disulfide group as the adsorptive group contains all groups having “—S—” or “—S—S—” as a partial structure.

The cationic group as the adsorptive group means a group containing a quaternary nitrogen atom, specifically such as an ammonio group or a nitrogen-containing heterocyclic group containing a quaternary nitrogen atom. As examples of the nitrogen-containing heterocyclic group containing a quaternary nitrogen atom, a pyridinio group, a quinolinio group, an isoquinolinio group, an imidazolio group, and the like are described.

The ethynyl group as the adsorptive group means —C≡CH group and the said hydrogen atom may be substituted.

The adsorptive group described above may have any substituent.

Further, as typical examples of the adsorptive group, the groups described in pages 4 to 7 in the specification of JP-A No. 11-95355 are described.

As the adsorptive group represented by A in formula (I), a mercapto-substituted heterocyclic group (for example, a 2-mercaptothiadiazole group, a 2-mercapto-5-aminothiadiazole group, a 3-mercapto-1,2,4-triazole group, a 5-mercaptotetrazole group, a 2-mercapto-1,3,4-oxadiazole group, a 2-mercaptobenzimidazole group, a 1,5-dimethyl-1,2,4-triazolium-3-thiolate group, a 2,4-dimercaptopyrimidine group, a 2,4-dimercaptotriazine group, a 3,5-dimercapto-1,2,4-triazole group, a 2,5-dimercapto-1,3-thiazole group, or the like) and a nitrogen-containing heterocyclic group having an —NH— group, which forms silver iminate (—N(Ag)—), as a partial structure of the heterocycle (for example, a benzotriazole group, a benzimidazole group, an indazole group, or the like) are preferable, and more preferable as the adsorptive group are a 2-mercaptobenzimidazole group and a 3,5-dimercapto-1,2,4-triazole group.

In formula (I), W represents a divalent linking group. The said linking group may be any divalent linking group as long as it does not exert adverse influences on photographic performance. For example, a divalent linking group which is formed from carbon, hydrogen, oxygen, nitrogen, or sulfur can be used. Specific examples thereof include an alkylene group having 1 to 20 carbon atoms (for example, a methylene group, an ethylene group, a trimethylene group, a tetramethylene group, a hexamethylene group, or the like), an alkenylene group having 2 to 20 carbon atoms, an alkynylene group having 2 to 20 carbon atoms, an arylene group having 6 to 20 carbon atoms (for example, a phenylene group, a naphthylene group, or the like), —CO—, —SO₂—, —O—, —S—, —NR₁—, and combinations of these linking groups. Herein, R₁ represents a hydrogen atom, an alkyl group, a heterocyclic group, or an aryl group.

The linking group represented by W may have any substituent.

In formula (I), the reducing group represented by B represents a group which reduces a silver ion. Examples thereof include a formyl group; an amino group; a triple bond group such as an acetylene group, a propargyl group, or the like; a mercapto group; and residues which are obtained by removing one hydrogen atom from hydroxyamines, hydroxamic acids, hydroxyureas, hydroxyurethanes, hydroxysemicarbazides, reductones (including reductone derivatives), anilines, phenols (including chroman-6-ols, 2,3-dihydrobenzofuran-5-ols, aminophenols, sulfonamido phenols, and polyphenols such as hydroquinones, catechols, resorcinols, benzenetriols, bisphenols), acylhydrazines, carbamoylhydrazines, 3-pyrazolidones, and the like. They may have any substituent.

The oxidation potential of the reducing group represented by B in formula (I) can be measured by using the measuring method described in Akira Fujishima, “DENKIKAGAKU SOKUTEIHO”, pages 150 to 208, GIHODO SHUPPAN and The Chemical Society of Japan, “JIKKEN KAGAKU KOZA”, 4th ed., vol. 9, pages 282 to 344, MARUZEN. For example, the method of rotating disc voltammetry can be used; namely the sample is dissolved in the solution (methanol: pH 6.5 Britton-Robinson buffer=10%:90% (% by volume)) and after bubbling with nitrogen gas for 10 minutes, the voltamograph can be measured under conditions of 1000 rotations/minute, sweep rate of 20 mV/second, at 25° C. by using a rotating disc electrode (RDE) made by glassy carbon as a working electrode, a platinum electrode as a counter electrode, and a saturated calomel electrode as a reference electrode. The half wave potential (E1/2) can be calculated by that obtained voltamograph.

When the reducing group represented by B in the present invention is measured by the method described above, the oxidation potential is preferably in a range of from about −0.3 V to about 1.0 V, more preferably from about −0.1 V to about 0.8 V, and particularly preferably from about 0 V to about 0.7 V.

In formula (I), the reducing group represented by B is preferably a residue which is obtained by removing one hydrogen atom from hydroxyamines, hydroxamic acids, hydroxyureas, hydroxysemicarbazides, reductones, phenols, acylhydrazines, carbamoylhydrazines, or 3-pyrazolidones.

The compound of formula (I) according to the present invention may have a ballast group or polymer chain, which are generally used in the non-moving photographic additives such as a coupler or the like, in it. And as the polymer, for example, the polymer described in JP-A No. 1-100530 is described.

The compound of formula (I) according to the present invention may be bis or tris type of compound. The molecular weight of the compound represented by formula (I) according to the present invention is preferably within a range of from 100 to 10000, more preferably from 120 to 1000, and particularly preferably from 150 to 500.

Specific examples of the compound represented by formula (I) according to the present invention are shown below, but the present invention is not limited to these examples.

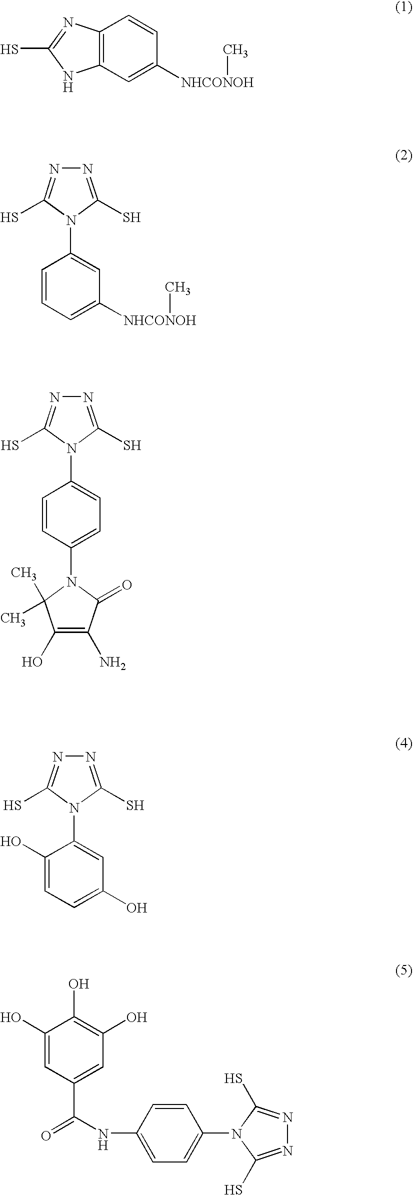

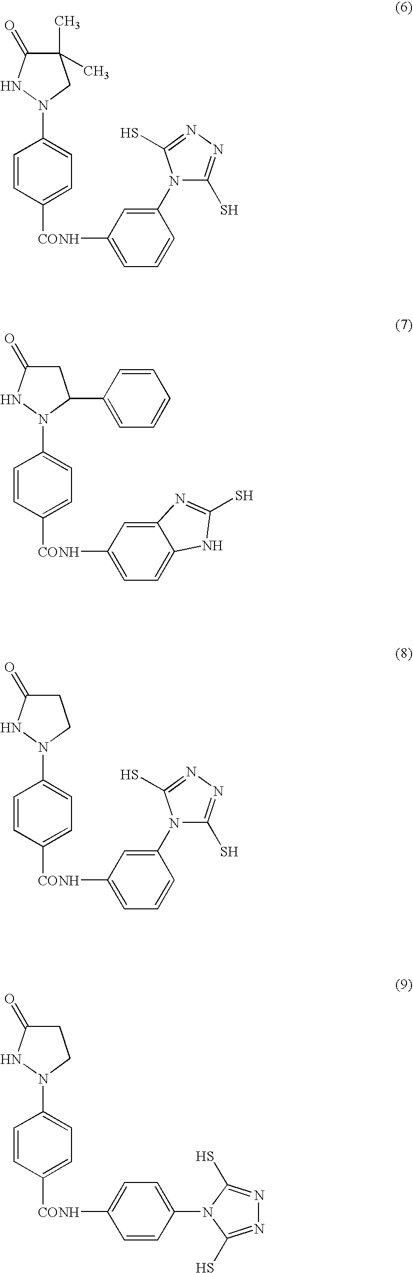

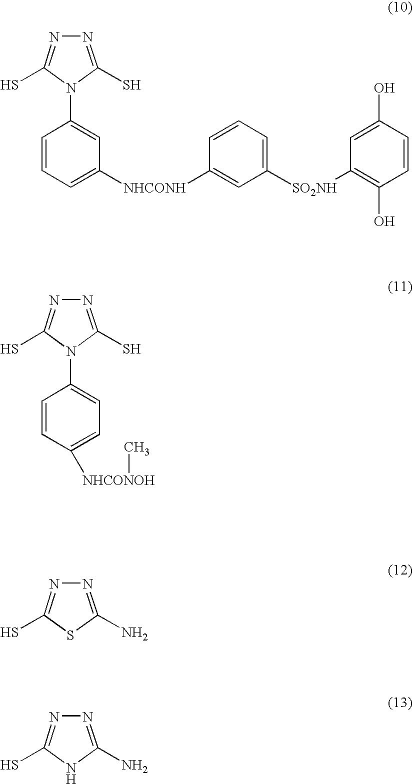

Further, specific compounds 1 to 30 and 1″-1 to 1″-77 shown in EP No. 1308776A2, pages 73 to 87 are also described as preferable examples of the compound having an adsorptive group and a reducing group according to the invention.

These compounds can be easily synthesized by a known method in the technical field. The compound of formula (I) according to the present invention may be used alone, but it is preferred to use two or more of the compounds simultaneously. When two or more of the compounds are used, those compounds may be added to the same layer or different layers, whereby addition methods may be different from each other.

The compound represented by formula (I) according to the present invention is preferably added to the silver halide emulsion layer (image forming layer) and more preferably, the compound represented by formula (I) is added at the time of emulsion preparation. In the case where the compound is added at the time of emulsion preparation, the compound can be added at any stage in the process. For example, the compound can be added during the silver halide grain formation step; before starting of desalting step; during the desalting step; before starting of chemical ripening; during the chemical ripening step; in the step before preparing a final emulsion, or the like. The compound can be added several times during these steps. It is preferred to use the compound in the image forming layer. But the compound may be added to a protective layer or intermediate layer adjacent to the image forming layer, in combination with its addition to the image forming layer, to be diffused in the coating step.

The preferred addition amount is largely dependent on the addition method described above or the type of the compound, but is generally from 1×10⁻⁶ mol to 1 mol, preferably from 1×10⁻⁵ mol to 5×10⁻¹ mol, and more preferably from 1×10⁻⁴ mol to 1×10⁻¹ mol, per 1 mol of photosensitive silver halide in each case.

The compound represented by formula (I) according to the present invention can be added by being dissolved in water, a water-soluble solvent such as methanol, ethanol and the like, or a mixed solvent thereof. In this process, the pH may be arranged suitably by an acid or a base, and a surfactant may coexist. Further, these compounds can be added as an emulsified dispersion by dissolving them in an organic solvent having a high boiling point, and also can be added as a solid dispersion.

11) Combined Use of Silver Halides

The photosensitive silver halide emulsion in the photothermographic material used for the invention may be used alone, or two or more of them (for example, those having different mean grain sizes, different halogen compositions, different crystal habits, or different conditions for chemical sensitization) may be used together. Gradation can be controlled by using plural types of photosensitive silver halides each having different sensitivity. The relevant techniques include those described, for example, in JP-A Nos. 57-119341, 53-106125, 47-3929, 48-55730, 46-5187, 50-73627, and 57-150841. It is preferred to provide a sensitivity difference of 0.2 or more in terms of log E between each of the emulsions.

12) Mixing Silver Halide and Organic Silver Salt

The photosensitive silver halide grains according to the present invention can be prepared by a conversion method such as described above, but the photosensitive silver halide grains are particularly preferably formed under the absence of the non-photosensitive organic silver salt and chemically sensitized.

The organic silver salt is prepared by adding an alkaline metal salt (for example, sodium hydroxide, potassium hydroxide, or the like) to an organic acid so that at least a part of the organic acid is converted to an alkaline metal soap of the organic acid, followed by adding a water-soluble silver salt (for example, silver nitrate). The photosensitive silver halide can be added at any of these steps. The main mixing step include the following four steps: A) adding the silver halide to the organic acid in advance, then adding the alkaline metal salt, and thereafter adding the water-soluble silver salt; B) mixing the silver halide after preparing the alkaline metal soap of the organic acid, and then adding the water-soluble silver salt; C) preparing an alkaline metal soap of the organic acid and converting a part thereof to silver salt, then adding the silver halide, and thereafter, converting the remaining part to silver salt; D) mixing the silver halide after preparing the organic silver salt. B) and C) are preferable.

The organic silver salt including the silver halide is preferably used by being dispersed to fine particles. As a means for dispersion to fine particles, a high speed stirrer, ball mill, sand mill, colloid mill, vibration mill, high-pressure homogenizer, or the like can be used.

13) Mixing Silver Halide into Coating Solution

In the invention, the time of adding silver halide to the coating solution for the image forming layer is preferably in a range of from 180 minutes before coating to just prior to coating, and more preferably 60 minutes before coating to 10 seconds before coating. However, so long as the effects of the invention are sufficiently realized, there is no particular restriction concerning the mixing method and the conditions of mixing. As a specific mixing method, there is a method of mixing in a tank and controlling an average residence time. The average residence time herein is calculated from addition flux and the amount of solution transferred to the coater. And another mixing method is a method using a static mixer, which is described in 8th chapter or the like of “Ekitai Kongo Gijutu” by N. Harnby, M. F. Edwards, and A. W. Nienow, translated by Koji Takahashi (Nikkan Kogyo Shinbunsha, 1989).

(Spectral Sensitizing Dye)

The photothermographic material of the present invention is preferably sensitized by a spectral sensitizing dye. Preferably, the photothermographic material of the present invention is spectrally sensitized to have a sensitization maximum wavelength within a range of from 700 nm to 1400 nm. Particularly preferably, it is spectrally sensitized to have a sensitization maximum in the infrared region of from 750 nm to 900 nm.

The spectral sensitizing dye which can be used in the photothermographic material of the present invention may be any dye as long as it has a spectral sensitization maximum wavelength within the above range, but particularly, the spectral sensitizing dye is preferably at least one spectral sensitizing dye represented by a formula selected from the group consisting of formulae (3a) to (3d). Next, the spectral sensitizing dye represented by formula (3a) to (3d) (hereinafter, sometimes referred to as the infrared photosensitive dye) will be described in detail.

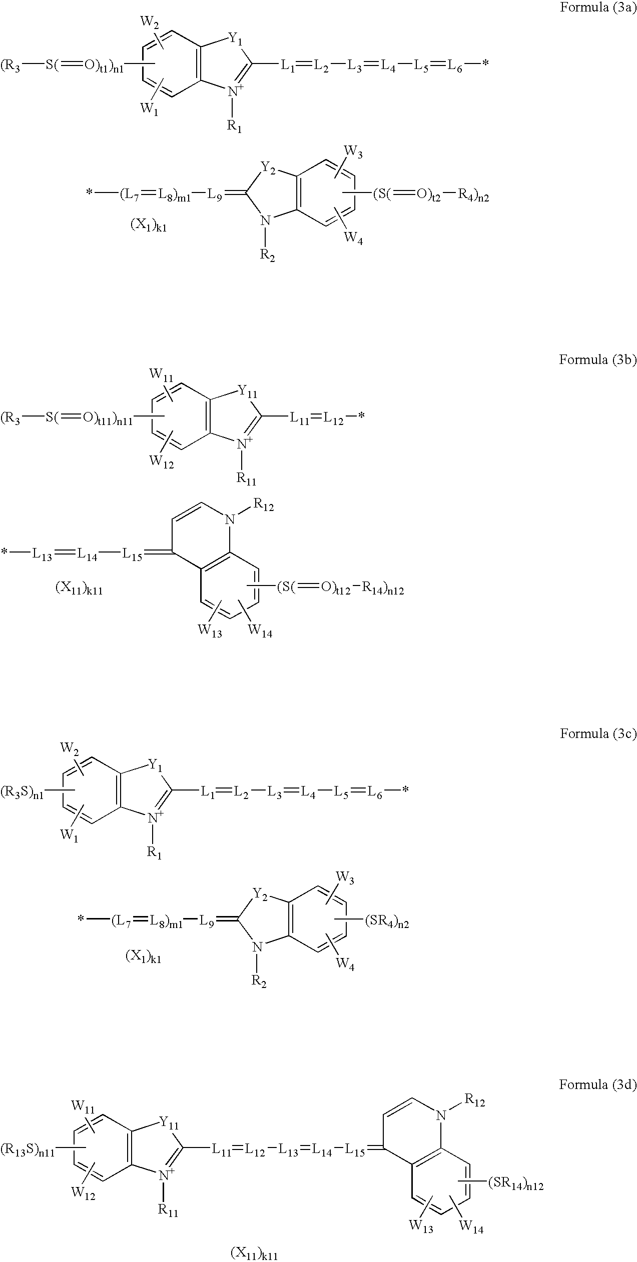

In the formulae, Y₁, Y₂, and Y₁₁ each independently represent an oxygen atom, a sulfur atom, a selenium atom, or —C≡CH group; L₁ to L₉ and L₁₁ to L₁₅ each represent a methine group; R₁, R₂, R₁₁, and R₁₂ each represent an aliphatic group; R₃, R₄, R₁₃, and R₁₄ each independently represent a lower alkyl group, a cycloalkyl group, an alkenyl group, an aralkyl group, an aryl group, or a heterocyclic group; W₁, W₂, W₃, W₄, W₁₁, W₁₂, W₁₃, and W₁₄ each independently represent a hydrogen atom, a substituent, a nonmetallic atomic group necessary for forming a condensed ring by linking each combination of W₁ and W₂, W₃ and W₄, W₁₁ and W₁₂, or W₁₃ and W₁₄, or a nonmetallic atomic group necessary for forming a 5- or 6-membered condensed ring by linking each combination of R₃ and W₁, R₃ and W₂, R₁₃ and W₁₂, R₁₃ and W₁₂, R₄ and W₃, R₄ and W₄, R₁₄ and W₁₃, or R₁₄ and W₁₄; X₁ and X₁₁ each represent an ion necessary to neutralize the electric charge in the molecule; k₁ and k₁₁ each represent a number of ion necessary to neutralize the electric charge in the molecule; m₁ represents 0 or 1; n₁, n₂, n₁₁, and n₁₂ each independently represent 0, 1, or 2; and n₁ and n₂ or n₁₁ and n₁₂ are not simultaneously 0.

In formulae (3a) to (3d) described above, the aliphatic group represented by each of R₁, R₂, R₁₁, and R₁₂ includes, for example, a branched or straight-chain alkyl group having 1 to 10 carbon atoms (for example, a methyl group, an ethyl group, a propyl group, a butyl group, a pentyl group, an isopentyl group, a 2-ethyl-hexyl group, an octyl group, a decyl group, or the like), an alkenyl group having 3 to 10 carbon atoms (for example, 2-propenyl group, a butenyl group, a 1-methyl-3-propenyl group, a 3-pentenyl group, a 1-methyl-3-butenyl group, a 4-hexenyl group, or the like), and an aralkyl group having 7 to 10 carbon atoms (for example, a benzyl group, a phenethyl group, or the like).

The above-described groups may further be substituted by a hydrophilic group such as a lower alkyl group (for example, a methyl group, an ethyl group, a propyl group, or the like), a halogen atom (for example, a fluorine atom, a chlorine atom, a bromine atom, or the like), a vinyl group, an aryl group (for example, a phenyl group, a p-tolyl group, a p-bromophenyl group, or the like), a trifluoromethyl group, an alkoxy group (for example, a methoxy group, an ethoxy group, a methoxyethoxy group, or the like), an aryloxy group (for example, a phenoxy group, a p-tolyloxy group, or the like), a cyano group, a sulfonyl group (for example, a methanesulfonyl group, a trifluoromethane sulfonyl group, a p-toluene sulfonyl group, or the like), an alkoxycarbonyl group (for example, an ethoxycarbonyl group, a butoxycarbonyl group, or the like), an amino group (for example, an amino group, a biscarboxymethyl amino group, or the like), an aryl group (for example, a phenyl group, a carboxyphenyl group, or the like), a heterocyclic group (for example, a tetrahydrofurfuryl group, a pyrrolidinon-1-yl group, or the like), an acyl group (for example, an acetyl group, a benzoyl group, or the like), a ureido group (for example, a ureido group, a 3-methylureido group, a 3-phenylureido group, or the like), a thioureido group (for example, a thioureido group, a 3-methylthioureido group, or the like), an alkylthio group (for example, a methylthio group, an ethylthio group, or the like), an arylthio group (for example, a phenylthio group or the like), a heterocyclic thio group (for example, a 2-thienylthio group, a 3-thienylthio group, a 2-imidazolylthio group, or the like), a carbonyloxy group (for example, an acetyloxy group, a propanoyloxy group, a benzoyloxy group, or the like), an acylamino group (for example, an acetylamino group, a benzoylamino group, or the like), a thioamido group (for example, a thioacetamido group, a thiobenzoylamino group, or the like), a sulfo group, a carboxy group, a phosphono group, a sulfato group, a hydroxy group, a mercapto group, a sulfino group, a carbamoyl group (for example, a carbamoyl group, an N-methylcarbamoyl group, an N,N-tetramethylenecarbamoyl group, or the like), a sulfamoyl group (for example, a sulfamoyl group, an N,N-3-oxapentamethylene aminosulfonyl group, or the like), a sulfonamido group (for example, a methane sulfonamido group, a butane sulfonamido group, or the like), a sulfonylaminocarbonyl group (for example, a methane sulfonylaminocarbonyl group, an ethane sulfonylaminocarbonyl group, or the like), an acylaminosulfonyl group (for example, an acetoamido sulfonyl group, a methoxyacetoamido sulfonyl group, or the like), an acylaminocarbonyl group (for example, an acetoamido carbonyl group, a methoxyacetoamido carbonyl group, or the like), a sulfinyl aminocarbonyl group (for example, a methane sulfinylamino carbonyl group, an ethane sulfinylamino carbonyl group, or the like), or the like.

Specific examples of the aliphatic group substituted by the hydrophilic group described above include each of the groups of carboxymethyl, carboxyethyl, carboxybutyl, carboxypentyl, 3-sulfato butyl, 3-sulfopropyl, 2-hydroxy-3-sulfopropyl group, 4-sulfobutyl, 5-sulfopentyl, 3-sulfopentyl, 3-sulfinobutyl, 3-phosphonopropyl, hydroxyethyl, N-methanesulfonyl carbamoylmethyl, 2-carboxy-2-propenyl, o-sulfobenzyl, p-sulfophenethyl, p-carboxybenzyl, and the like.

Concerning the group represented by each of R₃, R₄, R₁₃, and R₁₄, examples of the lower alkyl group include branched or straight-chain alkyl groups having 5 or fewer carbon atoms, and specifically, a methyl group, an ethyl group, a propyl group, a butyl group, a pentyl group, an isopropyl group, and the like; examples of the cycloalkyl group include a cyclopropyl group, a cyclobutyl group, a cyclopentyl group, and the like; examples of the alkenyl group include a 2-propenyl group, a 3-butenyl group, a 1-methyl-3-propenyl group, a 3-pentenyl group, a 1-methyl-3-butenyl group, a 4-hexenyl group, and the like; examples of the aralkyl group include a benzyl group, a phenetyl group, a p-methoxyphenylmethyl group, an o-acetylaminophenylethyl group, and the like; examples of the aryl group include substituted or unsubstituted aryl groups, and specifically, a phenyl group, a 2-naphthyl group, a 1-naphthyl group, an o-tolyl group, an o-methoxyphenyl group, a m-chlorophenyl group, a m-bromophenyl group, a p-tolyl group, a p-ethoxyphenyl group, and the like; and; examples of the heterocyclic group include substituted or unsubstituted heterocyclic groups, and specifically, a 2-furyl group, a 5-methyl-2-furyl group, a 2-thienyl group, a 3-thienyl group, a 2-imidazolyl group, a 2-methyl-1-imidazolyl group, a 4-phenyl-2-thiazolyl group, a 5-hydroxy-2-benzothiazolyl group, a 2-pyridyl group, a 1-pyrrolyl group, and the like.

Each of the groups described above can be substituted by a group such as a lower alkyl group (for example, a methyl group, an ethyl group, or the like), a lower alkoxy group (for example, a methoxy group, an ethoxy group, or the like), a hydroxy group, a halogen atom (for example, fluorine atom, chlorine atom, bromine atom, or iodine atom), an aryl group (for example, a phenyl group, a tolyl group, a chlorophenyl group), a mercapto group, a lower alkylthio group (for example, a methylthio group, an ethylthio group, or the like), or the like.

Specific examples of the substituent represented by each of W₁ to W₄ and W₁₁ to W₁₄ include an alkyl group (for example, a methyl group, an ethyl group, a butyl group, an isobutyl group, or the like), an aryl group (including monocyclic and polycyclic aryl groups, for example, a phenyl group, a naphthyl group, or the like), a heterocyclic group (for example, each of the groups of thienyl, furyl, pyridyl, carbazolyl, pyrrolyl, indolyl, or the like), a halogen atom (for example, fluorine atom, chlorine atom, bromine atom, or the like), a vinyl group, an aryl group (for example, a phenyl group, a p-tolyl group, a p-bromophenyl group, or the like), a trifluoromethyl group, an alkoxy group (for example, a methoxy group, an ethoxy group, a methoxyethoxy group, or the like), an aryloxy group (for example, a phenoxy group, a p-tolyloxy group, or the like), a sulfonyl group (for example, a methane sulfonyl group, a p-toluene sulfonyl group, or the like), an alkoxycarbonyl group (for example, an ethoxycarbonyl group, a butoxycarbonyl group, or the like), an amino group (for example, an amino group, a biscarboxymethylamino group, or the like), an aryl group (for example, a phenyl group, a carboxyphenyl group, or the like), a heterocyclic group (for example, a tetrahydrofurfuryl group, a 2-pyrrolidinon-1-yl group, or the like), an acyl group (for example, an acetyl group, a benzoyl group, or the like), a ureido group (for example, a ureido group, a 3-methylureido group, a 3-phenylureido group, or the like), a thioureido group (for example, a thioureido group, a 3-methylthioureido group, or the like), an alkylthio group (for example, a methylthio group, an ethylthio group, or the like), an arylthio group (for example, a phenylthio group or the like), a hydroxy group, a styryl group, and the like.

These groups can be substituted by the group described in the explanation of the aliphatic group represented by R₁ or the like. Specific examples of the substituted alkyl group include each of the groups of 2-methoxyethyl, 2-hydroxyethyl, 3-ethoxycarbonylpropyl, 2-carbamoylethyl, 2-methane sulfonylethyl, 3-methane sulfonylaminopropyl, benzyl, phenethyl, carboxymethyl, carboxyethyl, allyl, 2-furylethyl, and the like; specific examples of the substituted aryl group include each of the groups of p-carboxyphenyl, p-N,N-dimethylaminophenyl, p-morpholinophenyl, p-methoxyphenyl, 3,4-dimethoxyphenyl, 3,4-methylenedioxyphenyl, 3-chlorophenyl, and p-nitrophenyl; and specific examples of the substituted heterocyclic group include each of the groups of 5-chloro-2-pyridyl, 5-ethoxycarbonyl-2-pyridyl, 5-carbamoyl-2-pyridyl group, and the like.

Examples of the condensed ring formed by linking each combination of W₁ and W₂, W₃ and W₄, W₁₁ and W₁₂, W₁₃ and W₁₄, R₃ and W₁, R₃ and W₂, R₁₃ and W₁₁, R₁₃ and W₁₂, R₄ and W₃, R₄ and W₄, R₁₄ and W₁₃, or R₁₄ and W₁₄ include 5- or 6-membered, saturated or unsaturated condensed carbon rings. These condensed rings can be substituted at any position thereon, and the group for substitution includes those groups explained above as the groups capable of substituting the aliphatic group.

In formulae (3a) to (3d) described above, the methine groups represented by L₁ to L₉ or L₁₁ to L₁₅ each independently represent a substituted or unsubstituted methine group. Specific examples of the group for substitution include a substituted or unsubstituted lower alkyl group (for example, a methyl group, an ethyl group, an isopropyl group, a benzyl group, or the like), an alkoxy group (for example, a methoxy group, an ethoxy group, or the like), an aryloxy group (for example, a phenoxy group, a naphthoxy group, or the like), an aryl group (for example, a phenyl group, a naphthyl group, a p-tolyl group, an o-carboxyphenyl group, or the like), —N(V₁,V₂), —SR, or a heterocyclic group (for example, a 2-thienyl group, a 2-furyl group, an N,N′-bis(methoxyethyl)barbituric acid group, or the like). Herein, R represents a lower alkyl group, aryl group, or heterocyclic group described above; V₁ and V₂ each represent a substituted or unsubstituted lower alkyl group or aryl group; and V₁ and V₂ can also link together to form a 5- or 6-membered nitrogen-containing heterocycle. Further, the methine groups can link between adjacent methine groups to each other or between every other methine groups to each other to form a 5- or 6-membered ring.

In each of the compounds represented by formula (3a) to (3d), when it is substituted by a group having an electric charge of cation or anion, a pair ion is formed by equivalent anion or cation so as to neutralize the electric charge in the molecule. Concerning the ion necessary to neutralize the electric charge in the molecule represented by each of X₁ and X₁₁, specific examples of cation include proton, organic ammonium ion (for example, each ion of triethyl ammonium, triethanol ammonium, or the like) and inorganic cation (for example, each cation of lithium, sodium, potassium, or the like), and specific examples of acid anion include halogen ion (for example, chlorine ion, bromine ion, iodine ion, or the like), p-toluene sulfonate ion, perchlorate ion, tetrafluoro boron ion, sulfate ion, methyl sulfate ion, ethyl sulfate ion, methane sulfonate ion, trifluoromethane sulfonate ion, and the like.

Specific examples of the photosensitive dye represented by formula (3a) to (3d) described above are shown below; however the invention is not limited to these compounds.

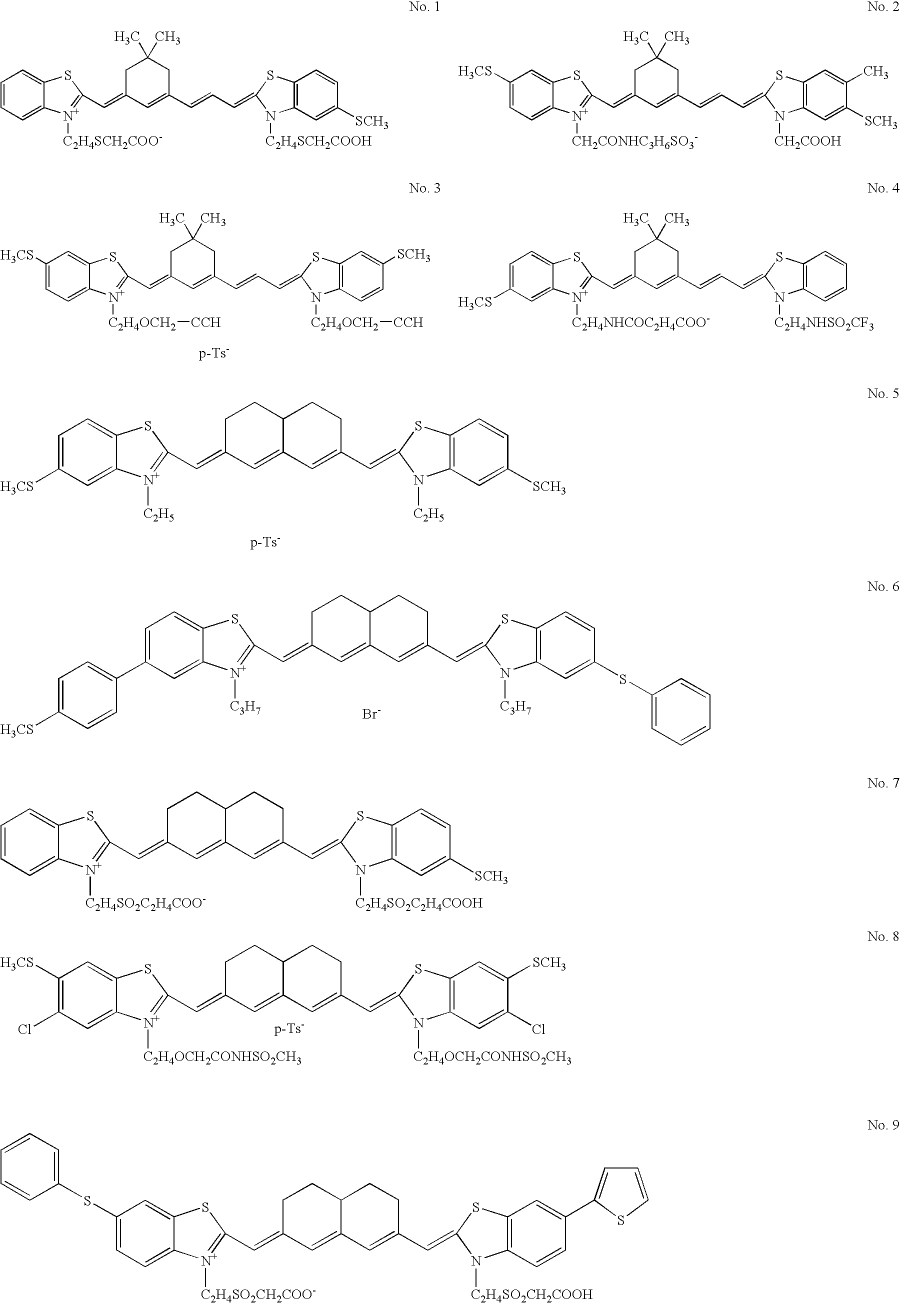

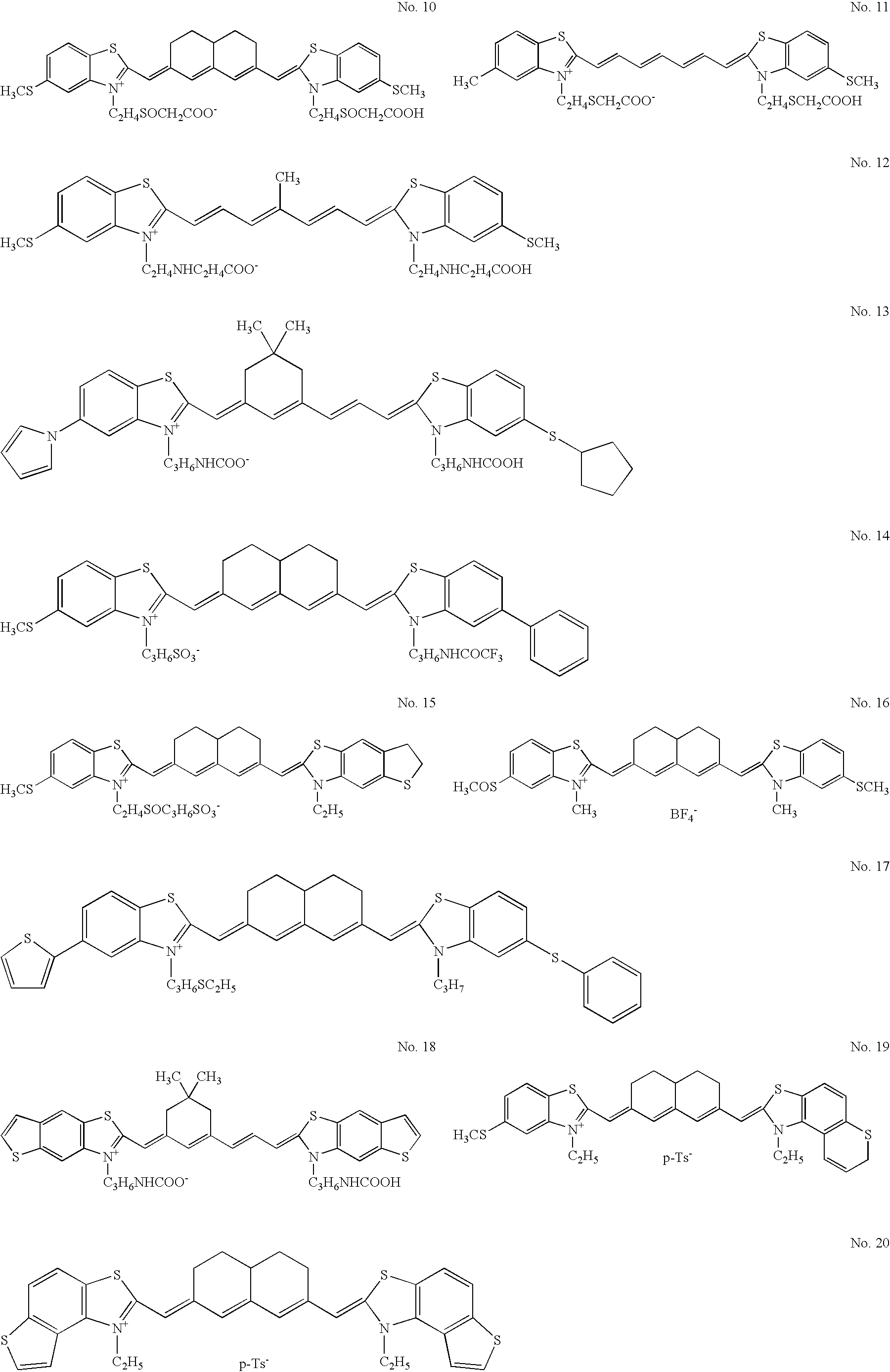

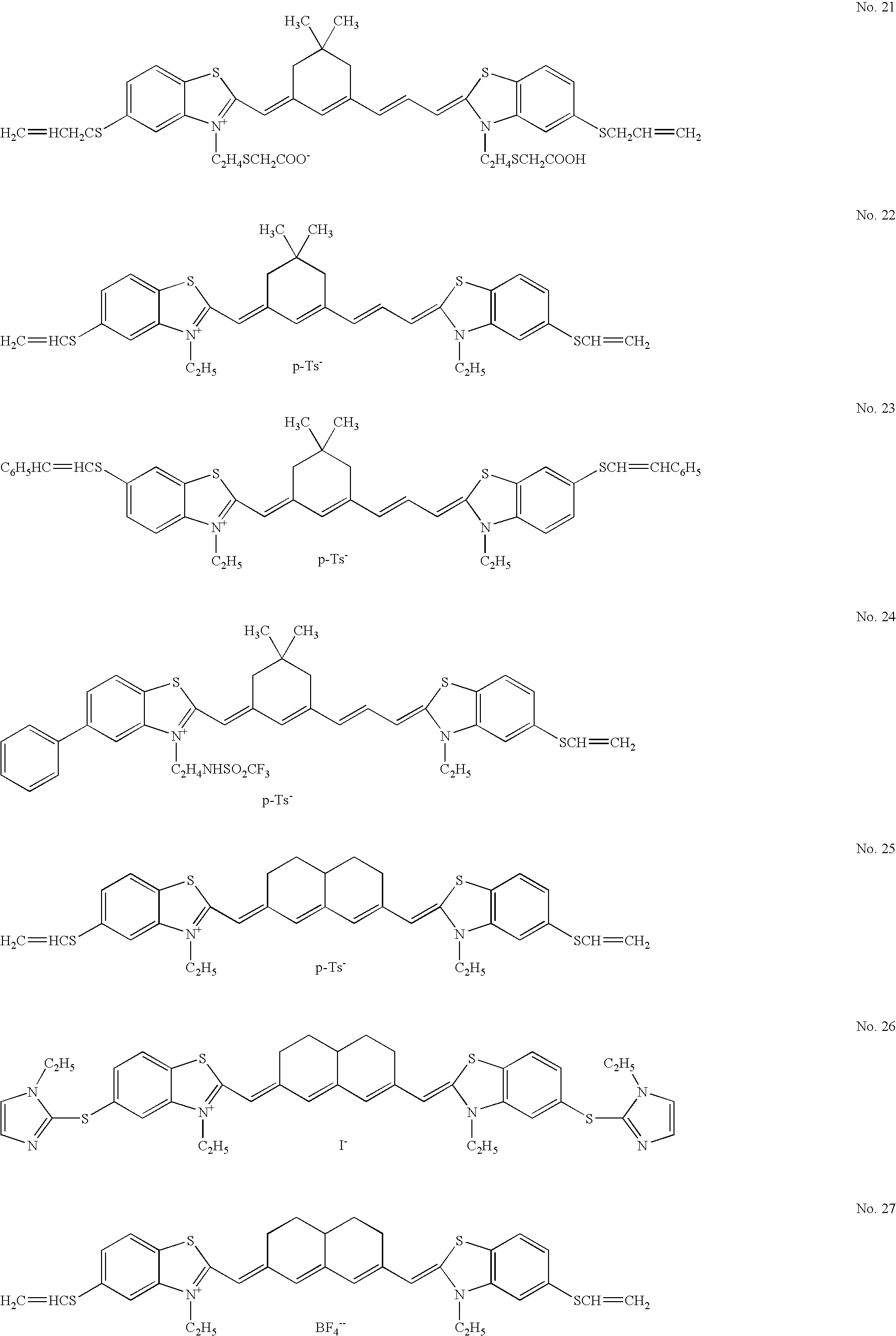

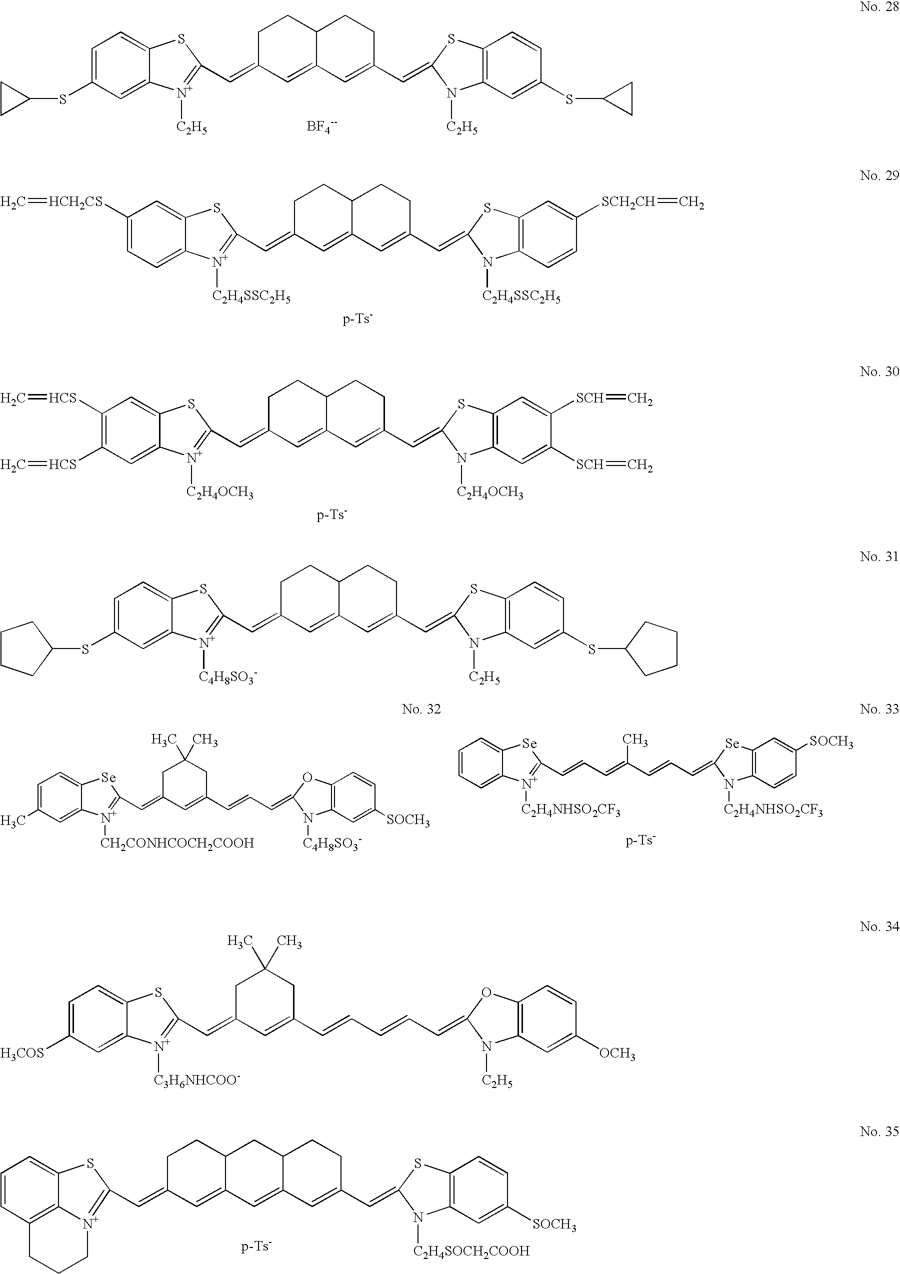

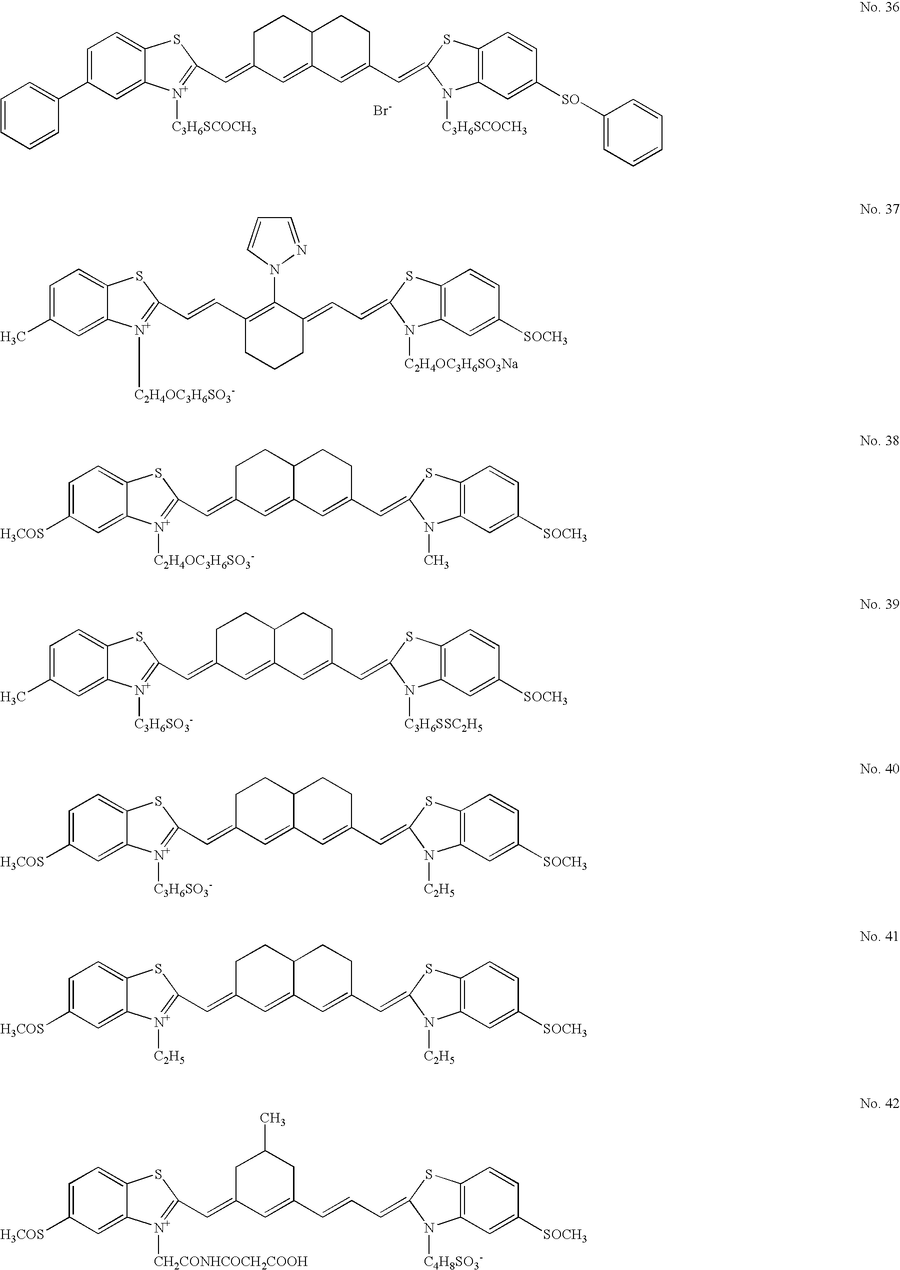

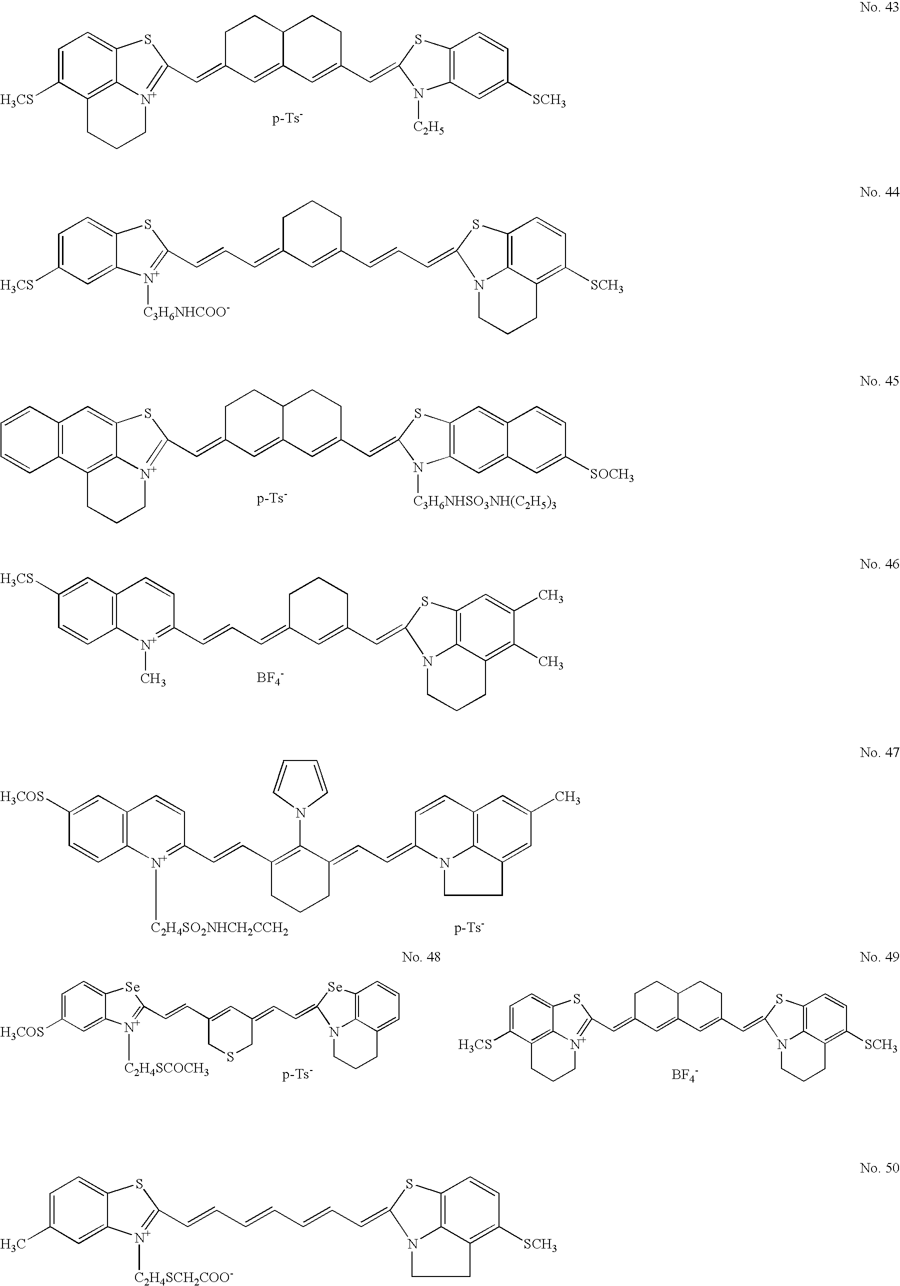

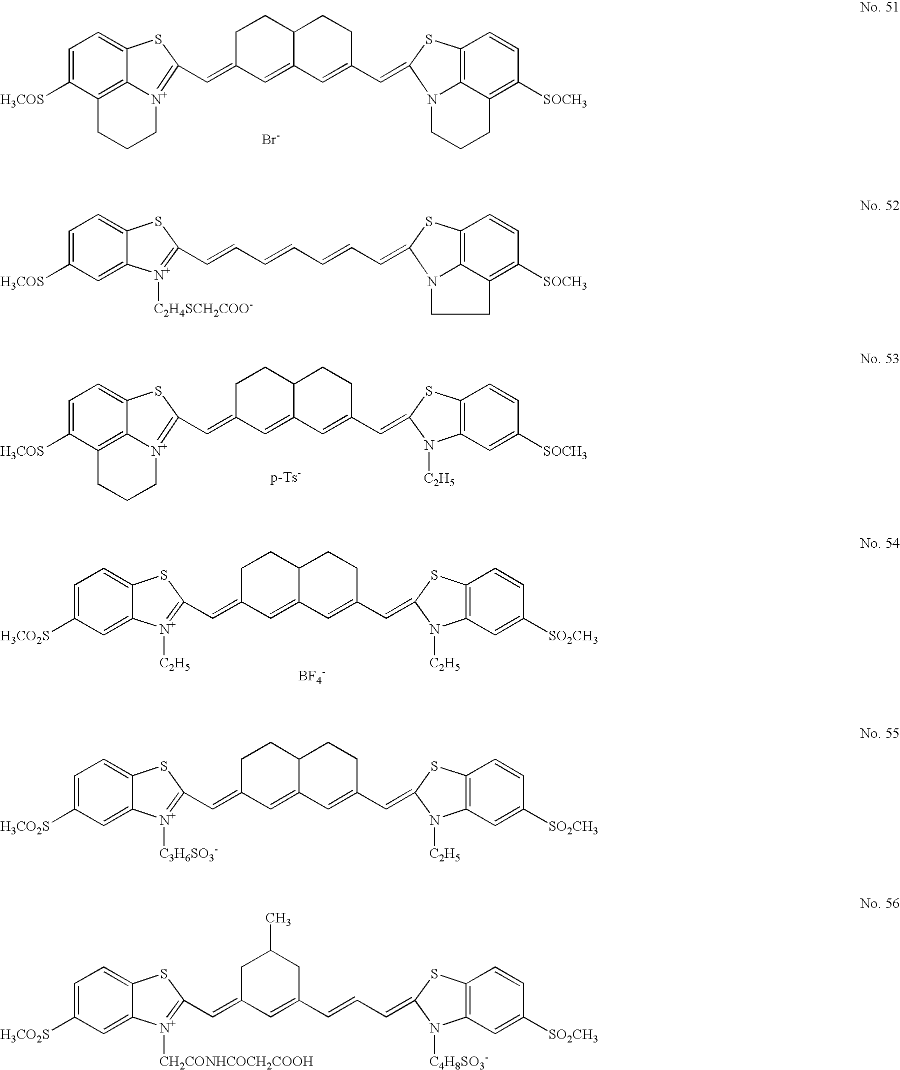

The infrared photosensitive dyes represented by formula (3a) to (3d) used in the present invention can be synthesized, for example, by the methods described in “The Chemistry of Heterocyclic Compounds” by F. M. Harmer, vol. 18, “The Cyanine Dyes and Related Compounds” (edited by A. Weissberger, issued from Interscience Co., New York, 1964), JP-A Nos. 3-138638 and 10-73900, JP-W No. 9-510022, U.S. Pat. No. 2,734,900, the specification of British Patent No. 774779, and JP-A No. 2000-095958.

In the present invention, the infrared photosensitive dyes represented by formula (3a) to (3d) may be used alone, or two or more of the photosensitive dyes can be used in combination. When the infrared photosensitive dyes are used alone or in combination, they are contained in the silver halide emulsion at a ratio of from 1×10⁻⁶ mol to 5×10⁻³ mol, preferably from 1×10⁻⁵ mol to 2.5×10⁻³ mol, and more preferably from 4×10⁻⁵ mol to 1×10⁻³ mol, in total per 1 mol of silver halide. When two or more photosensitive dyes are used in combination in the present invention, the photosensitive dyes can be incorporated in the silver halide emulsion at any ratio.

The sensitizing dyes and the addition method are described, for example, in paragraph Nos. 0103 to 0109 of JP-A No. 11-65021, as compounds represented by formula (II) in JP-A No. 10-186572, dyes represented by formula (1) and described in paragraph No. 0106 of JP-A No. 11-119374, dyes described in U.S. Pat. No. 5,510,236 and in the Example 5 of U.S. Pat. No. 3,871,887, dyes disclosed in JP-A Nos. 2-96131 and 59-48753, as well as in page 19, line 38 to page 20, line 35 of EP No. 0803764A1, and in JP-A Nos. 2001-272747, 2001-290238, and 2002-23306, and the like. The sensitizing dye may be used alone, or two or more of them may be used in combination. In the invention, the sensitizing dye is preferably added in the silver halide emulsion within a period after desalting step until coating, and more preferably in a period after desalting until the completion of chemical ripening.

In the invention, a super sensitizer can be used in order to improve the spectral sensitizing effect. The super sensitizer that can be used in the invention includes those compounds described in EP-A No. 587,338, U.S. Pat. Nos. 3,877,943 and 4,873,184, JP-A Nos. 5-341432, 11-109547, and 10-111543, and the like.

Concerning the photosensitive silver halide according to the present invention, other sensitizing dyes that are conventionally known in the technical field may be used in combination with the spectral sensitizing dye represented by formula (3a) to (3d). The sensitizing dye which can be used in combination and the addition method are described, for example, in paragraph Nos. 0103 to 0109 of JP-A No. 11-65021, as compounds represented by formula (II) in JP-A No. 10-186572, dyes represented by formula (1) and described in paragraph No. 0106 of JP-A No. 11-119374, dyes described in U.S. Pat. No. 5,510,236 and in the Example 5 of U.S. Pat. No. 3,871,887, dyes disclosed in JP-A Nos. 2-96131 and 59-48753, as well as in page 19, line 38 to page 20, line 35 of EP No. 0803764A1, and in JP-A Nos. 2001-272747, 2001-290238, and 2002-23306, and the like. These sensitizing dyes may be used alone, or two or more of them may be used in combination. The sensitizing dye is preferably added in the silver halide emulsion within a period after desalting step until coating.

(Non-Photosensitive Organic Silver Salt)

1) Composition

The organic silver salt which can be used in the present invention is relatively stable to light but serves to supply silver ions and forms silver images when heated to 80° C. or higher in the presence of an exposed photosensitive silver halide and a reducing agent. The organic silver salt may be any organic substance which supplies silver ions that are reducible by a reducing agent. Such a non-photosensitive organic silver salt is described, for example, in JP-A No. 10-62899 (paragraph Nos. 0048 and 0049), EP No. 0803764A1 (page 18, line 24 to page 19, line 37), EP No. 0962812A1, JP-A Nos. 11-349591, 2000-7683, and 2000-72711, and the like. A silver salt of an organic acid, particularly, a silver salt of a long-chain aliphatic carboxylic acid (having 10 to 30 carbon atoms, and preferably having 15 to 28 carbon atoms) is preferable. Preferred examples of the silver salt of a fatty acid include silver lignocerate, silver behenate, silver arachidinate, silver stearate, silver oleate, silver laurate, silver capronate, silver myristate, silver palmitate, silver erucate, and mixtures thereof. In the invention, among these silver salts of a fatty acid, it is preferred to use a silver salt of a fatty acid with a silver behenate content of 50 mol % or higher, more preferably 85 mol % or higher, and even more preferably 95 mol % or higher. Further, it is preferred to use a silver salt of a fatty acid with a silver erucate content of 2 mol % or lower, more preferably 1 mol % or lower, and even more preferably 0.1 mol % or lower.

It is preferred that the content of silver stearate is 1 mol % or lower. When the content of silver stearate is 1 mol % or lower, a silver salt of an organic acid having low fog, high sensitivity, and excellent image storability can be obtained. The above-mentioned content of silver stearate is preferably 0.5 mol % or lower, and particularly preferably, silver stearate is not substantially contained.

Further, in the case where silver arachidinate is included as a silver salt of an organic acid, it is preferred that the content of silver arachidinate is 6 mol % or lower from the viewpoint of obtaining a silver salt of an organic acid having low fog and excellent image storability. The content of silver arachidinate is more preferably 3 mol % or lower.

2) Particle Size

The non-photosensitive organic silver salt according to the present invention is preferably fine particles having a mean particle size of 0.2 μm or less. More preferably, the mean particle size is from 0.01 μm to 0.2 μm, and even more preferably, the mean particle size is from 0.02 μm to 0.15 μm.

In the present invention, particle size is an equivalent spherical diameter, which is expressed as a diameter of a sphere having a volume equal to the volume of a particle. The equivalent spherical diameter can be measured by a method of photographing a sample directly by using an electron microscope and then image processing the negative images.

As the particle size distribution of the organic silver salt, monodispersion is preferred. The particle size of the organic silver salt can be measured by analyzing a dispersion of an organic silver salt as transmission type electron microscopic images. Another method of measuring the monodispersion is a method of determining the standard deviation of the volume-weighted mean diameter of the organic silver salt particles, in which the percentage for the value defined by the volume-weighted mean diameter (variation coefficient) is preferably 100% or less, more preferably 80% or less, and even more preferably 50% or less. For determination of such a value, a commercially available laser beam scattering particle size analyzer can be used.

3) Preparing Method

The method for producing fine particles of the non-photosensitive organic silver salt used in the invention and the dispersion method thereof will be described.

The organic silver salt particle according to the present invention is preferably prepared at a reaction temperature of 60° C. or lower from the viewpoint of preparing particles having low minimum density. The temperature of chemicals to be added such as an aqueous solution of an organic acid alkaline metal salt may be higher than 60° C., but the temperature of the reaction bath to which the reaction solution is added is preferably 60° C. or lower, more preferably 50° C. or lower, and particularly preferably 40° C. or lower.

The pH of the silver ion-containing solution (for example, an aqueous solution of silver nitrate) for use in the present invention is preferably from 1 to 6, and more preferably from 1.5 to 4. For adjusting the pH, an acid or alkali may be added to the silver ion-containing solution itself. The types of acid and alkali are not particularly limited.

After completion of addition of a silver ion-containing solution (for example, an aqueous solution of silver nitrate) and/or a solution or suspension of an organic acid alkaline metal salt, the organic silver salt according to the present invention may be ripened by elevating the reaction temperature. In the present invention, the ripening temperature is different from the above-described reaction temperature. During the ripening, a silver ion-containing solution and a solution or suspension of an organic acid alkaline metal salt are not added at all. The ripening is preferably performed at a temperature of 1° C. to 20° C. higher than the reaction temperature, and more preferably 1° C. to 10° C. higher than the reaction temperature. The time period for ripening is preferably determined by trial and error.

In the preparation of the organic silver salt according to the present invention, 0.5 mol % to 30 mol % of the total added molar number of the solution or suspension of the organic acid alkaline metal salt may be added singly after completion of addition of the silver ion-containing solution. Preferably, it may be added singly in an amount of from 3 mol % to 20 mol %. The above addition is preferably carried out as one turn of the divided addition. In the case where a sealed mixing means is utilized, the solution or suspension may be added to either the sealed mixing means or the reaction vessel, but is preferably added to the reaction vessel. By carrying out this addition, hydrophilic property of the surface of the organic silver salt particles can be improved so that the obtained photothermographic material provides improved film-forming property and improved peeling resistance.

The silver ion concentration of the silver ion-containing solution (for example, an aqueous solution of silver nitrate) for use in the present invention may be arbitrary determined. The silver ion concentration is preferably in a range of from 0.03 mol/L to 6.5 mol/L, and more preferably from 0.1 mol/L to 5 mol/L, on the basis of the molar concentration.

In the practice of the present invention, in order to form organic silver salt particles, it is preferred that at least one of the silver ion-containing solution, the solution or suspension of an organic acid alkaline metal salt, or a solution prepared in advance in the reaction site contains an organic solvent in an amount that is sufficient to form a substantially transparent solution without making the organic acid alkaline metal salt into string-like aggregates or micelles.

As the solution, water, an organic solvent, or a mixture of water and an organic solvent is preferably employed, but more preferred is a mixed solution of water and an organic solvent.

The organic solvent for use in the present invention is not particularly limited concerning the type thereof as long as it is water soluble and has the above-described performance, but those which exert adverse influences on photographic performance are not favored. Alcohol or acetone that is miscible with water is preferred.

Specifically, the alkaline metal of the alkaline metal salt of an organic acid used in the invention is preferably potassium. The alkaline metal salt of an organic acid is prepared by adding potassium hydroxide to an organic acid. In this process, it is preferred to allow unreacted organic acid to remain by setting the amount of alkali equivalent to or less than the amount of organic acid. The amount of residual organic acid is preferably from 3 mol % to 50 mol %, and more preferably from 3 mol % to 30 mol %, with respect to the total amount of organic acids. The amount of residual organic acid may also be adjusted by adding an alkali in excess of the desired amount and thereafter adding an acid such as nitric acid or sulfuric acid to neutralize the excess alkali content. Furthermore, in the practice of the present invention, the liquid in the sealed mixing means where the silver ion-containing solution and at least one of the solution or suspension of an organic acid alkaline metal salt are added can contain, for example, a compound such as expressed by formula (1) of JP-A No. 62-65035, a nitrogen-containing heterocyclic compound having a water-soluble group such as described in JP-A No. 62-150240, an inorganic peroxide such as described in JP-A No. 50-101019, a sulfur compound such as described in JP-A No. 51-78319, a disulfide compound and hydrogen peroxide such as described in JP-A No. 57-643, and the like.

In the solution or suspension of the organic acid alkaline metal salt used in the present invention, the amount of organic solvent is preferably, in terms of the organic solvent volume, from 3% to 70%, and more preferably from 5% to 50%, with respect to the volume of water content. Here, the optimum solvent volume varies depending on the reaction temperature, and therefore, the optimum amount can be determined by trial and error. The concentration of the alkaline metal salt of an organic acid for use in the present invention is from 5% by weight to 50% by weight, preferably from 7% by weight to 45% by weight, and more preferably from 10% by weight to 40% by weight, on the basis of the weight ratio.

The temperature of the solution or suspension of the organic acid alkaline metal salt supplied to the reaction vessel is preferably from 50° C. to 90° C., more preferably from 60° C. to 85° C., and most preferably from 65° C. to 85° C., for the purpose of maintaining the temperature necessary for preventing crystallization or solidification of the organic acid alkaline metal salt. Also, for performing the reaction at a constant temperature, the solution or suspension of the organic acid alkaline metal salt is preferably controlled to a constant temperature selected from the above-described range. By this control, the speed at which the solution or suspension of the organic acid alkaline metal salt at a high temperature is rapidly cooled and precipitated in the form of fine crystal in the sealed mixing means and the speed at which an organic silver salt is formed by the reaction with the silver ion-containing solution are preferably controlled, so that crystal form, crystal size, and crystal size distribution of the organic silver salt can be preferably controlled, and at the same time, the performance as thermal developing image recording material can be further improved.

A solvent can be added in advance in the reaction vessel. As the solvent added in advance, water is preferably used, but a mixed solvent with a solution or suspension of organic acid alkaline metal salt is also preferably used.

The solution or suspension of organic acid alkaline metal salt, the ion-containing solution, or the reaction solution may contain a dispersing agent which is soluble in an aqueous medium. Any dispersing agent may be used as long as it can disperse the formed organic silver salt. Specific examples are the same as those described below for the dispersing agent of the organic silver salt.

In the method for preparing the organic silver salt, it is preferred to perform a desalting/dehydration step after the formation of the silver salt. The method thereof is not particularly limited and a known and commonly employed means can be used. For example, a known filtration method such as centrifugal filtration, suction filtration, ultra filtration, or flocculation/water washing by coagulation, or a method of removing the supernatant after centrifugal separation and precipitation is preferably used. Among these, the centrifuge method is more preferred. The desalting/dehydration may be performed once or may be repeated several times. Addition and removal of water may be performed continuously or individually. The desalting/dehydration is performed to such an extent that the final dehydrated water preferably has a conductivity of 300 μS/cm or less, more preferably 100 μS/cm or less, and most preferably 60 μS/cm or less. The lower limit of the conductivity is not particularly limited, but is usually about 5 μS/cm.

In the desalting by ultra filtration according to the present invention, prior to the treatment, the liquid is preferably dispersed beforehand to make the particle size about two times the final particle size based on the volume-weighted mean thereof. The dispersion may be performed using any means such as high-pressure homogenizer, micro-fluidizer, or the like described below.

During the period from the particle formation until the desalting operation starts, the temperature of the liquid is preferably maintained low. This is because, in the state where the organic solvent used for dissolving the alkaline metal salt of an organic acid is penetrated into the inside of the formed organic silver salt particles, silver nuclei are readily produced due to the liquid feeding operation or desalting operation. Accordingly, in the practice of the present invention, the desalting operation is preferably performed while keeping the organic silver salt particle dispersion at a temperature of from 1° C. to 30° C., and preferably from 5° C. to 25° C.

4) Addition Amount

While the non-photosensitive organic silver salt according to the invention can be used in a desired amount, a total amount of coated silver including also the silver halide is preferably in a range of from 0.05 g/m² to 3.0 g/m², more preferably from 0.1 g/m² to 1.8 g/m², and even more preferably from 0.2 g/m² to 1.2 g/m².

Concerning the method for producing the non-photosensitive organic silver salt used in the invention and the dispersion method thereof, in addition to the above, reference can be made to JP-A No. 10-62899, EP Nos. 0803763A1 and 0962812A1, JP-A Nos. 11-349591, 2000-7683, 2000-72711, 2001-163889, 2001-163890, 2001-163827, 2001-33907, 2001-188313, 2001-83652, 2002-6442, 2002-49117, 2002-31870, and 2002-107868, and the like.

When a photosensitive silver salt is present together during dispersion of the organic silver salt, fog increases and sensitivity becomes remarkably lower, so that it is more preferred that the photosensitive silver salt is not substantially contained during dispersion. In the invention, the amount of the photosensitive silver salt to be dispersed in the aqueous dispersion is preferably 1 mol % or lower, more preferably 0.1 mol % or lower, with respect to 1 mol of the organic silver salt in the solution, and even more preferably, positive addition of the photosensitive silver salt is not conducted.

(Development Accelerator)

In the photothermographic material of the invention, as a development accelerator, sulfonamido phenol compounds described in the specification of JP-A No. 2000-267222, and represented by formula (A) described in the specification of JP-A No. 2000-330234; hindered phenol compounds represented by formula (II) described in JP-A No. 2001-92075; hydrazine compounds described in the specification of JP-A No. 10-62895, represented by formula (I) described in the specification of JP-A No. 11-15116, represented by formula (D) described in the specification of JP-A No. 2002-156727, and represented by formula (1) described in the specification of JP-A No. 2002-278017; and phenol or naphthol compounds represented by formula (2) described in the specification of JP-A No. 2001-264929 are used preferably. The development accelerator is used in a range of from 0.1 mol % to 20 mol %, preferably, in a range of from 0.5 mol % to 10 mol %, and more preferably in a range of from 1 mol % to 5 mol %, with respect to the reducing agent. The introducing methods to the photothermographic material include similar methods to those for the reducing agent, and it is particularly preferred to add the development accelerator as a solid dispersion or an emulsified dispersion. In the case of adding the development accelerator as an emulsified dispersion, it is preferred to add it as an emulsified dispersion dispersed by using a solvent having a high boiling point which is solid at ordinary temperature and an auxiliary solvent having a low boiling point, or to add as a so-called oilless emulsified dispersion not using a solvent having a high boiling point.

In the present invention, among the development accelerators described above, hydrazine compounds represented by formula (D) described in the specification of JP-A No. 2002-156727 and phenol or naphthol compounds represented by formula (2) described in the specification of JP-A No. 2001-264929 are more preferred.

Particularly preferred development accelerators used for the invention are compounds represented by the following formulae (A-1) or (A-2).

Q₁-NHNH-Q₂ Formula (A-1)

In the formula, Q₁ represents an aromatic group or heterocyclic group which bonds to —NHNH-Q₂ at a carbon atom, and Q₂ represents one selected from a carbamoyl group, an acyl group, an alkoxycarbonyl group, an aryloxycarbonyl group, a sulfonyl group, or a sulfamoyl group.

In formula (A-1), the aromatic group or heterocyclic group represented by Q₁ is preferably a 5- to 7-membered unsaturated ring. Preferred examples thereof include a benzene ring, a pyridine ring, a pyrazine ring, a pyrimidine ring, a pyridazine ring, a 1,2,4-triazine ring, a 1,3,5-triazine ring, a pyrrole ring, an imidazole ring, a pyrazole ring, a 1,2,3-triazole ring, a 1,2,4-triazole ring, a tetrazole ring, a 1,3,4-thiadiazole ring, a 1,2,4-thiadiazole ring, a 1,2,5-thiadiazole ring, a 1,3,4-oxadiazole ring, a 1,2,4-oxadiazole ring, a 1,2,5-oxadiazole ring, a thiazole ring, an oxazole ring, an isothiazole ring, an isooxazole ring, a thiophene ring, and the like. Condensed rings in which the rings described above are condensed to each other are also preferred.

The rings described above may have substituents, and in the case where they have two or more substituents, the substituents may be identical or different from each other. Examples of the substituent include a halogen atom, an alkyl group, an aryl group, a carbonamido group, an alkylsulfonamido group, an arylsulfonamido group, an alkoxy group, an aryloxy group, an alkylthio group, an arylthio group, a carbamoyl group, a sulfamoyl group, a cyano group, an alkylsulfonyl group, an arylsulfonyl group, an alkoxycarbonyl group, an aryloxycarbonyl group, and an acyl group. In the case where the substituents are groups capable of substitution, they may further have a substituent, and examples of preferred substituent include a halogen atom, an alkyl group, an aryl group, a carbonamido group, an alkylsulfonamido group, an arylsulfonamido group, an alkoxy group, an aryloxy group, an alkylthio group, an arylthio group, an acyl group, an alkoxycarbonyl group, an aryloxycarbonyl group, a carbamoyl group, a cyano group, a sulfamoyl group, an alkylsulfonyl group, an arylsulfonyl group, and an acyloxy group.

The carbamoyl group represented by Q₂ is a carbamoyl group preferably having 1 to 50 carbon atoms, and more preferably having 6 to 40 carbon atoms; and examples thereof include unsubstituted carbamoyl, methylcarbamoyl, N-ethylcarbamoyl, N-propylcarbamoyl, N-sec-butylcarbamoyl, N-octylcarbamoyl, N-cyclohexylcarbamoyl, N-tert-butylcarbamoyl, N-dodecylcarbamoyl, N-(3-dodecyloxypropyl)carbamoyl, N-octadecylcarbamoyl, N-{3-(2,4-tert-pentylphenoxy)propyl}carbamoyl, N-(2-hexyldecyl)carbamoyl, N-phenylcarbamoyl, N-(4-dodecyloxyphenyl)carbamoyl, N-(2-chloro-5-dodecyloxycarbonylphenyl)carbamoyl, N-naphthylcarbamoyl, N-3-pyridylcarbamoyl, and N-benzylcarbamoyl.

The acyl group represented by Q₂ is an acyl group preferably having 1 to 50 carbon atoms, and more preferably having 6 to 40 carbon atoms; and examples thereof include formyl, acetyl, 2-methylpropanoyl, cyclohexylcarbonyl, octanoyl, 2-hexyldecanoyl, dodecanoyl, chloroacetyl, trifluoroacetyl, benzoyl, 4-dodecyloxybenzoyl, and 2-hydroxymethylbenzoyl. The alkoxycarbonyl group represented by Q₂ is an alkoxycarbonyl group preferably having 2 to 50 carbon atoms, and more preferably having 6 to 40 carbon atoms; and examples thereof include methoxycarbonyl, ethoxycarbonyl, isobutyloxycarbonyl, cyclohexyloxycarbonyl, dodecyloxycarbonyl, and benzyloxycarbonyl.

The aryloxycarbonyl group represented by Q₂ is an aryloxycarbonyl group preferably having 7 to 50 carbon atoms, and more preferably having 7 to 40 carbon atoms; and examples thereof include phenoxycarbonyl, 4-octyloxyphenoxycarbonyl, 2-hydroxymethylphenoxycarbonyl, and 4-dodecyloxyphenoxycarbonyl. The sulfonyl group represented by Q₂ is a sulfonyl group preferably having 1 to 50 carbon atoms, and more preferably having 6 to 40 carbon atoms; and examples thereof include methylsulfonyl, butylsulfonyl, octylsulfonyl, 2-hexadecylsulfonyl, 3-dodecyloxypropylsulfonyl, 2-octyloxy-5-tert-octylphenylsulfonyl, and 4-dodecyloxyphenylsulfonyl.

The sulfamoyl group represented by Q₂ is a sulfamoyl group preferably having 0 to 50 carbon atoms, and more preferably having 6 to 40 carbon atoms; and examples thereof include unsubstituted sulfamoyl, N-ethylsulfamoyl group, N-(2-ethylhexyl)sulfamoyl, N-decylsulfamoyl, N-hexadecylsulfamoyl, N-{3-(2-ethylhexyloxy)propyl}sulfamoyl, N-(2-chloro-5-dodecyloxycarbonylphenyl)sulfamoyl, and N-(2-tetradecyloxyphenyl)sulfamoyl. The group represented by Q₂ may further have a group mentioned as the example of the substituent of 5- to 7-membered unsaturated ring represented by Q₁ described above at the position capable of substitution. In the case where the group represented by Q₂ has two or more substituents, such substituents may be identical or different from one another.

Next, preferred range for the compound represented by formula (A-1) is to be described. A 5- or 6-membered unsaturated ring is preferred for Q₁, and a benzene ring, a pyrimidine ring, a 1,2,3-triazole ring, a 1,2,4-triazole ring, a tetrazole ring, a 1,3,4-thiadiazole ring, a 1,2,4-thiadiazole ring, a 1,3,4-oxadiazole ring, a 1,2,4-oxadiazole ring, a thiazole ring, an oxazole ring, an isothiazole ring, an isooxazole ring, and a ring in which the ring described above is condensed with a benzene ring or unsaturated heterocycle are more preferred. Further, Q₂ is preferably a carbamoyl group, and particularly preferably a carbamoyl group having a hydrogen atom on the nitrogen atom.

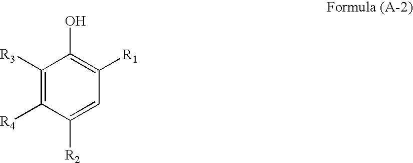

In formula (A-2), R₁ represents one selected from an alkyl group, an acyl group, an acylamino group, a sulfonamido group, an alkoxycarbonyl group, or a carbamoyl group. R₂ represents one selected from a hydrogen atom, a halogen atom, an alkyl group, an alkoxy group, an aryloxy group, an alkylthio group, an arylthio group, an acyloxy group, or a carbonic acid ester group. R₃ and R₄ each independently represent a group substituting for a hydrogen atom on a benzene ring which is mentioned as the example of the substituent of formula (A-1). R₃ and R₄ may link together to form a condensed ring.

R₁ is preferably an alkyl group having 1 to 20 carbon atoms (for example, a methyl group, an ethyl group, an isopropyl group, a butyl group, a tert-octyl group, a cyclohexyl group, or the like), an acylamino group (for example, an acetylamino group, a benzoylamino group, a methylureido group, a 4-cyanophenylureido group, or the like), or a carbamoyl group (for example, a n-butylcarbamoyl group, an N,N-diethylcarbamoyl group, a phenylcarbamoyl group, a 2-chlorophenylcarbamoyl group, a 2,4-dichlorophenylcarbamoyl group, or the like). An acylamino group (including a ureido group and a urethane group) is more preferred. R₂ is preferably a halogen atom (more preferably, a chlorine atom or a bromine atom), an alkoxy group (for example, a methoxy group, a butoxy group, an n-hexyloxy group, an n-decyloxy group, a cyclohexyloxy group, a benzyloxy group, or the like), or an aryloxy group (for example, a phenoxy group, a naphthoxy group, or the like).

R₃ is preferably a hydrogen atom, a halogen atom, or an alkyl group having 1 to 20 carbon atoms, and most preferably a halogen atom. R₄ is preferably a hydrogen atom, an alkyl group, or an acylamino group, and more preferably an alkyl group or an acylamino group. Examples of the preferred substituent thereof are similar to those for R₁. In the case where R₄ is an acylamino group, R₄ may preferably link with R₃ to form a carbostyryl ring.

In the case where R₃ and R₄ in formula (A-2) link together to form a condensed ring, a naphthalene ring is particularly preferred as the condensed ring. The same substituent as the example of the substituent referred to for formula (A-1) may bond to the naphthalene ring. In the case where formula (A-2) is a naphthol compound, R₁ is preferably a carbamoyl group. Among them, a benzoyl group is particularly preferred. R₂ is preferably an alkoxy group or an aryloxy group, and particularly preferably an alkoxy group.

Preferred specific examples for the development accelerator used for the invention are to be described below. The invention is not restricted to these examples.

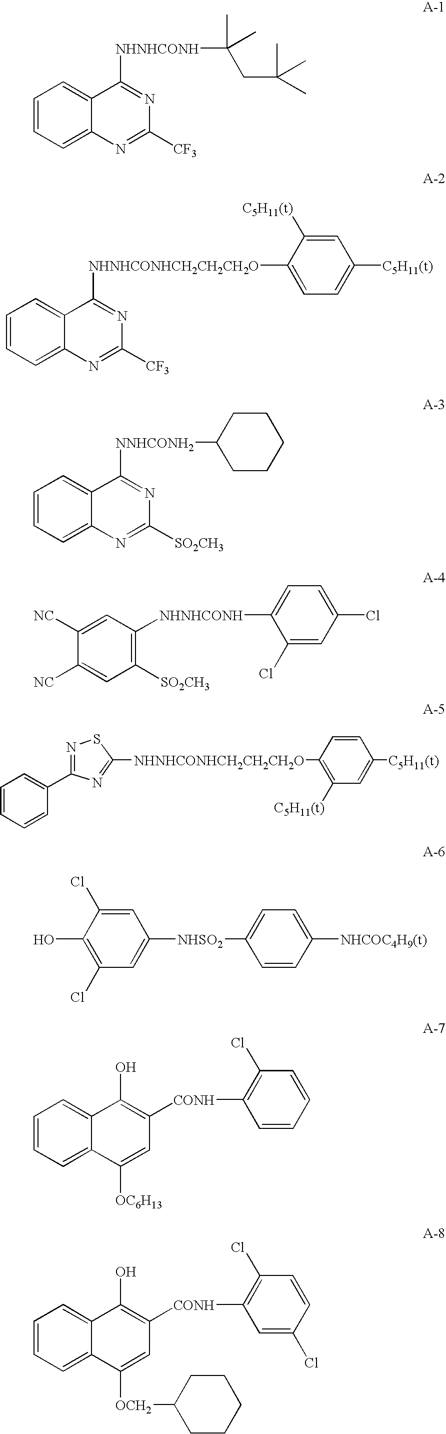

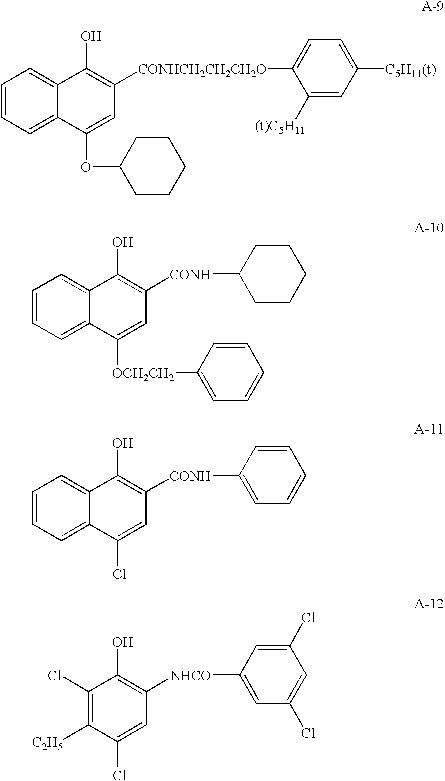

(Hydrogen Bonding Compound)

In the case where the reducing agent according to the invention has an aromatic hydroxy group (—OH) or an amino group (—NHR, R represents a hydrogen atom or an alkyl group), particularly in the case where the reducing agent is a bisphenol described above, it is preferred to use in combination a non-reducing compound having a group which forms a hydrogen bond with these groups of the reducing agent.

Examples of the group forming a hydrogen bond with the hydroxy group or amino group include a phosphoryl group, a sulfoxide group, a sulfonyl group, a carbonyl group, an amido group, an ester group, a urethane group, a ureido group, a tertiary amino group, a nitrogen-containing aromatic group, and the like. Preferred among them are a phosphoryl group, a sulfoxide group, an amido group (not having —N(H)— group but being blocked in the form of —N(Ra)— (where Ra represents a substituent other than H)), a urethane group (not having —N(H)— group but being blocked in the form of —N(Ra)— (where Ra represents a substituent other than H)), and a ureido group (not having —N(H)— group but being blocked in the form of —N(Ra)— (where Ra represents a substituent other than H)).

In the invention, particularly preferable hydrogen bonding compound is a compound represented by the following formula (D).

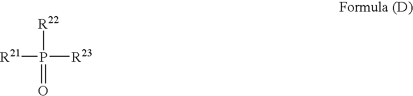

In formula (D), R²¹ to R²³ each independently represent one selected from an alkyl group, an aryl group, an alkoxy group, an aryloxy group, an amino group, or a heterocyclic group, which may be substituted or unsubstituted.

In the case where R²¹ to R²³ has a substituent, examples of the substituent include a halogen atom, an alkyl group, an aryl group, an alkoxy group, an amino group, an acyl group, an acylamino group, an alkylthio group, an arylthio group, a sulfonamido group, an acyloxy group, an oxycarbonyl group, a carbamoyl group, a sulfamoyl group, a sulfonyl group, a phosphoryl group, and the like, in which preferred as the substituent are an alkyl group and an aryl group, e.g., a methyl group, an ethyl group, an isopropyl group, a t-butyl group, a t-octyl group, a phenyl group, a 4-alkoxyphenyl group, a 4-acyloxyphenyl group, and the like.

Specific examples of the alkyl group represented by R²¹ to R²³ include a methyl group, an ethyl group, a butyl group, an octyl group, a dodecyl group, an isopropyl group, a t-butyl group, a t-amyl group, a t-octyl group, a cyclohexyl group, a 1-methylcyclohexyl group, a benzyl group, a phenethyl group, a 2-phenoxypropyl group, and the like.

Examples of the aryl group include a phenyl group, a cresyl group, a xylyl group, a naphthyl group, a 4-t-butylphenyl group, a 4-t-octylphenyl group, a 4-anisidyl group, a 3,5-dichlorophenyl group, and the like.

Examples of the alkoxy group include a methoxy group, an ethoxy group, a butoxy group, an octyloxy group, a 2-ethylhexyloxy group, a 3,5,5-trimethylhexyloxy group, a dodecyloxy group, a cyclohexyloxy group, a 4-methylcyclohexyloxy group, a benzyloxy group, and the like.

Examples of the aryloxy group include a phenoxy group, a cresyloxy group, an isopropylphenoxy group, a 4-t-butylphenoxy group, a naphthoxy group, a biphenyloxy group, and the like.

Examples of the amino group include a dimethylamino group, a diethylamino group, a dibutylamino group, a dioctylamino group, an N-methyl-N-hexylamino group, a dicyclohexylamino group, a diphenylamino group, an N-methyl-N-phenylamino group, and the like.

Preferred as R²¹ to R²³ are an alkyl group, an aryl group, an alkoxy group, and an aryloxy group. From the viewpoint of the effect of the invention, it is preferred that at least one of R²¹ to R²³ is an alkyl group or an aryl group, and it is more preferred that two or more of them are an alkyl group or an aryl group. Further, from the viewpoint of low cost availability, it is preferred that R²¹ to R²³ are of the same group.

Specific examples of the hydrogen bonding compound represented by formula (D) according to the invention and others are shown below, but the invention is not limited thereto.

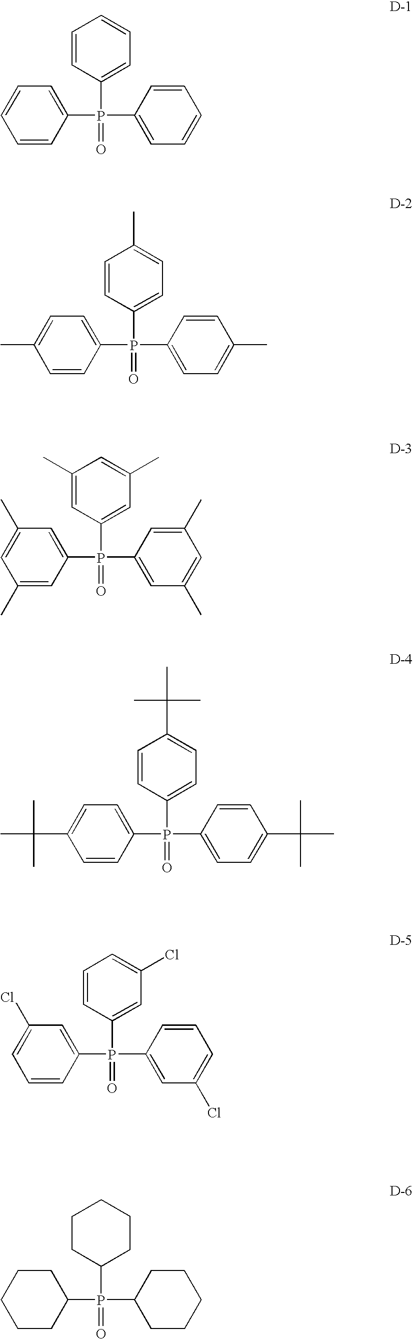

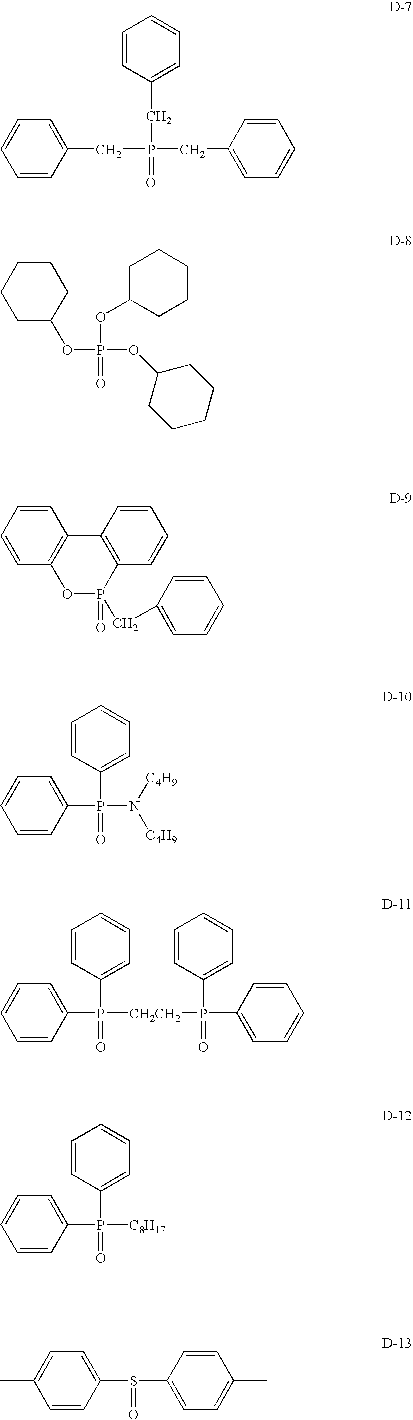

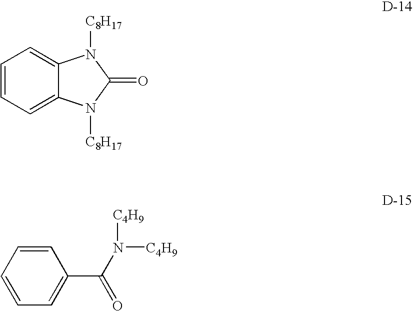

Specific examples of hydrogen bonding compounds other than those enumerated above can be found in those described in EP No. 1096310 and in JP-A Nos. 2002-156727 and 2002-318431.

The compound represented by formula (D) according to the invention can be used in the photothermographic material by being incorporated into the coating solution in the form of a solution, an emulsified dispersion, or a solid fine particle dispersion, similar to the case of reducing agent. However, it is preferably used in the form of a solid dispersion. In a solution state, the compound according to the invention forms a hydrogen-bonded complex with a compound having a phenolic hydroxy group or an amino group, and can be isolated as a complex in crystalline state depending on the combination of the reducing agent and the compound represented by formula (D) according to the invention.

The compound represented by formula (D) according to the invention is preferably used in a range of from 1 mol % to 200 mol %, more preferably from 10 mol % to 150 mol %, and even more preferably from 20 mol % to 100 mol %, with respect to the reducing agent.

(Antifoggant)

1) Organic Polyhalogen Compound

Preferable organic polyhalogen compound that can be used in the invention is explained specifically below. In the invention, preferred organic polyhalogen compound is a compound represented by the following formula (H).

Q-(Y)n-C(Z₁)(Z₂)X Formula (H)

In formula (H), Q represents an alkyl group, an aryl group, or a heterocyclic group; Y represents a divalent linking group; n represents 0 or 1; Z₁ and Z₂ each represent a halogen atom; and X represents a hydrogen atom or an electron-attracting group.

In formula (H), Q is preferably an alkyl group having 1 to 6 carbon atoms, an aryl group having 6 to 12 carbon atoms, or a heterocyclic group comprising at least one nitrogen atom (pyridine, quinoline, or the like).

In the case where Q is an aryl group in formula (H), Q is preferably a phenyl group substituted by an electron-attracting group whose Hammett substituent constant σp yields a positive value. For the details of Hammett substituent constant, reference can be made to Journal of Medicinal Chemistry, vol. 16, No. 11 (1973), pages 1207 to 1216, and the like.

Examples of the electron-attracting group include a halogen atom, an alkyl group substituted by an electron-attracting group, an aryl group substituted by an electron-attracting group, a heterocyclic group, an arylsulfonyl group, an alkylsulfonyl group, an acyl group, an alkoxycarbonyl group, a carbamoyl group, a sulfamoyl group, and the like. Preferable as the electron-attracting group is a halogen atom, a carbamoyl group, or an arylsulfonyl group, and a carbamoyl group is particularly preferable.

X is preferably an electron-attracting group. As the electron-attracting group, preferable are a halogen atom, an aliphatic arylsulfonyl group, a heterocyclic sulfonyl group, an aliphatic arylacyl group, a heterocyclic acyl group, an aliphatic aryloxycarbonyl group, a heterocyclic oxycarbonyl group, a carbamoyl group, and a sulfamoyl group; more preferable are a halogen atom and a carbamoyl group; and particularly preferable is a bromine atom.

Z₁ and Z₂ each are preferably a bromine atom or an iodine atom, and more preferably, a bromine atom.

Y preferably represents —C(═O)—, —SO—, —SO₂—, —C(═O)N(R)—, or —SO₂N(R)—; more preferably, —C(═O)—, —SO₂—, or —C(═O)N(R)—; and particularly preferably, —SO₂— or —C(═O)N(R)—.

Herein, R represents a hydrogen atom, an aryl group, or an alkyl group. R is preferably a hydrogen atom or an alkyl group, and particularly preferably a hydrogen atom.

n represents 0 or 1, and is preferably 1.

In formula (H), in the case where Q is an alkyl group, Y is preferably —C(═O)N(R)—. And, in the case where Q is an aryl group or a heterocyclic group, Y is preferably —SO₂—.

In formula (H), the embodiment where the residues, which are obtained by removing a hydrogen atom from the compound, bond to each other (generally called bis type, tris type, or tetrakis type) is also preferably used.

In formula (H), the embodiment having, as a substituent, a dissociative group (for example, a COOH group or a salt thereof, an SO₃H group or a salt thereof, a PO₃H group or a salt thereof, or the like), a group containing a quaternary nitrogen cation (for example, an ammonio group, a pyridinio group, or the like), a polyethyleneoxy group, a hydroxy group, or the like is also preferable.

Specific examples of the compound represented by formula (H) according to the invention are shown below.

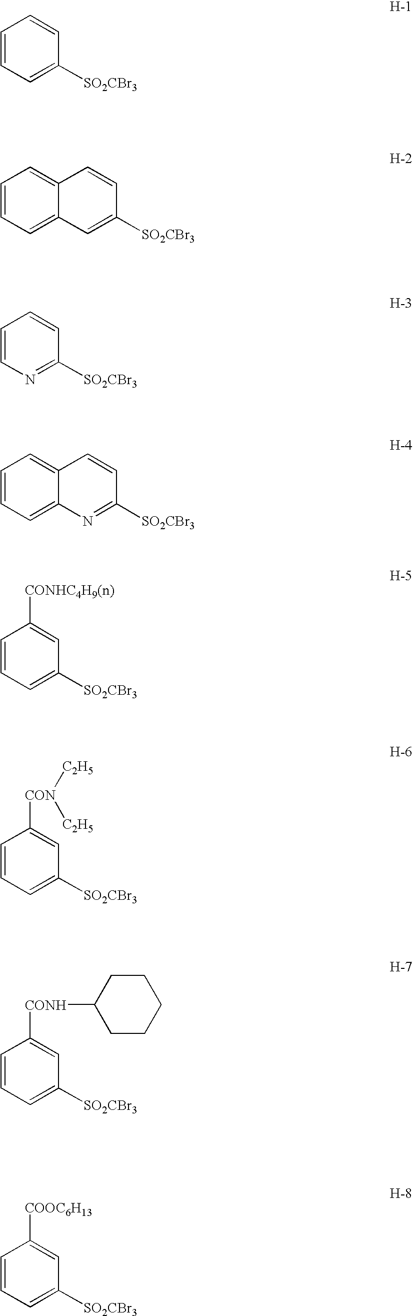

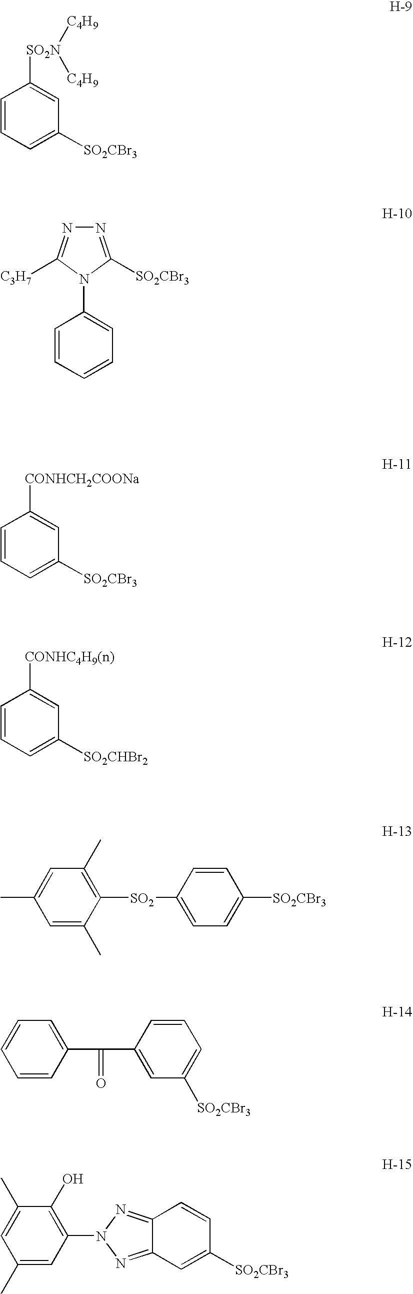

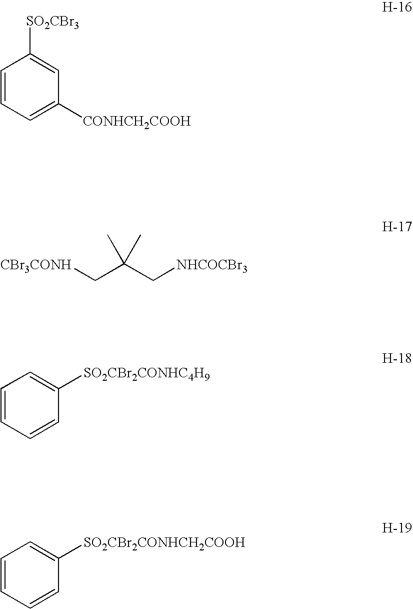

As preferred organic polyhalogen compounds which can be used in the present invention other than those above, there are mentioned compounds described as illustrated compounds of the relevant invention in the specifications of U.S. Pat. Nos. 3,874,946, 4,756,999, 5,340,712, 5,369,000, 5,464,737, and 6,506,548, and JP-A Nos. 50-137126, 50-89020, 50-119624, 59-57234, 7-2781, 7-5621, 9-160164, 9-244177, 9-244178, 9-160167, 9-258367, 9-265150, 9-319022, 10-197988, 10-197989, 11-242304, 2000-2963, 2000-112070, 2000-284410, 2000-284412, 2001-33911, 2001-31644, 2001-312027, and 2003-50441. Particularly, the compounds specifically illustrated in JP-A Nos. 7-2781, 2001-33911, and 2001-312027 are preferable.

The compound represented by formula (H) according to the invention is preferably used in an amount of from 10⁻⁴ mol to 1 mol, more preferably from 10⁻³ mol to 0.5 mol, and even more preferably from 1×10⁻² mol to 0.2 mol, per 1 mol of non-photosensitive silver salt incorporated in the image forming layer.

In the invention, methods which can be used for incorporating the antifoggant into the photothermographic material are those described above in the method for incorporating the reducing agent, and also for the organic polyhalogen compound, it is preferably added in the form of a solid fine particle dispersion.

2) Other Antifoggants

As other antifoggants, there are mentioned a mercury (II) salt described in paragraph number 0113 of JP-A No. 11-65021, benzoic acids described in paragraph number 0114 of the same literature, a salicylic acid derivative described in JP-A No. 2000-206642, a formalin scavenger compound represented by formula (S) in JP-A No. 2000-221634, a triazine compound related to Claim 9 of JP-A No. 11-352624, a compound represented by formula (III), 4-hydroxy-6-methyl-1,3,3a,7-tetrazaindene, described in JP-A No. 6-11791, and the like.

The photothermographic material of the invention may further contain an azolium salt in order to prevent fogging. Azolium salts useful in the present invention include a compound represented by formula (XI) described in JP-A No. 59-193447, a compound described in Japanese Patent Application Publication (JP-B) No. 55-12581, and a compound represented by formula (II) described in JP-A No. 60-153039. The azolium salt may be added to any part of the photothermographic material, but as the layer to be added, it is preferred to select a layer on the side having the image forming layer, and more preferred is to select the image forming layer itself. The azolium salt may be added at any time of the process of preparing the coating solution; in the case where the azolium salt is added into the image forming layer, any time of the process may be selected from the preparation of the organic silver salt to the preparation of the coating solution, but preferred is to add the azolium salt within a period after preparation of the organic silver salt until just prior to coating. As the method for adding the azolium salt, any method such as in the form of powder, a solution, a fine particle dispersion, or the like may be used.

Furthermore, the azolium salt may be added as a solution having mixed therein other additives such as a sensitizing agent, reducing agent, toner, or the like.

In the invention, the azolium salt may be added in any amount, but preferably, it is added in an amount of from 1×10⁻⁶ mol to 2 mol, and more preferably from 1×10⁻³ mol to 0.5 mol, per 1 mol of silver.

(Other Additives)

1) Mercapto Compounds, Disulfides, and Thiones

In the invention, mercapto compounds, disulfide compounds, and thione compounds can be added in order to control the development by suppressing or enhancing development, to improve spectral sensitization efficiency, and to improve storability before development and storability after development. Descriptions can be found in paragraph numbers 0067 to 0069 of JP-A No. 10-62899, as compounds represented by formula (1) and specific examples thereof shown in paragraph numbers 0033 to 0052 of JP-A No. 10-186572, and in lines 36 to 56 in page 20 of EP No. 0803764A1. Among them, mercapto-substituted heterocyclic aromatic compounds described in JP-A Nos. 9-297367, 9-304875, 2001-100358, 2002-303954, 2002-303951, and the like are preferred.

2) Toner

In the photothermographic material of the present invention, addition of a toner is preferred. Description on the toner can be found in JP-A No. 10-62899 (paragraph numbers 0054 and 0055), EP No. 0803764A1 (page 21, lines 23 to 48), JP-A Nos. 2000-356317 and 2000-187298. Preferred are phthalazinones (phthalazinone, phthalazinone derivatives, or metal salts thereof; for example, 4-(1-naphthyl)phthalazinone, 6-chlorophthalazinone, 5,7-dimethoxyphthalazinone, and 2,3-dihydro-1,4-phthalazinedione); combinations of phthalazinones and phthalic acids (e.g., phthalic acid, 4-methylphthalic acid, 4-nitrophthalic acid, diammonium phthalate, sodium phthalate, potassium phthalate, and tetrachlorophthalic anhydride); phthalazines (phthalazine, phthalazine derivatives, or metal salts thereof; for example, 4-(1-naphthyl)phthalazine, 6-isopropylphthalazine, 6-tert-butylphthalazine, 6-chlorophthalazine, 5,7-dimethoxyphthalazine, and 2,3-dihydrophthalazine); and combinations of phthalazines and phthalic acids. Particularly preferred are combinations of phthalazines and phthalic acids. Among them, particularly preferable are the combination of 6-isopropylphthalazine and phthalic acid, and the combination of 6-isopropylphthalazine and 4-methylphthalic acid.

3) Plasticizer and Lubricant

Plasticizers and lubricants which can be used in the image forming layer according to the invention are described in paragraph No. 0117 of JP-A No. 11-65021. Lubricants are described in paragraph Nos. 0061 to 0064 of JP-A No. 11-84573.

4) Dyes and Pigments

From the viewpoints of improving color tone, preventing the generation of interference fringes and preventing irradiation upon laser exposure, various dyes and pigments (for instance, C.I. Pigment Blue 60, C.I. Pigment Blue 64, and C.I. Pigment Blue 15:6) can be used in the image forming layer according to the invention. Detailed description can be found in International Patent Publication (WO) No. 98/36322, JP-A Nos. 10-268465 and 11-338098, and the like. Further, it is preferred to use water-insoluble azomethine dye in combination.

5) Nucleator

Concerning the photothermographic material of the invention, it is preferred to add a nucleator into the image forming layer. Details on the nucleators, method for their addition, and addition amount can be found in paragraph No. 0118 of JP-A No. 11-65021, paragraph Nos. 0136 to 0193 of JP-A No. 11-223898, as compounds represented by formulae (H), (1) to (3), (A), or (B) in JP-A No. 2000-284399; as for a nucleation accelerator, description can be found in paragraph No. 0102 of JP-A No. 11-65021, and in paragraph Nos. 0194 and 0195 of JP-A No. 11-223898.

In the case of using formic acid or formates as a strong fogging agent, it is preferably incorporated at the side having the image forming layer containing a photosensitive silver halide in an amount of 5 mmol or less, and more preferably 1 mmol or less, per 1 mol of silver.

In the case of using a nucleator in the photothermographic material of the invention, it is preferred to use an acid obtained by hydration of diphosphorus pentaoxide, or a salt thereof in combination. Acids obtained by hydration of diphosphorus pentaoxide or salts thereof include metaphosphoric acid (salt), pyrophosphoric acid (salt), orthophosphoric acid (salt), triphosphoric acid (salt), tetraphosphoric acid (salt), hexametaphosphoric acid (salt), and the like. Particularly preferred acids obtained by hydration of diphosphorus pentaoxide or salts thereof include orthophosphoric acid (salt) and hexametaphosphoric acid (salt). Specific examples of the salt include sodium orthophosphate, sodium dihydrogen orthophosphate, sodium hexametaphosphate, ammonium hexametaphosphate, and the like.

The addition amount of the acid obtained by hydration of diphosphorus pentaoxide or the salt thereof (i.e., the coating amount per 1 m² of the photothermographic material) may be set as desired depending on sensitivity or fogging, but the addition amount is preferably from 0.1 mg/m² to 500 mg/m², and more preferably from 0.5 mg/m² to 100 mg/m².

(Binder)

Any polymer may be used as the binder for the image forming layer according to the invention. Suitable as the binder are those that are transparent or translucent, and that are generally colorless, such as natural resin or polymer and their copolymers; synthetic resin or polymer and their copolymer; or media forming a film; for example, included are gelatins, rubbers, poly(vinyl alcohols), hydroxyethyl celluloses, cellulose acetates, cellulose acetate butyrates, poly(vinyl pyrrolidones), casein, starch, poly(acrylic acids), poly(methyl methacrylates), poly(vinyl chlorides), poly(methacrylic acids), styrene-maleic anhydride copolymers, styrene-acrylonitrile copolymers, styrene-butadiene copolymers, poly(vinyl acetals) (e.g., poly(vinyl formal) or poly(vinyl butyral)), polyesters, polyurethanes, phenoxy resin, poly(vinylidene chlorides), polyepoxides, polycarbonates, poly(vinyl acetates), polyolefins, cellulose esters, and polyamides. A binder may be used with water, an organic solvent, or emulsion to form a coating solution.

<Binder Used in the Case of Solvent Coating Method>

As the binder used in the case of solvent coating, in which coating is performed using an organic solvent as a coating solvent, poly(vinyl butyral) is preferable. Specifically, poly(vinyl butyral) is used in an amount of 50% by weight or more with respect to the entire constituent content of the binder in the image forming layer. Copolymer and terpolymer are naturally included.

It is preferred that the poly(vinyl butyral) is a mixture of a poly(vinyl acetal) resin (hereinafter, sometimes referred to as a resin of a low polymerization degree) having a residual acetyl group in an amount of 25 mol % or lower, a residual hydroxy group in an amount of from 17 mol % to 35 mol %, and a weight-average polymerization degree of from 200 to 600, and a poly(vinyl acetal) resin (hereinafter, sometimes referred to as a resin of a high polymerization degree) having a residual acetyl group in an amount of 25 mol % or lower, a residual hydroxy group in an amount of from 17 mol % to 35 mol %, and a weight-average polymerization degree of from 900 to 3,000.

The resin of a low polymerization degree described above is used for the purpose of enhancing the adhesive strength between the image forming layer and the support. Concerning the resin of a low polymerization degree, the lower limit of the weight-average polymerization degree is 200 and the upper limit thereof is 600. When the polymerization degree is less than 200, coating ability is not sufficiently obtained, and the mechanical strength of the obtained image forming layer is deteriorated, even if a resin of a high polymerization degree is used in combination. When the polymerization degree exceeds 600, improvement effect with respect to adhesive property is not sufficiently obtained. The lower limit is preferably 300, and the upper limit is preferably 500.

The resin of a high polymerization degree described above is used for the purpose of enhancing the mechanical strength of the image forming layer and keeping the coating ability. Concerning the resin of a high polymerization degree, the lower limit of the weight-average polymerization degree is 900 and the upper limit thereof is 3,000. When the polymerization degree is less than 900, coating ability and the mechanical strength of the image forming layer are deteriorated. When the polymerization degree exceeds 3,000, coating ability and dispersibility are deteriorated. The lower limit is preferably 1,000, and the upper limit is preferably 1,500.

The weight ratio of the resin of a low polymerization degree to the resin of a high polymerization degree is preferably from 5/95 to 95/5. When the ratio is outside of this range, sufficient adhesive property between the image forming layer and the support is not obtained, or the mechanical strength of the image forming layer is deteriorated.

Concerning the poly(vinyl acetal) resin described above, the upper limit of the amount of residual acetyl group is preferably 25 mol %. When the amount of residual acetyl group exceeds 25 mol %, blocking tends to occur between the obtained photothermographic materials, or sharpness of the obtained image is deteriorated. The upper limit is more preferably 15 mol %.

The lower limit of the amount of residual hydroxy group of the poly(vinyl acetal) resin described above is preferably 17 mol %, and the upper limit thereof is preferably 35 mol %. When the amount of residual hydroxy group is lower than 17 mol %, the poly(vinyl acetal) resin used as the binder resin deteriorates the dispersibility of silver salts and tends to lower the sensitivity. When the amount of residual hydroxy group exceeds 35 mol %, the image forming layer of the obtained photothermographic material has high moisture permeability, resulting in occurrence of fog, deterioration of storage stability, or lowering in image density.

The lower limit of the acetalization degree of the poly(vinyl acetal) resin described above is preferably 40 mol %, and the upper limit thereof is preferably 78 mol %. When the acetalization degree is lower than 40 mol %, the poly(vinyl acetal) resin is insoluble in organic solvent so that it cannot be used as the binder resin of the image forming layer of the photothermographic material. When the acetalization degree exceeds 78 mol %, the amount of residual hydroxy group becomes so small that the poly(vinyl acetal) resin loses its toughness and the mechanical strength of the coated membrane is deteriorated.

In the present specification, as a method for calculating the acetalization degree, a method of counting pairs of acetalized hydroxy groups is applied for the calculation of acetalization degree, which is expressed by mol %, because the acetal group of poly(vinyl acetal) resin is formed by acetalizing two hydroxy groups.

The poly(vinyl acetal) resin described above is preferably a modified poly(vinyl acetal) resin having, at the side chain, at least one functional group selected from the group consisting of a functional group represented by the following formula (1), a functional group represented by the following formula (2), a functional group represented by the following formula (3), a functional group represented by the following formula (4), a functional group represented by the following formula (5), a functional group represented by the following formula (6), a tertiary amine group, and a quaternary ammonium salt group. By having such a hydrophilic functional group in the side chain, dispersibility of organic silver salts can be improved.

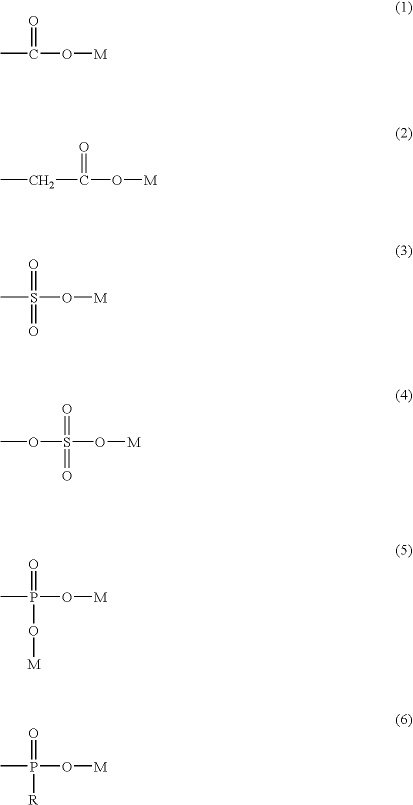

In the formulae, M represents H, Li, Na, or K; and R represents a hydrogen atom or an alkyl group having 1 to 20 carbon atoms.

Examples of the tertiary amine group described above include trimethylamine, triethylamine, triethanolamine, tripropylamine, tributylamine, and the like. When R represents an alkyl group, an alkyl group having 1 to 10 carbon atoms is preferred, and examples thereof include a methyl group, an ethyl group, an isopropyl group, a butyl group, a t-butyl group, a cyclohexyl group and the like.

The lower limit of the amount of functional groups in the modified poly(vinyl acetal) resin described above is preferably 0.1 mol %, and the upper limit thereof is preferably 5 mol %. When the amount is lower than 0.1 mol %, improvement effect with respect to dispersibility of the organic silver salt cannot be obtained. When the amount exceeds 5 mol %, solubility in organic solvent is lowered.

As the poly(vinyl acetal) resin, a modified poly(vinyl acetal) resin having an α-olefin unit in the main chain is also preferable. The α-olefin unit is not particularly limited, but for example, an α-olefin unit derived from a straight-chain or cyclic alkyl group having 1 to 20 carbon atoms is preferable.

As long as the α-olefin unit is within the above range, it may include both of a branched or straight-chain part and a cyclic part. When the α-olefin unit has more than 20 carbon atoms, solvent solubility of modified poly(vinyl alcohol) resin used as a raw material may be lowered so that acetalization reaction does not proceed sufficiently to obtain modified poly(vinyl acetal) resin, or solvent solubility of the obtained modified poly(vinyl acetal) resin may be so low that the resin cannot be used as the binder resin for the image forming layer of the photothermographic material. The α-olefin unit is more preferably derived from a straight-chain or cyclic alkyl group having 1 to 10 carbon atoms, and even more preferably, the α-olefin unit is derived from a straight-chain alkyl group having 2 to 6 carbon atoms. Specific preferred examples thereof include units derived from methylene, ethylene, propylene, isopropylene, butylene, isobutylene, pentylene, hexylene, cyclohexylene, cyclohexylethylene, cyclohexylpropylene, or the like.

Concerning the content of the α-olefin unit in the main chain of the modified poly(vinyl acetal) resin described above, the lower limit is preferably 1 mol % and the upper limit is preferably 20 mol %. When the content is lower than 1 mol %, the effect of decreasing moisture permeability cannot be sufficiently obtained. When the content exceeds 20 mol %, solvent solubility of modified poly(vinyl alcohol) resin used as a raw material is lowered so that acetalization reaction does not proceed sufficiently to obtain modified poly(vinyl acetal) resin. Even if obtained, solvent solubility of the obtained modified poly(vinyl acetal) resin is so low that the resin cannot be used as the binder resin for the image forming layer of the photothermographic material. The upper limit is more preferably 10 mol %.

Concerning the amount of residual halide of the poly(vinyl acetal) resin described above, the upper limit is preferably 100 ppm. When the amount exceeds 100 ppm, the residual halide acts as a formation material of photosensitive silver halide and causes deterioration in storage stability of coating solution, deterioration in storability of the photothermographic material, fogging, or the like. Examples of the method for adjusting the amount of residual halide to an amount of 100 ppm or less include a method of selecting a non-halogen type catalyst for use in acetalization, a method of refining the resulting product by a washing operation using water, a mixed solution of water and alcohol, or the like to remove the residual halide to reach the defined amount or less in the case where a halogen type catalyst is used, and the like. The upper limit is more preferably 50 ppm.

The poly(vinyl acetal) resin described above can be synthesized by an acetalization reaction of poly(vinyl alcohol) having a saponification degree of 75 mol % or higher with various types of aldehydes. Generally, the poly(vinyl acetal) resin is synthesized by reacting poly(vinyl alcohol) with various types of aldehydes using an acid catalyst in an aqueous solution, alcohol solution, mixed solution of water and alcohol, dimethyl sulfoxide solution (DMSO), or the like. Furthermore, the poly(vinyl acetal) resin can also be synthesized by adding an acid catalyst and aldehyde in an alcohol solution containing poly(vinyl acetate) or modified poly(vinyl acetate).

Any aldehydes capable of being acetalized, such as formaldehyde, acetaldehyde, butyraldehyde, propyl aldehyde, and the like may be used for the aldehyde described above. Acetaldehyde and butyraldehyde are preferably used alone or in combination. Furthermore, a proportion of the portion acetalized by acetaldehyde based on the total acetalized portion of the poly(vinyl acetal) resin is preferably 30% or higher.

In the case where the proportion of the portion acetalized by acetaldehyde is lower than 30%, the glass transition temperature of the obtained poly(vinyl acetal) resin becomes 80° C. or lower, so that the nucleus growth of the photosensitive silver salt proceeds too much and dispersibility of the silver salt is not sufficiently obtained, whereby resolution and sharpness of the image cannot be sufficiently provided. More preferably, the proportion of the portion acetalized by acetaldehyde is 50% or higher. By using the poly(vinyl acetal) resin in which the acetoacetal portion is introduced, dispersibility of the silver salt is improved, and thermal melting property, cool-hardening property, and the like become sharper. As a result, it is possible to control the nucleus growth of the silver salt precisely, resulting in improved sharpness of the image and gradation portion.

The acid catalyst described above is not particularly limited, and either organic acid or inorganic acid can be applied. Examples of the acid catalyst include acetic acid, p-toluene sulfonic acid, nitric acid, sulfuric acid, hydrochloric acid, and the like. Examples of alkali which is used upon stopping the synthesizing reaction include sodium hydroxide, potassium hydroxide, ammonia, sodium acetate, sodium carbonate, sodium hydrogencarbonate, potassium carbonate, potassium hydrogencarbonate, and the like.

In the acetalization reaction of poly(vinyl alcohol) and aldehyde, an antioxidant is usually added in the reaction system or in the resin system for the purpose of inhibiting oxidation of the aldehyde or inhibiting oxidation of the obtained resin and enhancing heat resistance. However, in the synthesis of the above-described poly(vinyl acetal) resin, an antioxidant which is used normally such as a hindered phenol antioxidant, bisphenol antioxidant, phosphoric acid type antioxidant, or the like is not used. When these antioxidants are used, the antioxidant used remains in the poly(vinyl acetal) resin and causes deterioration in the pot life of coating solution, deterioration in storage stability of the photothermographic material, and the like, resulting in fogging and spoiling sharpness of the image and gradation portion.

Further, examples of the method for preparing the modified poly(vinyl acetal) resin having the above functional group in the side chain include a method of using, as a raw material, a modified poly(vinyl alcohol) resin, which is obtained by saponifying a copolymer copolymerized by vinyl ester and a monomer having the above functional group, and acetalizing the resin; a method of introducing the functional group by utilizing the hydroxy group which bonds to the main chain of poly(vinyl alcohol) resin or poly(vinyl acetal) resin; and the like.

Examples of the monomer having the functional group described above include acrylic acid, maleic acid, itaconic acid, and the like.

Further, examples of the method for obtaining the above-described modified poly(vinyl acetal) resin having an α-olefin unit in the main chain include a method of using, as a raw material, a modified poly(vinyl alcohol) resin, which is obtained by saponifying a copolymer copolymerized by vinyl ester and α-olefin, and acetalizing the resin, and the like.

The mixed resin described above is preferably obtained by acetalizing poly(vinyl alcohol) having a polymerization degree of from 200 to 600 and poly(vinyl alcohol) having a polymerization degree of from 900 to 3,000.

In the mixed resin prepared by the above method, intermolecular crosslinking is partially performed by aldehyde so that solubility of the entire resin in the solvent, transparency, and dispersibility of compounds are improved, and further, occurrence of fog can be suppressed and coating ability can be improved.

Concerning the mixed resin described above, the lower limit of the ratio of weight-average molecular weight relative to number-average molecular weight (Mw/Mn) is preferably 3.5. When the ratio is less than 3.5, thixotropic property is lowered, and viscosity increases at the time of coating, whereby productivity of the photothermographic material of the present invention would be deteriorated. Incidentally, the ratio of molecular distribution Mw/Mn can be measured by gel permeation chromatography (GPC) or the like using THF or the like as solvent and standard polystyrene or the like as a correction sample.

The total amount of the binder is set to an amount sufficient to maintain the components of the image forming layer therein. Namely, the binder is used within a range effective to exert the function as binder. The effective range can be appropriately determined by one skilled in the art. As a standard amount in the case of maintaining at least the organic silver salt, the weight ratio of the binder to the organic silver salt is from 15:1 to 1:3, and particularly preferably from 8:1 to 1:2.

<Binder Used in the Case of Aqueous Coating Method>

Concerning the binder used in the case of aqueous coating method, the glass transition temperature (Tg) of the binder is preferably in a range of from 0° C. to 80° C. (hereinafter, sometimes referred to as a “high-Tg binder”), more preferably from 10° C. to 70° C., and even more preferably from 15° C. to 60° C.

In the specification, Tg is calculated according to the following equation:

1/Tg=Σ(Xi/Tgi)

where the polymer is obtained by copolymerization of n monomer components (from i=1 to i=n); Xi represents the weight fraction of the ith monomer (ΣXi=1), and Tgi is the glass transition temperature (absolute temperature) of the homopolymer obtained with the ith monomer. The symbol Σ stands for the summation from i=1 to i=n.

Values for the glass transition temperature (Tgi) of the homopolymers derived from each of the monomers were obtained from the values of J. Brandrup and E. H. Immergut, Polymer Handbook (3rd Edition) (Wiley-Interscience, 1989).

The binder may be of two or more types in combination depending on needs. And, the polymer having Tg of 20° C. or higher and the polymer having Tg of lower than 20° C. may be used in combination. In the case where two or more polymers differing in Tg are blended for use, it is preferred that the weight-average Tg is within the range mentioned above.

In the invention, in the case where the image forming layer is formed by first applying a coating solution containing 30% by weight or more of water in the solvent and by then drying, furthermore, in the case where the binder of the image forming layer is soluble or dispersible in an aqueous solvent (water solvent), and particularly in the case where a polymer latex having an equilibrium moisture content of 2% by weight or lower at 25° C. and 60% RH is used, the performance is enhanced. Most preferred embodiment is such prepared to yield an ion conductivity of 2.5 mS/cm or lower, and as such a preparing method, there is mentioned a refining treatment using a separation function membrane after synthesizing the polymer.

The aqueous solvent in which the polymer is soluble or dispersible, as referred herein, signifies water or water containing mixed therein 70% by weight or less of a water-miscible organic solvent. Examples of the water-miscible organic solvent include alcohols such as methyl alcohol, ethyl alcohol, propyl alcohol, or the like; cellosolves such as methyl cellosolve, ethyl cellosolve, butyl cellosolve, or the like; ethyl acetate; dimethylformamide, and the like.

The term “aqueous solvent” is also used in the case where the polymer is not thermodynamically dissolved, but is present in a so-called dispersed state.

The term “equilibrium moisture content at 25° C. and 60% RH” as referred herein can be expressed as follows:

Equilibrium moisture content at 25° C. and 60% RH=[(W1−W0)/W0]×100(% by weight)

wherein W1 is the weight of the polymer in moisture-controlled equilibrium under an atmosphere of 25° C. and 60% RH, and W0 is the weight of the polymer in an absolutely dried state at 25° C.

For the definition and the method of measurement for moisture content, reference can be made to Polymer Engineering Series 14, “Testing methods for polymeric materials” (The Society of Polymer Science, Japan, published by Chijin Shokan).

The equilibrium moisture content at 25° C. and 60% RH is preferably 2% by weight or lower, more preferably in a range of from 0.01% by weight to 1.5% by weight, and even more preferably from 0.02% by weight to 1% by weight.

The binders used in the invention are particularly preferably polymers capable of being dispersed in an aqueous solvent. Examples of dispersed states may include a latex, in which water-insoluble fine particles of hydrophobic polymer are dispersed, or such in which polymer molecules are dispersed in molecular states or by forming micelles, but preferred are latex-dispersed particles. The mean particle diameter of the dispersed particles is in a range of from 1 nm to 50,000 nm, preferably from 5 nm to 1,000 nm, more preferably from 10 nm to 500 nm, and even more preferably from 50 nm to 200 nm. There is no particular limitation concerning particle diameter distribution of the dispersed particles, and the particles may be widely distributed or may exhibit a monodispersed particle diameter distribution. From the viewpoint of controlling the physical properties of the coating solution, preferred mode of usage includes mixing two or more types of dispersed particles each having monodispersed particle diameter distribution.

In the invention, preferred embodiment of the polymers capable of being dispersed in aqueous solvent includes hydrophobic polymers such as acrylic polymer, polyesters, rubbers (e.g., SBR resin), polyurethanes, poly(vinyl chlorides), poly(vinyl acetates), poly(vinylidene chlorides), polyolefins, or the like. As the polymers above, usable are straight-chain polymers, branched polymers, or crosslinked polymers; also usable are the so-called homopolymers in which one type of monomer is polymerized, or copolymers in which two or more types of monomers are polymerized. In the case of a copolymer, it may be a random copolymer or a block copolymer. The molecular weight of the polymer is, in number average molecular weight, in a range of from 5,000 to 1,000,000, and preferably from 10,000 to 200,000. Those having too small molecular weight exhibit insufficient mechanical strength on forming the image forming layer, and those having too large molecular weight are also not preferred because the resulting film-forming properties are poor. Further, crosslinking polymer latexes are particularly preferred for use.

—Specific Examples of Latex—

Specific examples of preferable polymer latex are given below, which are expressed by the starting monomers with % by weight given in parenthesis. The molecular weight is given in number average molecular weight. In the case where polyfunctional monomer is used, the concept of molecular weight is not applicable because they build a crosslinked structure. Hence, they are denoted as “crosslinking”, and the description of the molecular weight is omitted. Tg represents glass transition temperature.

P-1: Latex of -MMA(70) -EA(27) -MAA(3)—(molecular weight 37000, Tg 61° C.)

P-2: Latex of -MMA(70) -2EHA(20) -St(5) -AA(5)—(molecular weight 40000, Tg 59° C.)

P-3: Latex of -St(50) -Bu(47) -MAA(3)—(crosslinking, Tg −17° C.)

P-4: Latex of -St(68) -Bu(29) -AA(3)—(crosslinking, Tg 17° C.)

P-5: Latex of -St(71) -Bu(26) -AA(3)—(crosslinking, Tg 24° C.)

P-6: Latex of -St(70) -Bu(27) -IA(3)—(crosslinking)

P-7: Latex of -St(75) -Bu(24) -AA(1)—(crosslinking, Tg 29° C.)

P-8: Latex of -St(60) -Bu(35) -DVB(3) -MAA(2)—(crosslinking)

P-9: Latex of -St(70) -Bu(25) -DVB(2) -AA(3)—(crosslinking)

P-10: Latex of -VC(50) -MMA(20) -EA(20) -AN(5) -AA(5)—(molecular weight 80000)

P-11: Latex of -VDC(85) -MMA(5) -EA(5) -MAA(5)—(molecular weight 67000)

P-12: Latex of -Et(90) -MAA(10)—(molecular weight 12000)

P-13: Latex of -St(70) -2EHA(27) -AA(3)—(molecular weight 130000, Tg 43° C.)

P-14: Latex of -MMA(63) -EA(35) -AA(2)—(molecular weight 33000, Tg 47° C.)

P-15: Latex of -St(70.5) -Bu(26.5) -AA(3)—(crosslinking, Tg 23° C.)

P-16: Latex of -St(69.5) -Bu(27.5) -AA(3)—(crosslinking, Tg 20.5° C.)

P-17: Latex of -St(61.3) -Isoprene(35.5) -AA(3)—(crosslinking, Tg 17° C.)

P-18: Latex of -St(67) -Isoprene(28) -Bu(2) -AA(3)—(crosslinking, Tg 27° C.)

In the structures above, abbreviations represent monomers as follows. MMA: methyl methacrylate, EA: ethyl acrylate, MAA: methacrylic acid, 2EHA: 2-ethylhexyl acrylate, St: styrene, Bu: butadiene, AA: acrylic acid, DVB: divinylbenzene, VC: vinyl chloride, AN: acrylonitrile, VDC: vinylidene chloride, Et: ethylene, IA: itaconic acid.

The polymer latexes described above are also commercially available, and polymers below can be used. Examples of acrylic polymer include Cevian A-4635, 4718, and 4601 (all manufactured by Daicel Chemical Industries, Ltd.), Nipol Lx811, 814, 821, 820, and 857 (all manufactured by Nippon Zeon Co., Ltd.), and the like; examples of polyesters include FINETEX ES650, 611, 675, and 850 (all manufactured by Dainippon Ink and Chemicals, Inc.), WD-size and WMS (all manufactured by Eastman Chemical Co.), and the like; examples of polyurethanes include HYDRAN AP10, 20, 30, and 40 (all manufactured by Dainippon Ink and Chemicals, Inc.), and the like; examples of rubbers include LACSTAR 7310K, 3307B, 4700H, and 7132C (all manufactured by Dainippon Ink and Chemicals, Inc.), Nipol Lx416, 410, 438C, and 2507 (all manufactured by Nippon Zeon Co., Ltd.), and the like; examples of poly(vinyl chlorides) include G351 and G576 (all manufactured by Nippon Zeon Co., Ltd.), and the like; examples of poly(vinylidene chlorides) include L502 and L513 (all manufactured by Asahi Chemical Industry Co., Ltd.), and the like; and examples of polyolefins include Chemipearl S120 and SA100 (all manufactured by Mitsui Petrochemical Industries, Ltd.), and the like.

The polymer latex above may be used alone, or may be used by blending two or more of them depending on needs.

—Preferable Latex—

Particularly preferable as the polymer latex for use in the invention is that of styrene-butadiene copolymer or that of styrene-isoprene copolymer. The weight ratio of the monomer unit of styrene relative to that of butadiene or isoprene constituting the styrene-butadiene copolymer or the styrene-isoprene copolymer is preferably in a range of from 40:60 to 95:5. Further, the monomer unit of styrene and that of butadiene or isoprene preferably account for 60% by weight to 99% by weight with respect to the copolymer. Further, the polymer latex according to the invention preferably contains acrylic acid or methacrylic acid in a range of from 1% by weight to 6% by weight with respect to the sum of styrene and butadiene or isoprene, and more preferably from 2% by weight to 5% by weight.

The polymer latex according to the invention preferably contains acrylic acid. Preferable range of molecular weight is similar to that described above.

As the latex of styrene-butadiene copolymer preferably used in the invention, there are mentioned P-3 to P-9 and P-15 described above, and commercially available LACSTAR-3307B, 7132C, Nipol Lx416, and the like. And as examples of the latex of styrene-isoprene copolymer, there are mentioned P-17 and P-18 described above.

In the image forming layer of the photothermographic material of the invention, if necessary, there may be added hydrophilic polymer such as gelatin, poly(vinyl alcohol), methyl cellulose, hydroxypropyl cellulose, carboxymethyl cellulose, or the like. The hydrophilic polymer is preferably added in an amount of 30% by weight or less, and more preferably 20% by weight or less, with respect to the total weight of binder incorporated in the image forming layer.

The image forming layer according to the invention is preferably formed by using polymer latex. Concerning the amount of the binder for the image forming layer, a weight ratio of the entire binder to organic silver salt is preferably in a range of from 1/10 to 10/1, more preferably from 1/3 to 5/1, and even more preferably from 1/1 to 3/1.

The image forming layer is, in general, a photosensitive layer containing a photosensitive silver halide, i.e., a photosensitive silver salt; and in such a case, a weight ratio of the entire binder to silver halide is in a range of from 5 to 400, and more preferably from 10 to 200.

The total amount of binder in the image forming layer according to the invention is preferably in a range of from 0.2 g/m² to 30 g/m², more preferably from 1 g/m² to 15 g/m², and even more preferably from 2 g/m to 10 g/m². To the image forming layer according to the invention, there may be added a crosslinking agent for crosslinking, a surfactant to improve coating ability, or the like.

—Preferred Solvent of Coating Solution—

In the invention, a solvent of a coating solution for the image forming layer of the photothermographic material (wherein a solvent and dispersion medium are collectively represented as a solvent for simplicity) is preferably an aqueous solvent containing water at 30% by weight or more. Examples of components other than water may include any of water-miscible organic solvents such as methyl alcohol, ethyl alcohol, isopropyl alcohol, methyl cellosolve, ethyl cellosolve, dimethylformamide and ethyl acetate. The content of water in a solvent of the coating solution is more preferably 50% by weight or higher, and even more preferably 70% by weight or higher. Examples of a preferable solvent composition include, in addition to water, water/methyl alcohol=90/10, water/methyl alcohol=70/30, water/methyl alcohol/dimethylformamide=80/15/5, water/methyl alcohol/ethyl cellosolve=85/10/5, water/methyl alcohol/isopropyl alcohol=85/10/5, and the like (wherein the numerals are values in % by weight).

(Layer Constitution and Constituent Components)

The photothermographic material of the invention can have a non-photosensitive layer in addition to the image forming layer. Non-photosensitive layers can be classified depending on the layer arrangement into (a) a surface protective layer provided on the image forming layer (on the side farther from the support), (b) an intermediate layer provided among plural image forming layers or between the image forming layer and the surface protective layer, (c) an undercoat layer provided between the image forming layer and the support, and (d) a back layer which is provided on the opposite side of the support from the image forming layer.

Furthermore, a layer that functions as an optical filter may be provided as (a) or (b) above. An antihalation layer may be provided as (c) or (d) to the photothermographic material.

1) Surface Protective Layer

The photothermographic material of the invention can comprise a surface protective layer with an object to prevent adhesion of the image forming layer, or the like. The surface protective layer may be a single layer or plural layers.

Description on the surface protective layer may be found in paragraph Nos. 0119 and 0120 of JP-A No. 11-65021 and in JP-A No. 2000-171936.

Preferred as the binder of the surface protective layer according to the invention is gelatin, but poly(vinyl alcohol) (PVA) is also preferably used instead, or in combination. As gelatin, there can be used inert gelatin (e.g., Nitta gelatin 750), phthalated gelatin (e.g., Nitta gelatin 801), and the like. Usable as PVA are those described in paragraph Nos. 0009 to 0020 of JP-A No. 2000-171936, and preferred are the completely saponified product PVA-105, the partially saponified product PVA-205 and PVA-335, as well as modified poly(vinyl alcohol) MP-203 (all of them are trade names of products from Kuraray Ltd.), and the like. The amount of coated poly(vinyl alcohol) (per 1 m² of support) in the surface protective layer (per one layer) is preferably in a range of from 0.3 g/m² to 4.0 g/m², and more preferably from 0.3 g/m² to 2.0 g/m².

The total amount of the coated binder (including water-soluble polymer and latex polymer) (per 1 m² of support) in the surface protective layer (per one layer) is preferably in a range of from 0.3 g/m² to 5.0 g/m², and more preferably from 0.3 g/m² to 2.0 g/m²,

2) Matting Agent

A matting agent is preferably added to the photothermographic material of the invention in order to improve transportability. Description on the matting agent can be found in paragraphs Nos. 0126 and 0127 of JP-A No. 11-65021. The addition amount of the matting agent is preferably in a range of from 1 mg/m² to 400 mg/m², and more preferably from 5 mg/m² to 300 mg/m², when expressed by the coating amount per 1 m² of the photothermographic material.

In the invention, the shape of the matting agent may be a fixed form or non-fixed form, but preferred is to use those having a fixed form and a spherical shape. The mean particle diameter is preferably in a range of from 0.5 μm to 10 μm, more preferably from 1.0 μm to 8.0 μm, and even more preferably from 2.0 μm to 6.0 μm. Furthermore, the particle size distribution of the matting agent is preferably set as such that the variation coefficient is 50% or lower, more preferably 40% or lower, and even more preferably 30% or lower. Herein, the variation coefficient is defined by (the standard deviation of particle diameter)/(mean diameter of the particle)×100. Furthermore, it is preferred to use two types of matting agents having low variation coefficient, in which the ratio of their mean particle diameters being higher than 3, in combination.

The level of matting on the image forming layer surface is not restricted as long as star-dust trouble does not occur, but the level of matting is preferably from 30 sec to 2000 sec, and particularly preferably from 40 sec to 1500 sec, when expressed by a Beck's smoothness. Beck's smoothness can be calculated easily, using Japan Industrial Standard (JIS) P8119 “The method of testing smoothness for papers and sheets using a Beck's test apparatus”, or TAPPI standard method T479.

The level of matting of the back layer in the invention is preferably in a range of 1200 sec or less and 10 sec or more; more preferably, 800 sec or less and 20 sec or more; and even more preferably, 500 sec or less and 40 sec or more, when expressed by a Beck's smoothness.

In the present invention, a matting agent is preferably contained in an outermost layer of the photothermographic material, in a layer which functions as an outermost layer, or in a layer nearer to outer surface, and is also preferably contained in a layer which functions as a so-called protective layer.

3) Polymer Latex

In the present invention, polymer latex is preferably used in the surface protective layer or the back layer of the photothermographic material. As such polymer latex, descriptions can be found in “Gosei Jushi Emulsion (Synthetic resin emulsion)” (Taira Okuda and Hiroshi Inagaki, Eds., published by Kobunshi Kankokai (1978)), “Gosei Latex no Oyo (Application of synthetic latex)” (Takaaki Sugimura, Yasuo Kataoka, Soichi Suzuki, and Keiji Kasahara, Eds., published by Kobunshi Kankokai (1993)), and “Gosei Latex no Kagaku (Chemistry of synthetic latex)” (Soichi Muroi, published by Kobunshi Kankokai (1970)), and the like. Specifically, there are mentioned a latex of methyl methacrylate (33.5% by weight)/ethyl acrylate (50% by weight)/methacrylic acid (16.5% by weight) copolymer, a latex of methyl methacrylate (47.5% by weight)/butadiene (47.5% by weight)/itaconic acid (5% by weight) copolymer, a latex of ethyl acrylate/methacrylic acid copolymer, a latex of methyl methacrylate (58.9% by weight)/2-ethylhexyl acrylate (25.4% by weight)/styrene (8.6% by weight)/2-hydroxyethyl methacrylate (5.1% by weight)/acrylic acid (2.0% by weight) copolymer, a latex of methyl methacrylate (64.0% by weight)/styrene (9.0% by weight)/butyl acrylate (20.0% by weight)/2-hydroxyethyl methacrylate (5.0% by weight)/acrylic acid (2.0% by weight) copolymer, and the like.

Furthermore, as the binder for the surface protective layer, there may be applied the technology described in paragraph Nos. 0021 to 0025 of the specification of JP-A No. 2000-267226, and the technology described in paragraph Nos. 0023 to 0041 of the specification of JP-A No. 2000-19678. The polymer latex in the surface protective layer is preferably contained in an amount of from 10% by weight to 90% by weight, particularly preferably from 20% by weight to 80% by weight, with respect to the total weight of binder.

4) Film Surface pH

The film surface pH of the photothermographic material of the invention preferably yields a pH of 7.0 or lower, and more preferably 6.6 or lower, before thermal developing processing. Although there is no particular restriction concerning the lower limit, the lower limit of pH value is about 3. The most preferred film surface pH range is from 4 to 6.2. From the viewpoint of reducing the film surface pH, it is preferred to use an organic acid such as a phthalic acid derivative or a non-volatile acid such as sulfuric acid, or a volatile base such as ammonia for the adjustment of the film surface pH. In particular, ammonia is preferably used for the achievement of low film surface pH, because it can easily vaporize to remove it in the coating step or before applying thermal development.

It is also preferred to use a non-volatile base such as sodium hydroxide, potassium hydroxide, lithium hydroxide, or the like, in combination with ammonia. The method of measuring the film surface pH value is described in paragraph No. 0123 of the specification of JP-A No. 2000-284399.

5) Hardener

A hardener may be used in each of the image forming layer, protective layer, back layer, and the like according to the invention. As examples of the hardener, descriptions of various methods can be found in pages 77 to 87 of T. H. James, “THE THEORY OF THE PHOTOGRAPHIC PROCESS, FOURTH EDITION” (Macmillan Publishing Co., Inc., 1977). Preferably used are, in addition to chromium alum, sodium salts of 2,4-dichloro-6-hydroxy-s-triazine, N,N-ethylenebis(vinylsulfonacetamide), and N,N-propylenebis(vinylsulfonacetamide), polyvalent metal ions described in page 78 of the above literature and the like, polyisocyanates described in U.S. Pat. No. 4,281,060, JP-A No. 6-208193, and the like, epoxy compounds of U.S. Pat. No. 4,791,042 and the like, and vinylsulfone compounds of JP-A No. 62-89048 and the like.

The hardener is added as a solution, and this solution is added to the coating solution for the protective layer within a period from 180 minutes before coating to just before coating, and preferably within a period from 60 minutes before coating to 10 seconds before coating. However, so long as the effects of the invention are sufficiently realized, there is no particular restriction concerning the mixing method and the conditions of mixing. As specific mixing methods, there can be mentioned a method of mixing in the tank, in which the average stay time calculated from the flow rate of addition and the feed rate to the coater is controlled to yield a desired time, and a method using static mixer such as described in Chapter 8 of N. Harnby, M. F. Edwards, and A. W. Nienow (translated by Koji Takahashi) “Ekitai Kongo Gijutu (Liquid Mixing Technology)” (Nikkan Kogyo Shinbunsha, 1989), and the like.

6) Surfactant

Concerning the surfactant, the solvent, the support, the antistatic or electrically conductive layer, and the method for obtaining color images applicable in the invention, there can be used those described in paragraph numbers 0132, 0133, 0134, 0135, and 0136, respectively, of JP-A No. 11-65021. Concerning lubricants, there can be used those described in paragraph numbers 0061 to 0064 of JP-A No. 11-84573.

In the invention, it is preferred to use a fluorocarbon surfactant. Specific examples of the fluorocarbon surfactant include the compounds described in JP-A Nos. 10-197985, 2000-19680, and 2000-214554. Polymer fluorocarbon surfactants described in JP-A No. 9-281636 are also used preferably.

For the photothermographic material of the invention, the fluorocarbon surfactants described in JP-A Nos. 2002-82411, 2003-57780, and 2001-264110 are preferably used. In the case of conducting coating manufacture with an aqueous coating solution, the usage of the fluorocarbon surfactants described in JP-A Nos. 2003-57780 and 2001-264110 is particularly preferred viewed from the standpoints of capacity in static control, stability of the coated surface state, and sliding capability. The fluorocarbon surfactant described in JP-A No. 2001-264110 is most preferred because of high capacity in static control and that it needs small amount to use.

According to the invention, the fluorocarbon surfactant can be used on either side of the image forming layer side or the backside, but is preferably used on the two sides. Further, it is particularly preferred to use a fluorocarbon surfactant in combination with an electrically conductive layer including metal oxides described below. In this case, sufficient performance is obtained even if the amount of the fluorocarbon surfactant to be used on the side having the electrically conductive layer is reduced or removed.

The addition amount of the fluorocarbon surfactant is preferably in a range of from 0.1 mg/m² to 100 mg/m² on each side of the image forming layer side and backside, more preferably from 0.3 mg/m² to 30 mg/m², and even more preferably from 1 mg/m² to 10 mg/m². Especially, the fluorocarbon surfactant described in JP-A No. 2001-264110 is effective, and is preferably used in a range of from 0.01 mg/m² to 10 mg/m², and more preferably in a range of from 0.1 mg/m² to 5 mg/m².

7) Antistatic Agent

The photothermographic material of the invention preferably has an antistatic layer (electrically conductive layer) including metal oxides or electrically conductive polymer. The antistatic layer may serve as an undercoat layer, a back surface protective layer, or the like, but can also be placed specially. As an electrically conductive material of the antistatic layer, metal oxides having enhanced electric conductivity by the method of introducing oxygen defects or different types of metallic atoms into the metal oxides are preferable for use. Preferred examples of the metal oxide include ZnO, TiO₂, and SnO₂. The addition of Al, or In with respect to ZnO, the addition of Sb, Nb, P, halogen elements, or the like with respect to SnO₂, and the addition of Nb, Ta, or the like with respect to TiO₂ are preferred.

Particularly preferred for use is SnO₂ combined with Sb. The addition amount of heteroatom is preferably in a range of from 0.01 mol % to 30 mol %, and more preferably in a range of from 0.1 mol % to 10 mol %. The shape of the metal oxide includes, for example, spherical, needle-like, or tabular shape. Needle-like particle, in which (the major axis)/(the minor axis) ratio is 2.0 or higher, and more preferably from 3.0 to 50, is preferred viewed from the standpoint of the electric conductivity effect. The metal oxide is preferably used in a range of from 1 mg/m² to 1000 mg/m², more preferably from 10 mg/m² to 500 mg/m², and even more preferably from 20 mg/m² to 200 mg/m².

The antistatic layer according to the invention may be disposed on either side of the image forming layer side or the backside, but it is preferred to set between the support and the back layer. Specific examples of the antistatic layer according to the invention are described in paragraph Nos. 0135 of JP-A No. 11-65021, in JP-A Nos. 56-143430, 56-143431, 58-62646, and 56-120519, and in paragraph Nos. 0040 to 0051 of JP-A No. 11-84573, in U.S. Pat. No. 5,575,957, and in paragraph Nos. 0078 to 0084 of JP-A No. 11-223898.

8) Support

As the transparent support, preferably used is polyester, particularly, polyethylene terephthalate, which is subjected to heat treatment in the temperature range of from 130° C. to 185° C. in order to relax the internal strain which is caused by biaxial stretching and remaining inside the film, and to remove strain ascribed to heat shrinkage generated during thermal development. In the case of a photothermographic material for medical use, the transparent support may be colored with a blue dye (for instance, dye-I described in the Example of JP-A No. 8-240877), or may be uncolored. Concerning the support, it is preferred to apply undercoating technology such as water-soluble polyester described in JP-A No. 11-84574, a styrene-butadiene copolymer described in JP-A No. 10-186565, a vinylidene chloride copolymer described in JP-A No. 2000-39684, or the like. The moisture content of the support is preferably 0.5% by weight or lower, when coating for the image forming layer or back layer is conducted on the support.

9) Other Additives

Furthermore, an antioxidant, stabilizer, plasticizer, UV absorber, or film-forming promoting agent may be added to the photothermographic material of the invention. Each of the additives is added to either of the image forming layer or the non-photosensitive layer. Reference can be made to WO No. 98/36322, EP No. 0803764A1, JP-A Nos. 10-186567 and 10-18568, and the like.

10) Coating Method

The photothermographic material of the invention may be coated by any method. Specifically, various types of coating operations including extrusion coating, slide coating, curtain coating, immersion coating, knife coating, flow coating, or an extrusion coating using the type of hopper described in U.S. Pat. No. 2,681,294 are used. Preferably used is slide coating or extrusion coating described in pages 399 to 536 of Stephen F. Kistler and Petert M. Schweizer, “LIQUID FILM COATING” (Chapman & Hall, 1997), and particularly preferably used is slide coating. An example of the shape of the slide coater for use in slide coating is shown in FIG. 11b.1, page 427, of the same literature. If desired, two or more layers can be coated simultaneously by the method described in pages 399 to 536 of the same literature or by the methods described in U.S. Pat. No. 2,761,791 and British Patent No. 837,095. Particularly preferable coating method in the invention is the method described in JP-A Nos. 2001-194748, 2002-153808, 2002-153803, and 2002-182333.

In the case of mixing two types of liquids on preparing the coating solution used for the invention, known in-line mixer or in-plant mixer is preferably used. Preferred in-line mixer used for the invention is described in JP-A No. 2002-85948, and preferred in-plant mixer used for the invention is described in JP-A No. 2002-90940.

The coating solution according to the invention is preferably subjected to antifoaming treatment to maintain the coated surface in a good state. Preferred method for antifoaming treatment in the invention is described in JP-A No. 2002-66431.

In the case of applying the coating solution according to the invention to the support, it is preferred to perform diselectrification in order to prevent adhesion of dust, particulates, and the like due to charging of the support. Preferred example of the method of diselectrification for use in the invention is described in JP-A No. 2002-143747.

Since a non-setting coating solution is used for the image forming layer in the invention, it is important to precisely control the drying air and the drying temperature. Preferred drying method for use in the invention is described in detail in JP-A Nos. 2001-194749 and 2002-139814.

In order to improve film-forming properties in the photothermographic material of the invention, it is preferred to apply heat treatment immediately after coating and drying. The temperature of the heat treatment is preferably in a range of from 60° C. to 100° C. at the film surface, and the time period for heating is preferably in a range of from 1 sec to 60 sec. More preferably, heating is performed in a temperature range of from 70° C. to 90° C. at the film surface, and the time period for heating is from 2 sec to 10 sec. A preferred method of heat treatment for the invention is described in JP-A No. 2002-107872.

Furthermore, the production methods described in JP-A Nos. 2002-156728 and 2002-182333 are favorably employed in order to produce the photothermographic material of the invention stably and successively.

11) Wrapping Material

In order to suppress fluctuation from occurring on photographic performance during raw stock storage of the photothermographic material of the invention or in order to improve curling or winding tendencies when the photothermographic material is manufactured in a roll state, it is preferred that the photothermographic material of the invention is packed with a wrapping material having low oxygen permeability and/or moisture permeability. Preferably, oxygen permeability is 50 mL·atm⁻¹m⁻² day⁻¹ or lower at 25° C., more preferably 10 mL·atm⁻¹m⁻²day⁻¹ or lower, and even more preferably 1.0 mL·atm⁻¹m⁻²day⁻¹ or lower. Preferably, moisture permeability is 10 g·atm⁻¹m⁻²day⁻¹ or lower, more preferably 5 g·atm⁻¹m⁻²day⁻¹ or lower, and even more preferably 1 g·atm⁻¹m⁻²day⁻¹ or lower.

As specific examples of a wrapping material having low oxygen permeability and/or moisture permeability, reference can be made to, for instance, the wrapping material described in JP-A Nos. 8-254793 and 2000-206653.

12) Other Applicable Techniques

Techniques which can be used for the photothermographic material of the invention also include those in EP No. 0803764A1, EP No. 0883022A1, WO No. 98/36322, JP-A Nos. 56-62648 and 58-62644, JP-A Nos. 9-43766, 9-281637, 9-297367, 9-304869, 9-311405, 9-329865, 10-10669, 10-62899, 10-69023, 10-186568, 10-90823, 10-171063, 10-186565, 10-186567, 10-186569 to 10-186572, 10-197974, 10-197982, 10-197983, 10-197985 to 10-197987, 10-207001, 10-207004, 10-221807, 10-282601, 10-288823, 10-288824, 10-307365, 10-312038, 10-339934, 11-7100, 11-15105, 11-24200, 11-24201, 11-30832, 11-84574, 11-65021, 11-109547, 11-125880, 11-129629, 11-133536 to 11-133539, 11-133542, 11-133543, 11-223898, 11-352627, 11-305377, 11-305378, 11-305384, 11-305380, 11-316435, 11-327076, 11-338096, 11-338098, 11-338099, and 11-343420, JP-A Nos. 2000-187298, 2000-10229, 2000-47345, 2000-206642, 2000-98530, 2000-98531, 2000-112059, 2000-112060, 2000-112104, 2000-112064, and 2000-171936.

(Image Forming Method)

1) Imagewise Exposure

The photothermographic material of the invention may be subjected to imagewise exposure by any method. Preferably, the photothermographic material of the present invention is subjected to scanning exposure using a laser beam. As laser beam which can be used in the invention, He—Ne laser of red through infrared emission, red laser diode, or Ar⁺, He—Ne, He—Cd laser of blue through green emission, and blue laser diode are described. Preferred is red to infrared laser diode, and the peak wavelength of the laser beam is from 600 nm to 900 nm, preferably from 750 nm to 850 nm, and particularly preferably from 780 nm to 790 nm.

Laser beam which oscillates in a longitudinal multiple modulation by a method such as high frequency superposition is also preferably employed.

2) Thermal Development

Although any method may be used for developing the photothermographic material of the present invention, development is usually performed by elevating the temperature of the photothermographic material exposed imagewise. The temperature for development is preferably from 80° C. to 250° C., more preferably from 100° C. to 140° C., and even more preferably from 110° C. to 130° C. The time period for development is preferably from 1 sec to 60 sec, more preferably from 2 sec to 11 sec, and particularly preferably from 3 sec to 10 sec.

(Thermal Developing Apparatus)

Next, a thermal developing apparatus preferably used in the present invention is explained. In the thermal developing apparatus preferably used in the present invention, the thermal development process can adopt a configuration including a separate temperature raising portion and temperature keeping portion. In the temperature raising portion, close contact between heating means, such as heating components and the like, and a photothermographic material is sought to suppress the occurrence of density unevenness. In the temperature keeping portion, it is not necessary to seek such close contact. By using optimum heating methods, which are different in the temperature raising portion and temperature keeping portion, a configuration which enables rapid processing in the thermal development process, downsizing of the apparatus, and cost reduction can be attained while maintaining high image quality without density unevenness.

In the thermal developing apparatus described above, a configuration in which, in the temperature raising portion, the photothermographic material is heated while being pushed and contacted to a plate heater by opposing rollers, and in the temperature keeping portion, the photothermographic material is heated within a slit which is formed between guides, at least one of which has a heater, can be attained. In the temperature raising portion, the photothermographic material is pushed and contacted to a plate heater by opposing rollers, and thereby it is possible to bring the plate heater into close contact with the photothermographic material. On the other hand, in the temperature keeping portion, it is sufficient to convey the photothermographic material while heating (retaining the heat) the space within the slit, using the power of conveyance of the opposing rollers of the temperature raising portion. Therefore, in the temperature keeping portion, driving parts for a conveyance system are unnecessary, high precision of slit size is not strictly required, and downsizing of the apparatus and cost reduction are possible.

According to this thermal developing apparatus, a configuration which enables rapid processing in the thermal development process, downsizing of the apparatus, and cost reduction while maintaining high image quality without density unevenness can be achieved by ensuring, in the first zone, close contact between heating means, such as heating components or the like, and a photothermographic material to raise the temperature of the photothermographic material while suppressing the occurrence of density unevenness, and in the second zone, by retaining the temperature of the photothermographic material in the space between the guides because there is no need to seek such close contact in the second zone. When the space between the guides (slit space) is 3 mm or less, the influence on temperature keeping performance is small regardless of the conveyance position of the photothermographic material in the second zone, high precision of the arrangement of a fixed guide and another guide is not strictly required, and the permissible range with respect to curvature error when processing the two guides or precision of installation is increased, resulting in an increase in the degree of freedom for design which significantly contributes to cost reduction of the apparatus.

In the thermal developing apparatus described above, it is preferable that the slit space of the second zone described above is within a range of from 1 mm to 3 mm. It is preferable that the slit space is 1 mm or more because it is thereby difficult for the coated surface of the photothermographic material to contact with the surface of the guide, which thus reduces the risk of occurrence of defects.

Further, it is preferable that the fixed guide and the other guide described above in the second zone have almost the same curvature. When the guides are made to have a curvature in order to downsize the apparatus or the like, it is possible to configure guides having almost constant guide space.

Furthermore, it is possible to configure the time period for engagement with the photothermographic material in the temperature raising portion and temperature keeping portion to be 10 sec or less, and to shorten the time period for the temperature raising step and temperature keeping step, thereby enabling rapid processing in the thermal developing process.

By preparing a concave portion between the temperature raising portion and the temperature keeping portion to achieve a configuration wherein foreign substances from the temperature raising portion enter the concave portion, it is possible to prevent foreign substances, which accumulate and are moved from the leading end part of the film during conveyance of the film through the temperature raising portion, from being carried to the temperature keeping portion, which results in it becoming possible to prevent the occurrence of jamming, defects, density unevenness, or the like.

In addition, it is preferable that the temperature raising portion and the temperature keeping portion are configured so that the photothermographic material is heated with the side having the image forming layer (hereinafter referred to as the EC side) open. Further, it is preferable to conduct cooling with the EC side of the photothermographic material open in the cooling portion also.

Embodiments of the thermal developing apparatus used in the present invention are explained hereinafter with reference to the attached drawings.

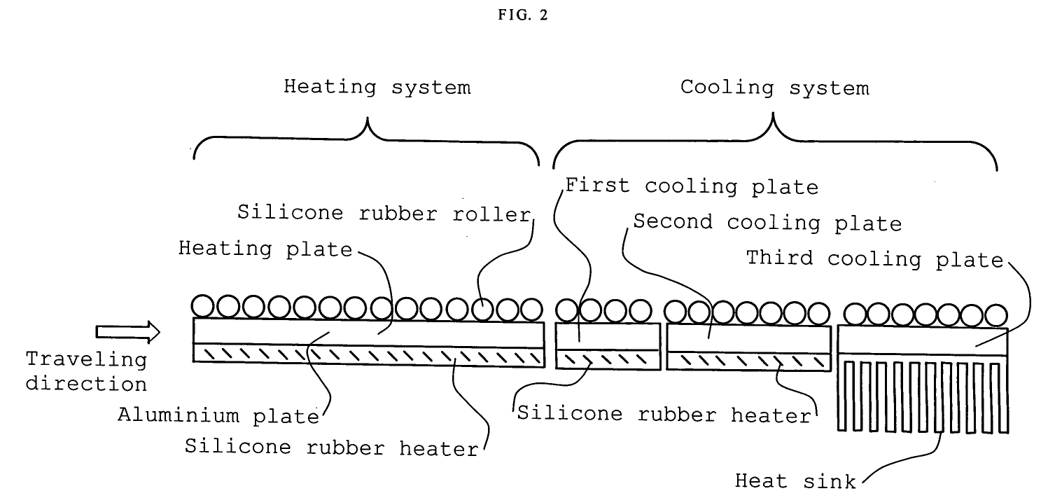

FIG. 1 is a lateral view schematically illustrating the configuration of the main components of a thermal developing apparatus according to the present invention. FIG. 2 is a lateral view schematically illustrating the configuration of the main components of another thermal developing apparatus according to the present invention.

Reference numerals used in FIG. 1 are explained below.
40: Thermal developing apparatus
50: Temperature raising portion
51: First heating zone
51a: Opposing rollers
51b: Heating guide
51c: Heater
51d: Fixed guide surface
52: Second heating zone
52a: Opposing rollers
52b: Heating guide
52c: Heater
52d: Fixed guide surface
53: Temperature keeping portion
53a: Guide portion
53b: Heating guide
53c: Heater
53d: Fixed guide surface
54: Cooling portion
54a: Opposing rollers
54b: Cooling plate
54c: Cooling guide surface
55: Light-scanning exposure portion
56: Conveyance roller pair
40a: Apparatus case
45: Film storage portion
46: Pick-up roller
47: Conveyance roller pair
48: Curved guide
49a, 49b: Conveyance rollers
56: Densitometer
57: Conveyance roller pair
58: Film stacking portion
59: Board portion
F: Photothermographic material
EC: Image forming layer side
BC: Backside
L: Laser

In the thermal developing apparatus 40, during sub-scanning conveyance of a film F, which has an EC side coated with a photothermographic material on one side of a sheet-shaped support formed from PET or the like, similar to that described above, and a BC side which is the opposite side of the support from the EC side, a latent image is formed on the EC side using a laser beam L from a light-scanning exposure portion 55; and next, the film F is heated from the BC side and developed to make the latent image visible; and the film F is conveyed via a conveyance route having curvature to the upper part of the apparatus to be discharged.

The thermal developing apparatus 40 in FIG. 1 is equipped with a film storage portion 45 which is placed near the bottom of an apparatus case 40a and stores a plurality of unused films F; a pick-up roller 46 to pick up and convey the film F placed at the top of the film storage portion 45; a conveyance roller pair 47 to convey the film F from the pick-up roller 46; a curved guide 48 which is configured to have a curved surface to guide the film F from the conveyance roller pair 47 so that the film is conveyed so as to almost reverse the traveling direction; conveyance roller pairs 49a and 49b for sub-scanning conveyance of the film F from the curved guide 48; and a light-scanning exposure portion 55 in which, between the conveyance roller pairs 49a and 49b, the film F is subjected to imagewise exposure by light-scanning the laser beam L based on the image data so that a latent image is formed on the EC side.

The thermal developing apparatus 40 is further equipped with a temperature raising portion 50 in which the film F, at which a latent image has been formed, is heated from the BC side to elevate the temperature of the film to a designated temperature for thermal development; a temperature keeping portion 53 in which the temperature-elevated film F is heated to keep the temperature of the film at the designated temperature for thermal development; a cooling portion 54 in which the heated film F is cooled from the BC side; a densitometer 56 which is placed at the exit side of the cooling portion 54 and measures the density of the film F; a conveyance roller pair 57 that discharges the film F from the densitometer 56; and a film stacking portion 58 which is provided at an incline at the upper surface of the apparatus case 40a to stack the film F discharged from the conveyance roller pair 57.

In the thermal developing apparatus 40, the film storage portion 45, a board portion 59, and the conveyance roller pairs 49a and 49b, temperature raising portion 50, and temperature keeping portion 53 (upstream side) as a group, are arranged in this order from the bottom part of the apparatus case 40a upwards. The film storage portion 45 is at the lowest part, and because the board portion 59 is set between the film storage portion 45 and the temperature raising portion 50 and temperature keeping portion 53, it is difficult for the film storage portion 45 to be affected by heat.

Further, because the conveyance route of the sub-scanning conveyance from the conveyance roller pairs 49a and 49b to the temperature raising portion 50 is configured to be relatively short, the film F is subjected to imagewise exposure at the light-scanning exposure portion 55 while the leading end side of the film F is subjected to thermal development heating at the temperature raising portion 50 and temperature keeping portion 53.

The heating portion comprises the temperature raising portion 50 and the temperature keeping portion 53, and at this portion, the film F is heated to the temperature for thermal development and the temperature for thermal development is maintained. The temperature raising portion 50 has a first heating zone 51 to heat the film F at the upstream side thereof and a second heating zone 52 to heat the film F at the downstream side thereof.

The first heating zone 51 has a fixed planar heating guide 51b which is made from a metal material such as aluminium or the like; a planar heating heater 51c formed from a silicone heater or the like adhered closely to the reverse side of the heating guide 51b; and a plurality of opposing rollers 51a, which are disposed so as to maintain a space narrower than the thickness of the film in order to enable the film to be pushed against a fixed guide surface 51d of the heating guide 51b and which have surfaces made from silicone rubber or the like having a heat insulating property as compared with metals or the like.

The second heating zone 52 has a fixed planar heating guide 52b which is made from a metal material such as aluminium or the like; a planar heating heater 52c formed from a silicone heater or the like adhered closely to the reverse side of the heating guide 52b; and a plurality of opposing rollers 52a, which are disposed so as to maintain a space narrower than the thickness of the film in order to enable the film to be pushed against a fixed guide surface 52d of the heating guide 52b and which have surfaces made from silicone rubber or the like having a heat insulating property as compared with metals or the like.

The temperature keeping portion 53 has a fixed heating guide 53b which is made from a metal material such as aluminium or the like; a planar heating heater 53c formed from a silicone heater or the like adhered closely to the reverse side of the heating guide 53b; and a guide portion 53a, which is arranged to face the fixed guide surface 53d configured on the surface of the heating guide 53b so as to provide a designated space (slit) d and is made from a heat insulating material or the like. The temperature keeping portion 53 is configured so that the side of the temperature raising portion 50 is planar and continuous with the second heating zone 52, and is configured to be curved at a designated curvature toward the upper part of the apparatus from a given point along the conveyance route.

In the first heating zone 51 of the temperature raising portion 50, the film F, which is conveyed from the upstream side of the temperature raising portion 50 by the conveyance roller pairs 49a and 49b, is pushed against the fixed guide surface 51d by each rotatably driven opposing roller 51a, and thereby the film is conveyed while being heated, with the BC side closely contacted to the fixed guide surface 51d.

In the second heating zone 52, similarly, the film F, which is conveyed from the first heating zone 51, is pushed against the fixed guide surface 52d by each rotatably driven opposing roller 52a, and thereby the film is conveyed while being heated, with the BC side closely contacted to the fixed guide surface 52d.

A configuration may be adopted in which a concave portion, which is opened upward in a V-shape, is provided between the second heating zone 52 of the temperature raising portion 50 and the temperature keeping portion 53 so that foreign substances conveyed from the temperature raising portion 50 fall inside the concave portion, resulting in the foreign substances conveyed from the temperature raising portion 50 being prevented from being carried to the temperature keeping portion 53.

In the temperature keeping portion 53, the film F conveyed from the second heating zone 52 passes through the space d due to the conveyance power of the opposing rollers 52a of the second heating zone 52 side, while being heated (keeping the temperature of the film) by the heat from the heating guide 53b in the space d between the fixed guide surface 53d of the heating guide 53b and the guide portion 53a. Here, the film F is conveyed toward the cooling portion 54 while the direction is changed gradually from a horizontal direction to a vertical direction.

In the cooling portion 54, the film F, which is conveyed in an approximately vertical direction from the temperature keeping portion 53, is further conveyed using opposing rollers 54a while the direction of the film is gradually changed from a vertical direction to a diagonal direction toward the film stacking portion 58, while being contacted against a cooling guide surface 54c of a cooling plate 54b, which is made from a metal material or the like, and cooled. The cooling effect can be increased by giving the cooling plate 54b a heat sink structure with fins. A part of the cooling plate 54b may have a heat sink structure with fins.

The density of the cooled film F that has emerged from the cooling portion 54 is measured using the densitometer 56, and the film F is conveyed by a conveyance roller pair 57 and discharged to the film stacking portion 58. In the film stacking portion 58, plural sheets of the film F can be temporarily stacked.

As described above, according to the thermal developing apparatus 40 in FIG. 1, in the temperature raising portion 50 and temperature keeping portion 53 the film F is conveyed with the BC side facing the fixed guide surfaces 51d, 52d, and 53d in a heated state and with the EC side coated with photothermographic material being in an opened state, and in the cooling portion 54 the film F is conveyed with the BC side contacted to the cooling guide surface 54c and being cooled and with the EC side coated with photothermographic material being in an opened state.

Further, the film F is conveyed by the opposing rollers 51a and 52a so that the time taken to pass through the temperature raising portion 50 and the temperature keeping portion 53 is 10 sec or less. Therefore, the heating period of raising and maintaining the temperature is also 10 sec or less.

As described above, according to the thermal developing apparatus 40 in FIG. 1, in the temperature raising portion 50 where uniform heat transmission is needed, the film F is conveyed while maintaining contact heat transmission by closely contacting the film F against the fixed guide surfaces 51d and 52d using the heating guides 51b and 52b and plural opposing rollers 51a and 52a, which push the film F against the heating guides 51b and 52b. Therefore, the whole surface of the film is uniformly heated, and the temperature of the film is uniformly elevated, so that the finished film provides an image of high quality and the occurrence of density unevenness is suppressed.

Further, after elevating the temperature of the film to the temperature for thermal development, the film is conveyed to the space d between the fixed guide surface 53d of the heating guide 53b and the guide portion 53a in the temperature keeping portion 53. In particular, even though the film is heated in the space d without closely contacting the fixed guide surface 53d (heat transmission by at least one selected from heat-transmission heating by direct contact with the fixed guide surface 53d and heat-transmission heating by contact with surrounding high-temperature-air), the temperature of the film is set within a designated range (for example, 0.5° C.) with respect to the temperature for thermal development (for example, 123° C.). In this manner, whether the film is conveyed through the spaced along the wall of the heating guide 53b or along the wall of the curved guide 53a, the difference in temperature of the film is less than 0.5° C., and because a uniform temperature keeping state can be maintained, there is almost no possibility of occurrence of density unevenness in the finished film. As a result, because there is no need to place driving parts such as rollers or the like in the temperature keeping portion 53, reduction of the number of parts can be attained.

In FIG. 2, the effect of space (slit) heating in the temperature keeping portion is explained. The heating system comprises a first heating plate at the upstream side and a second heating plate at the downstream side without rubber rollers. By covering the second heating plate with a heat insulating material, the film passage portion becomes slit-like for slit heating to be performed. The slit space between the second heating plate and the heat insulating material is set to 3 mm.

Thereby, after reaching the temperature for thermal development, the temperature of the wall of the heat insulating material and the temperature of the air inside the silt are approximately constant and very nearly the same, and can be set to about 3° C. lower than the temperature of the heating plate surface. The slit space in the temperature keeping portion can be set to within 3 mm, and the permissible level with respect to curvature error when processing the two guides or to the precision of installation is increased, resulting in a greatly increased degree of freedom in design.

Further, because it is sufficient for the time period for heating the film F to be 10 sec or less, a rapid thermal development process can be realized. Moreover, because the temperature keeping portion 53, which extends in a horizontal direction from the temperature raising portion 50, is configured to have a curved surface from a given point along the conveyance route so as to further extend in a vertical direction and the direction of the film F is approximately reversed in the cooling portion 54 to be discharged to the film stacking portion 58, it becomes possible to cope with downsizing the installation space or downsizing the entire apparatus by designing the cooling portion 54 to have a designated curvature in accordance with the layout of the apparatus.

In a conventional large-sized apparatus, a heating conveyance mechanism identical to the temperature raising portion is provided even in a portion with an adequate temperature keeping capacity after elevation of the film temperature to the temperature for development. As a result, unnecessary components are used, leading to an increase in the number of parts or costs. In a conventional small-sized apparatus, because it is difficult to secure heat transmission when elevating the temperature, there is the problem that density unevenness occurs and it is difficult to secure high image quality. However, according to the second embodiment, similarly to the first embodiment, these problems can all be solved by carrying out the thermal development process separately in the temperature raising portion 50 and in the temperature keeping portion 53.

Further, by heating the film F from the BC side in a state in which the EC side coated with the photothermographic material is in an opened state in the temperature raising portion 50 and temperature keeping portion 53, when the thermal development process is performed with rapid processing of 10 sec or less, the solvent (water, an organic solvent, or the like), which is contained in the film F and will volatilize (vaporize) upon being heated, separates in the minimum distance because the EC side is opened. Therefore, even though the time period for heating (the time period for volatilization) is shortened, the detrimental influence of time shortening is negligible, and, at the same time, even when there are parts at which the contact property between the film F and the fixed guide surface 51d or 52d is partially poor, the difference in temperature with the parts where the contact property is good is alleviated by the effect of heat-diffusion by the PET support on the BC side. As a result, there is hardly any difference in density so that density can be stabilized to make image quality stable. In general, in view of heating efficiency, heating from the EC side has been considered superior. However, in view of the fact that the thermal conductivity of PET used for the support of the film F is 0.17 W/m° C. and the thickness of the PET support is about 170 μm, the time-lag is slight enough to be easily offset by increasing the capacity of the heater or the like. Therefore, heating from the BC side is preferable because the aforementioned effect of alleviation of contact unevenness is favorable.

Moreover, even while the film emerges from the temperature keeping portion 53 and arrives at the cooling portion 54, the solvent (water, an organic solvent, or the like) inside the film F is apt to volatilize (vaporize) due to high temperature, and since the EC side of the film F is also opened in the cooling portion, the solvent (water, an organic solvent, or the like) is not trapped and can volatilize over a longer period. Therefore, image quality is stabilized. As described above, the time period for cooling is also important for rapid processing, particularly for rapid processing when the heating time is 10 sec or less.

(Application of the Invention)

The photothermographic material and the image forming method of the invention are preferably employed as photothermographic materials and image forming methods for photothermographic materials for use in medical diagnosis, for use in graphic arts, for use in micro photographs, as well as for use in industrial photographs, through forming black and white images by silver imaging.

All publications, patent applications, and technical standards mentioned in this specification are herein incorporated by reference to the same extent as if each individual publication, patent application, or technical standard was specifically and individually indicated to be incorporated by reference.

### EXAMPLES

The present invention is specifically explained by way of Examples below, which should not be construed as limiting the invention thereto.

### Example 1

### 1. Preparation of PET Support and Undercoating

### 1-1. Film Manufacturing

PET having IV (intrinsic viscosity) of 0.66 (measured in phenol/tetrachloroethane=6/4 (by weight ratio) at 25° C.) was obtained according to a conventional manner using terephthalic acid and ethylene glycol. The product was pelletized, dried at 130° C. for 4 hours, melted at 300° C., and dye BB having the following structure was included at 0.04% by weight. Thereafter, the mixture was extruded from a T-die and rapidly cooled to form a non-tentered film having such a thickness that the thickness should become 175 μm after tentered and thermal fixation.

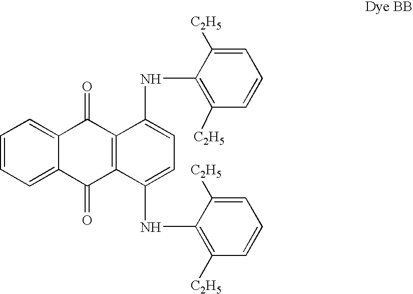

The film was stretched along the longitudinal direction by 3.3 times using rollers of different peripheral speeds, and then stretched along the transverse direction by 4.5 times using a tenter machine. The temperatures used for these operations were 110° C. and 130° C., respectively. Then, the film was subjected to thermal fixation at 240° C. for 20 seconds, and relaxed by 4% along the transverse direction at the same temperature. Thereafter, the chucking part of the tenter machine was slit off, and both edges of the film were knurled. Then the film was rolled up at the tension of 4 kg/cm² to obtain a roll having a thickness of 175 μm.

### 1-2. Surface Corona Discharge Treatment

Both surfaces of the support were treated at room temperature at 20 m/minute using Solid State Corona Discharge Treatment Machine Model 6 KVA manufactured by Piller GmbH. It was proven that treatment of 0.375 kV A·minute/m² was executed, judging from the readings of current and voltage on that occasion. The frequency upon this treatment was 9.6 kHz, and the gap clearance between the electrode and dielectric roll was 1.6 mm.

### 2. Preparation and Coating of Coating Solution for Back Layer

To 830 g of MEK were added 84.2 g of cellulose acetate butyrate (Eastman Chemical Co., CAB381-20) and 4.5 g of a polyester resin (Bostic Co., Vitel PE2200B) with stirring, and dissolved. To this solution was added the dye shown in Table 1 respectively in an amount to provide an optical density of 0.4 at the absorption maximum wavelength, and thereto were added 4.5 g of a fluorocarbon surfactant (Asahi Glass Co., Ltd., Surflon KH40) which had been dissolved in 43.2 g of methanol, and 2.3 g of a fluorocarbon surfactant (Dai-Nippon Ink & Chemicals, Inc., Megaface F-120K). The mixture was thoroughly stirred until dissolution was completed. Thereafter, 75 g of silica (W.R. Grace Co., Siloid 64X6000) dispersed in methyl ethyl ketone at a concentration of 1% by weight with a dissolver type homogenizer was added thereto, followed by stirring to prepare a coating solution for the back layer.

Thus prepared coating solution for the back layer was coated on the support with an extrusion coater so that the dry film thickness became 3.5 μm and dried. Drying was executed over 5 minutes using a drying air with a drying temperature of 100° C. and a dew point temperature of 10° C.

### 3. Image Forming Layer and Surface Protective Layer

### 3-1. Preparation of Coating Materials

1) Preparation of Silver Halide Emulsion

To 5429 mL of water, 88.3 g of phthalated gelatin, 10 mL of a 10% by weight aqueous methanol solution of a PAO compound (HO(CH₂CH₂O)n-(CH(CH₃)CH₂O)₁₇—(CH₂CH₂O)m-H; m+n=5 to 7), and 0.32 g of potassium bromide were added and dissolved. The solution was kept at 40° C., and thereto were added 659 mL of 0.67 mol/L silver nitrate aqueous solution and a solution prepared through dissolving 0.703 mol of potassium bromide and 0.013 mol of potassium iodide per one liter, using a mixing stirrer shown in JP-B Nos. 58-58288 and 58-58289, while controlling the pAg to be 8.09 by a simultaneous mixing method over 4 minutes and 45 seconds, to proceed nucleation. At one minute later, 20 mL of 0.63 N potassium hydroxide solution was added thereto. At additional 6 minutes later, thereto were added 1976 mL of 0.67 mol/L silver nitrate aqueous solution and a solution prepared through dissolving 0.657 mol of potassium bromide, 0.013 mol of potassium iodide, and 30 μmol of dipotassium hexachloroiridate per one liter, while controlling the temperature to be 40° C. and the pAg to be 8.09 by a simultaneous mixing method over 14 minutes and 15 seconds. After stirring for 5 minutes, the mixture was cooled to 38° C.

To the resulting mixture was added 18 mL of a 56% by weight aqueous solution of acetic acid to precipitate a silver halide emulsion. The supernatant was removed to leave 2 L of a precipitate portion. To the precipitate portion was added 10 L of water, followed by stirring to precipitate the silver halide emulsion once again. Moreover, the supernatant was removed to leave 1.5 L of a precipitate portion, and 10 L of water was further added to the precipitate portion, followed by stirring to precipitate the silver halide emulsion. After removing the supernatant to leave 1.5 L of a precipitate portion, thereto was added a solution prepared through dissolving 1.72 g of sodium carbonate anhydrous in 151 mL of water, and the mixture was warmed to 55° C. The mixture was stirred for additional 120 minutes. Finally, the solution was adjusted to the pH of 5.0, and water was added thereto to yield 1161 g per one mol of the silver amount.

Grains in this emulsion were monodispersed cubic silver iodobromide grains having a mean grain size of 40 nm, a variation coefficient of a grain size distribution of 12%, the [100] face ratio of 92%, and silver iodide content of 2 mol %.

2) Preparation of Non-Photosensitive Organic Silver Salt A

To 4720 mL of pure water were added 0.3776 mol of behenic acid, 0.2266 mol of arachidic acid, and 0.1510 mol of stearic acid and allowed to be dissolved at 80° C. Thereafter, 540.2 mL of 1.5 N sodium hydroxide aqueous solution was added to the solution, and then, 6.9 mL of concentrated nitric acid was added thereto, followed by cooling to 55° C. to obtain a solution of sodium salt of organic acid. While keeping the temperature of the solution of sodium salt of organic acid at 55° C., 45.3 g of the aforementioned silver halide emulsion and 450 mL of pure water were added thereto. The mixture was stirred with a homogenizer manufactured by IKA JAPAN Co. (ULTRA-TURRAXT-25) at 13200 rpm (corresponding to 21.1 kHz of mechanical vibration frequency) for 5 minutes. Then, 702.6 mL of 1 mol/L silver nitrate solution was added thereto over 2 minutes, followed by stirring for 10 minutes to obtain an organic silver salt dispersion. Thereafter, the resulting organic silver salt dispersion was poured into a water-washing vessel, and deionized water was added thereto. After stirring, the mixture was allowed to stand still so that the organic silver salt dispersion was float-separated, and the water-soluble salts existing in the bottom phase were removed. Thereafter, water washing with deionized water and drainage of the wastewater were repeated until the electric conductivity of the wastewater was 2 μS/cm. After performing centrifugal dehydration, drying was performed using a circulating dryer with a warm current of air having an oxygen partial pressure of 10% by volume at 40° C. until weight loss did not take place. Thereby, powder organic silver salt including photosensitive silver halide was obtained.

### 3-2. Preparation of Coating Solution for Image Forming Layer

Polyvinyl butyral powder (Monsanto Co., Butvar B-79) in an amount of 14.57 g was dissolved in 1457 g of methyl ethyl ketone (MEK), and thereto was gradually added 500 g of the aforementioned non-photosensitive organic silver salt A while stirring with Dissolver DISPERMAT CA-40M type manufactured by VMA-GETZMANN Co., and thoroughly mixed to give slurry.

The slurry was subjected to two-pass dispersion with a GM-2 pressure type homogenizer manufactured by SMT Limited to prepare a photosensitive emulsion dispersion. In this process, the pressure for treatment upon the first pass was set to 280 kg/cm², while the pressure for treatment upon the second pass was set to 560 kg/cm².

To the obtained organic silver salt dispersion in an amount of 50 g was added 15.1 g of MEK, and the mixture was kept at 21° C. while stirring with a dissolver type homogenizer at 1000 rpm. Thereto was added 390 μL of a 10% by weight methanol solution of an aggregate of: two molecules of N,N-dimethylacetamide/one molecule of bromic acid/one molecule of bromine, followed by stirring and allowed to be mixed. Furthermore, 494 μL of a 10% by weight methanol solution of calcium bromide was added thereto, and the mixture was stirred for 20 minutes.

Subsequently, sensitizer A1 and sensitizer A2 were added respectively in an amount to give 1×10⁶ mol per 1 mol of silver, and further, 167 mg of a methanol solution containing 15.9% by weight of dibenzo-18-crown-6 and 4.9% by weight of potassium acetate was added to the mixture, followed by stirring for 10 minutes. Thereafter, thereto were added 18.3% by weight 2-chlorobenzoic acid, 34.2% by weight salicylic acid-p-toluenesulfonate, and 2.6 g of sensitizing dye No. 41 (0.24% by weight MEK solution). Then, the dye shown in Table 1 was added respectively in an amount to provide an optical density of 0.4 at the absorption maximum wavelength, followed by stirring for one hour.

Thereafter, the mixture was cooled to 13° C., and stirred for additional 30 minutes. While keeping the temperature at 13° C., 13.31 g of polyvinyl butyral (Monsanto Co., Butvar B-79) was added, followed by stirring for 30 minutes, and then 1.08 g of a 9.4% by weight tetrachlorophthalic acid solution was added thereto, followed by stirring for 15 minutes. While keeping stirring, reducing agent-1 in an amount of 0.4 mol per 1 mol of silver and 12.4 g of a 1.1% by weight MEK solution of 4-methyl phthalic acid were added thereto.

Further, 1.5 g of 10% by weight Desmodur N3300 (Mobay, aliphatic isocyanate) was subsequently added, and 13.7 g of a 7.4% by weight MEK solution of tribromomethylsulfonylquinoline and 4.27 g of a 7.2% by weight MEK solution of phthalazine were added thereto.

### 3-3. Preparation of Coating Solution for Surface Protective Layer

To 865 g of MEK, 96 g of cellulose acetate butyrate (Eastman Chemical Co., CAB171-15), 4.5 g of poly(methyl methacrylate) (Rohm and Haas Co., PARALOID A-21), 1.5 g of 1,3-di(vinyl sulfonyl)-2-propanol, 1.0 g of benzotriazole, and 1.0 g of fluorocarbon surfactant (Asahi Glass Co., Ltd., Surflon KH40) were added while stirring, and allowed to be dissolved. Then, 30 g of a dispersion obtained by dispersing 13.6% by weight of cellulose acetate butyrate (Eastman Chemical Co., CAB171-15) and 9% by weight of calcium carbonate (Speciality Minerals Co., Super-Pflex200) to MEK using dissolver type homogenizer at 8000 rpm for 30 minutes was added thereto, followed by stirring to prepare a coating solution for the surface protective layer.

### 3-4. Preparation of Photothermographic Materials

The coating solution for the image forming layer and the coating solution for the surface protective layer were subjected to simultaneous multilayer coating, using an extrusion coater, on the reverse surface of the support from the back layer coated with the back layer, and thereby photothermographic materials were prepared.

Coating was carried out so that the image forming layer had the amount of coated silver of 1.6 g/m², and so that the surface protective layer had the dry film thickness of 2.5 μm. Thereafter, drying was carried out for 10 minutes using a drying air with a drying temperature of 75° C. and a dew point temperature of 10° C.

TABLE 1

| | | |
|---|---|---|
| | | Difference in |
| | | Absorption |
| First Dye | Second Dye | Maximum |

| | | Absorption | | Absorption | Wavelength | |
|---|---|---|---|---|---|---|
| | | Maximum | | Maximum | (λ max2- | |
| Sample | | Wavelength | | Wavelength | λ max1) | |
| No. | No. | λ max1 (nm) | No. | λ max2 (nm) | (nm) | Note |
| 1 | 1-1 | 787 | — | — | — | Comparative |
| 2 | — | — | 2-1 | 814 | — | Comparative |
| 3 | 2-1 | 814 | 2-2 | 817 | 3 | Comparative |
| 4 | 1-4 | 755 | 2-1 | 814 | 59 | Comparative |
| 5 | 1-1 | 787 | 2-1 | 814 | 27 | Invention |
| 6 | 1-1 | 787 | 2-2 | 817 | 30 | Invention |
| 7 | 1-2 | 785 | 2-1 | 814 | 29 | Invention |
| 8 | 1-3 | 786 | 2-1 | 814 | 28 | Invention |
| 9 | 1-2 | 785 | 2-2 | 817 | 32 | Invention |
| 10 | 1-3 | 786 | 2-2 | 817 | 31 | Invention |
| 11 | 1-1 | 787 | 2-3 | 808 | 21 | Invention |

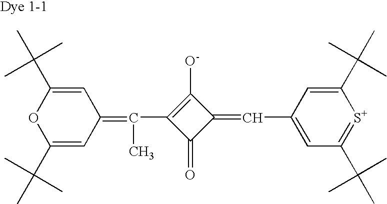

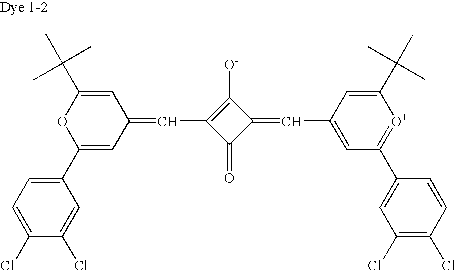

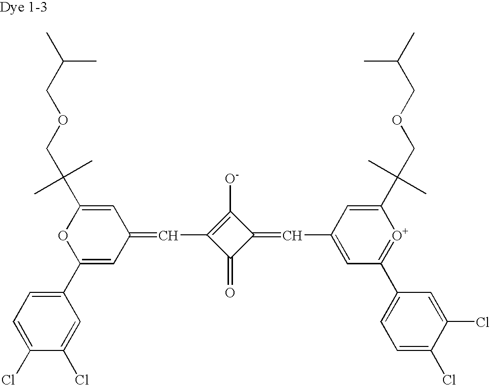

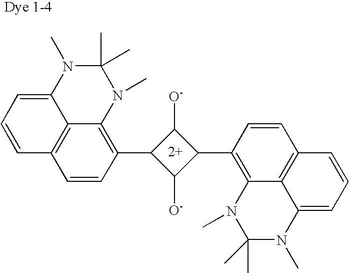

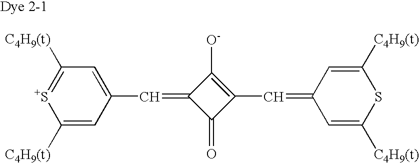

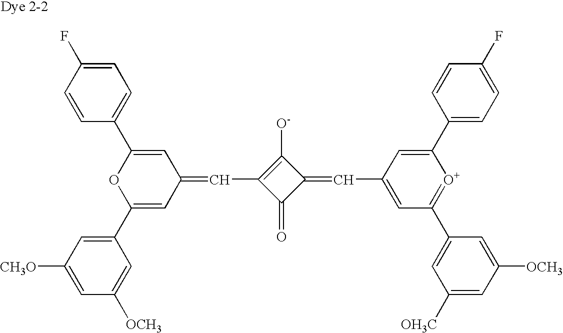

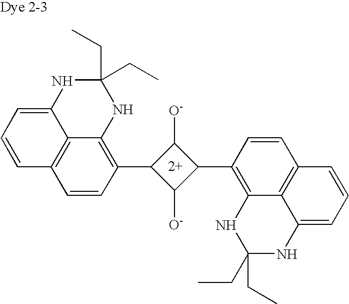

Chemical structures of the compounds used in Examples of the invention are shown below.

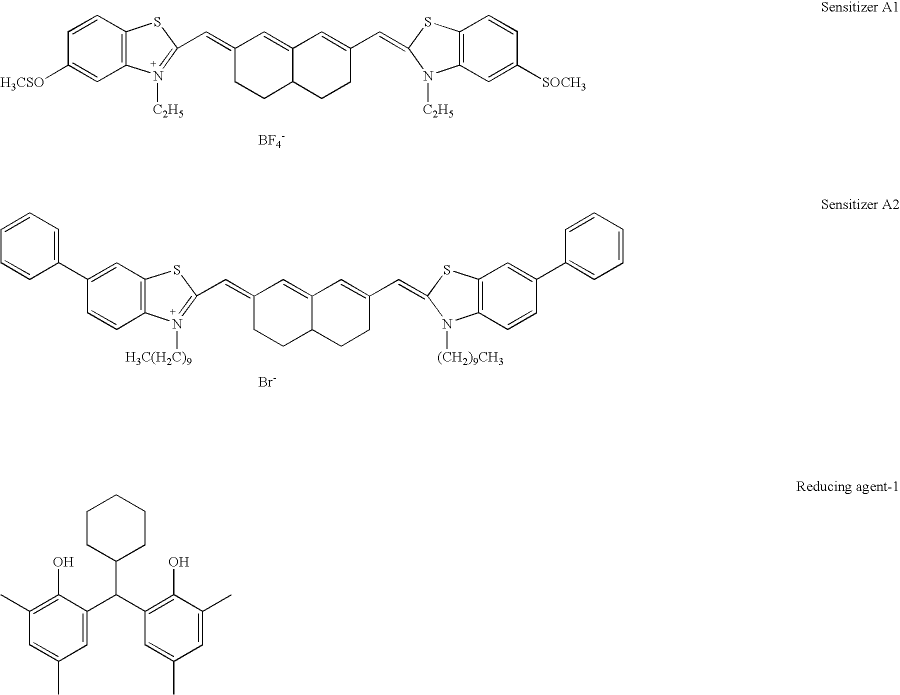

### 4. Evaluation of Performance

### 4-1. Imagewise Exposure and Thermal Development

Using the image forming apparatus shown in FIG. 1 equipped with a laser diode, which is longitudinally multiple modulated at the wavelength of 785 nm with high-frequency mass, as a laser for imagewise exposure, scanning exposure is executed. In the thermal developing portion, as shown in FIG. 2, a silicone rubber heater is attached at the backside of the aluminium plate having a thickness of 10 mm to provide a plate-like heating plate. On the guide surface of the heating plate, there are arranged silicone rubber rollers, in which a surface layer of silicone rubber layer having a thickness of 1 mm is respectively provided and each of which has a diameter of 12 mm and an effective conveyance length of 380 mm, so that the line pressure becomes about 8 gf/cm. By these silicone rubber rollers, the film coated with the photothermographic material is pushed and allowed to be conveyed while contacting the BC surface to the heating plate. The conveyance length of the heating plate is 210 mm.

In the cooling portion, aluminium plates each having a thickness of 10 mm are used for the first, second, and third cooling plates. To the first and second cooling plates are provided respectively a silicone rubber heater to make it possible to control the cooling temperature. To the backside of the aluminium plate of the third cooling plate is joined a heat sink which is arranged with 21 sheets of fins having a thickness of 0.7 mm, a height of 35 mm, and a depth of 390 mm at intervals of 4 mm. On the first, second, and third cooling plates, there are arranged silicone rubber rollers, in which a surface layer of silicone rubber layer having a thickness of 1 mm is respectively provided and each of which has a diameter of 12 mm and an effective conveyance length of 380 mm, so that the line pressure is about 8 gf/cm. The film is allowed to be conveyed while being pushed. The conveyance lengths of the first, second, and third cooling plates are 60 mm, 105 mm, and 105 mm, respectively.

When carrying out normal processing, the conveying speed is set to 15.1 mm/s; and when carrying out rapid processing, the conveying speed is changed to 21.2 mm/s. The temperature of the heating plate is set to 123° C., the temperature of the first cooling plate is set to 110° C., the temperature of the second cooling plate is set to 90° C., and the temperature of the third cooling plate is set to be within a range of from 30° C. to 60° C. Between the heating plate and the cooling plate, a space of 2 mm is provided to suppress heat transfer between the plates.

The samples were each subjected to imagewise exposure and, at the same time, thermal development using the thermal developing apparatus described above, and evaluation of the obtained image was carried out using a densitometer. Herein, “being subjected to imagewise exposure and, at the same time, thermal development” means that, in one sheet of the photothermographic material, a part is imagewise exposed while thermal development is started at another part of the sheet that has already been imagewise exposed. The distance between the imagewise exposure portion and the thermal developing portion was 26 cm.

Each sample was conveyed with the side having the image forming layer (EC side), on which coating solution was coated, open and being pushed by silicone rubber rollers to be conveyed while the reverse side of the side coated with the image forming layer (BC side) being contacted to the heating plate to carry out thermal development by setting the time period for heating at the thermal development temperature to 10 sec. In this process, conveyance was carried out by setting each of the conveying speed from photosensitive material-supplying device portion to imagewise-exposing device portion, the conveying speed in the imagewise exposure portion, the conveying speed in the thermal developing portion, and the conveying speed in the cooling portion to 21.2 mm/sec.

### 4-2. Evaluation Terms

(Fog)

Fog is expressed in terms of density of an unexposed portion.

(Sensitivity)

Sensitivity is defined as a reciprocal of the inverse of the exposure value giving density of fog +1.0. The sensitivities of samples are shown as relative sensitivities (S_{1.0}), with the sensitivity of sample No. 1 designated as 100.

(Sharpness)

Using the obtained samples, a breast image was outputted and the image was evaluated with respect to sharpness by visual observation. The evaluation was carried out according to the following criteria:

A: extremely sharp;

B: good in sharpness but a few blurry parts are seen;

C: blurry parts are remarkable, and interpretation is slightly difficult with the image;

D: interpretation is difficult with the image due to blurry parts.

(Residual Color)

Samples after thermal development were sensory evaluated by visual observation on a film monitor (Schaukasten). The evaluation was carried out by ten persons and was classified as follows. ⊚: Nine or more persons judge that residual color is not seen; ◯: seven or eight persons judge that residual color is not seen; Δ: four to six persons judge that residual color is not seen; and X: three or fewer persons judge that residual color is not seen.

(Evaluation of Laser Dependency)

The laser was allowed to emit light continuously for a long period under the evaluation conditions described above. When the emission wavelength got about 10 nm longer, evaluation with respect to photographic performance was similarly performed.

For each photothermographic material, the sensitivity when the laser is fresh (S1) and the sensitivity after the laser is continuously used for a long period (S2) were compared. The nearer to one the ratio S1/S2 is, the higher the stability is.

### 4-3. Evaluation Results

The obtained results are shown in Table 2.

TABLE 2

| Sample | | | | Residual | S1/S2 | |
|---|---|---|---|---|---|---|
| No. | Fog | Sensitivity | Sharpness | Color | Ratio | Note |
| 1 | 0.22 | 100 | B | ⊚ | 0.85 | Comparative |
| 2 | 0.22 | 135 | D | ⊚ | 1.12 | Comparative |
| 3 | 0.22 | 130 | D | ⊚ | 1.11 | Comparative |
| 4 | 0.22 | 125 | C | ◯ | 1.10 | Comparative |
| 5 | 0.22 | 98 | A | ⊚ | 1.01 | Invention |
| 6 | 0.22 | 98 | A | ⊚ | 1.00 | Invention |
| 7 | 0.22 | 98 | A | ⊚ | 0.99 | Invention |
| 8 | 0.22 | 99 | A | ⊚ | 1.00 | Invention |
| 9 | 0.22 | 98 | A | ⊚ | 1.00 | Invention |
| 10 | 0.22 | 99 | A | ⊚ | 0.99 | Invention |
| 11 | 0.22 | 98 | A | ⊚ | 1.01 | Invention |

The samples of the invention exhibit high sharpness and excellent performance in residual color. And concerning the samples of the invention, the S1/S2 ratio is within a range of from 0.99 to 1.01, and the variation is extremely small. The photothermographic materials of the invention show stable performance with respect to the variation in laser wavelength, and because the dependency on laser wavelength is small, an image for medical diagnosis which is excellent in reproducibility can be provided.

### Example 2

The laser wavelength used in Example 1 was changed from 785 nm to 810 nm, and evaluations with respect to photographic performance and sharpness were performed similar to Example 1. As a result, the photothermographic materials of the present invention exhibit excellent photographic performance also by using different laser wavelength.

TABLE 3

| Sample | | | | |
|---|---|---|---|---|
| No. | Fog | Sensitivity | Sharpness | Note |
| 1 | 0.22 | 138 | D | Comparative |
| 2 | 0.22 | 100 | B | Comparative |
| 3 | 0.22 | 99 | A | Comparative |
| 4 | 0.22 | 100 | C | Comparative |
| 5 | 0.22 | 99 | A | Invention |
| 6 | 0.22 | 100 | A | Invention |
| 7 | 0.22 | 100 | A | Invention |
| 8 | 0.22 | 99 | A | Invention |
| 9 | 0.22 | 101 | A | Invention |
| 10 | 0.22 | 99 | A | Invention |
| 11 | 0.22 | 100 | A | Invention |

What is claimed is:

1. A photothermographic material comprising, on at least one side of a support, at least a photosensitive silver halide, a non-photosensitive organic silver salt, and a reducing agent for thermal development, and further comprising at least two dyes having maximum absorption wavelengths that are different from each other, wherein the difference between the maximum absorption wavelengths is from 10 nm to 50 nm, a maximum absorption wavelength of a first dye corresponds to a wavelength of a first laser for imagewise exposure, and a maximum absorption wavelength of a second dye corresponds to a wavelength of a second laser for imagewise exposure.

2. The photothermographic material according to claim 1, wherein the maximum absorption wavelength of the first dye is from 750 nm to 800 nm, and the difference between the maximum absorption wavelength of the second dye and the maximum absorption wavelength of the first dye is from 10 nm to 50 nm.

3. The photothermographic material according to claim 2, wherein the maximum absorption wavelength of the second dye is 10 nm to 50 nm longer than the maximum absorption wavelength of the first dye.

4. The photothermographic material according to claim 1, wherein an amount of coated silver of the photothermographic material is from 0.5 g/m² to 1.5 g/m².

5. An image forming method for forming an image during conveyance of a sheet of a photothermographic material by using an image forming apparatus comprising an imagewise exposure portion and a thermal developing portion, wherein the photothermographic material is the photothermographic material according to claim 1, a part of the sheet is subjected to imagewise exposure using a laser while another part of the sheet that has already been imagewise exposed is subjected to thermal development, and a distance between the imagewise exposure portion and the thermal developing portion is 50 cm or less.

6. The image forming method according to claim 5, wherein the thermal developing portion comprises a temperature raising portion and a temperature keeping portion, a distance between the imagewise exposure portion and the temperature raising portion is 50 cm or less, and the temperature raising portion and the temperature keeping portion comprise heating means that are different from each other.

7. The image forming method according to claim 6, wherein a total time required for the photothermographic material to pass through the temperature raising portion and the temperature keeping portion is from 2 sec to 11 sec.
